(19) United States
(12) Patent Application Publication
(10) Pub. No.: US 2007/0081568 A1
(43) Pub. Date: Apr. 12, 2007

(54) OPTICAL SEMICONDUCTOR ELEMENT AND METHOD FOR MANUFACTURING THE SAME

(75) Inventor: Yasutaka Imai, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/535,730

(22) Filed: Sep. 27, 2006

(30) Foreign Application Priority Data
Oct. 6, 2005 (JP) 2005-293423
Oct. 6, 2005 (JP) 2005-293424
Jun. 22, 2006 (JP) 2006-172547

(51) Int. Cl. H01S 3/00; H01S 5/00

(52) U.S. Cl. 372/38.09; 372/50.124; 372/50.21

(57) ABSTRACT

An optical semiconductor element includes a surface-emitting type semiconductor laser with a multilayered structure that emits laser light in a direction vertical to a substrate surface, a photodetecting element with a multilayered structure formed above or below the surface-emitting type semiconductor laser, and an electrostatic breakdown protection element that protects the surface-emitting type semiconductor laser from electrostatic destruction, which are provided on the substrate, wherein a pair of input terminals for driving the surface-emitting type semiconductor laser and a pair of output terminals of the photodetecting element are provided independently of one another.

The entire disclosure of Japanese Patent Application No.2005-293423, filed Oct. 6, 2005, No.2005-293424, filed Oct. 6, 2005 and No.2006-172547, filed Jun. 22, 2006 are expressly incorporated by reference herein.

### BACKGROUND

1. Technical Field

The present invention relates to optical semiconductor elements that emit laser light and methods for manufacturing the same.

2. Related Art

A surface-emitting type semiconductor laser is a type of optical elements that emit laser light. The surface-emitting type semiconductor laser is provided with a resonator formed in a direction vertical to a surface of the substrate, and emits laser light from the substrate surface. Compared to conventional edge-emitting type semiconductor lasers that use horizontal cleavage surfaces of a substrate as a resonator, the surface-emitting type semiconductor laser has various favorable characteristics. For example, surface-emitting type semiconductor lasers are suitable for mass-production, capable of direct modulation, and capable of operation with low threshold current, and a two-dimensional laser array structure can be readily formed with surface-emitting type semiconductor lasers.

A surface-emitting type semiconductor laser has a smaller device volume compared to an ordinary edge-emitting type semiconductor laser, such that the electrostatic breakdown voltage of the device itself is low. When the electrostatic breakdown voltage is low, the device may be damaged by static electricity caused by a machine or an operator while the device is mounted on a substrate or a pedestal. For this reason, a variety of measures are implemented in a mounting process to remove static electricity. To remove static electricity from operators, for example, the operators wear working dresses made of antistatic fabric during work, humidity of the work environment is controlled, and the work environment is always placed in an electrically neutralized state by using ionizers. However, these measures have limitations, and the possibility of destruction of devices having an electrostatic breakdown voltage of about 200V or lower during mounting process becomes higher. In this respect, for example, Japanese Laid-open Patent Application JP-A-2004-6548 describes a semiconductor laser with an improved electrostatic breakdown voltage.

Furthermore, surface-emitting type semiconductor lasers have characteristics in that their optical output changes according to the ambient temperature. In this respect, Japanese Laid-open Patent Applications JP-A-2005-33109 and JP-A2005-197514 describe semiconductor elements in which a photodetecting element such as a photodiode is provided on a surface-emitting type semiconductor laser, a portion of laser light emitted from the surface-emitting type semiconductor laser is detected by the photodetecting element, and outputs of the surface-emitting type semiconductor laser are controlled based on the monitored results.

It is noted that higher operation speed of surface-emitting type semiconductor lasers is also desired in such optical semiconductor elements.

### SUMMARY

In accordance with an advantage of some aspects of the present invention, there are provided optical semiconductor elements having a surface-emitting type semiconductor laser and an electrostatic breakdown protection element which are capable of high-speed operation, and methods for manufacturing the same.

In accordance with an embodiment of the invention, an optical semiconductor element is equipped with a surface-emitting type semiconductor laser with a multilayered structure that emits laser light in a direction vertical to a substrate surface, a photodetecting element with a multilayered structure formed above or below the surface-emitting type semiconductor laser, and an electrostatic breakdown protection element that protects the surface-emitting type semiconductor laser from electrostatic destruction, which are provided on the substrate, wherein a pair of input terminals for driving the surface-emitting type semiconductor laser and a pair of output terminals of the photodetecting element are provided independently of one another.

In accordance with another embodiment of the invention, there is provided a method for manufacturing an optical semiconductor element equipped with a surface-emitting type semiconductor laser with a multilayered structure that emits laser light in a direction vertical to a substrate surface, a photodetecting element with a multilayered structure formed above or below the surface-emitting type semiconductor laser, and an electrostatic breakdown protection element that protects the surface-emitting type semiconductor laser from electrostatic destruction, which are provided on the substrate, wherein a pair of input terminals (i.e., driving electrodes) for driving the surface-emitting type semiconductor laser and a pair of output terminals (i.e., output electrodes) of the photodetecting element are formed independently of one another.

In the embodiment of the invention, a pair of driving electrodes and a pair of output electrodes are formed independently of one another, such that a high-speed signal can be applied to the pair of driving electrodes, and the surface-emitting type semiconductor laser can be driven at high speed.

More specifically, if one of the pair of driving electrodes is conductively connected to one of the pair of output terminals, and when a driving signal capable of high-speed driving such as differential driving is applied to the pair of driving electrodes of the surface-emitting type semiconductor laser, the bias voltage across the pair of output electrodes may change because of the influence of the driving signal. However, by providing the driving electrodes and the output electrodes independently of one another, the output electrodes would become more difficult to be affected by driving signals applied to the driving electrodes. For this reason, the surface-emitting type semiconductor laser can be driven by a high-speed driving signal.

In the optical semiconductor element in accordance with an aspect of the embodiment of the invention, the electrostatic breakdown protection element may preferably be connected between a pair of driving electrodes in parallel with the surface-emitting type semiconductor laser and has a rectification action in a reverse direction with respect to the surface-emitting type semiconductor laser.

In the method for manufacturing an optical semiconductor element in accordance with an aspect of the embodiment of the invention, the electrostatic breakdown protection element may preferably be connected between the pair of input electrodes in parallel with the surface-emitting type semiconductor laser to as to have a rectification action in a reverse direction with respect to the surface-emitting type semiconductor laser.

According to the embodiments described above, even when a reverse bias voltage is applied to the surface-emitting type semiconductor laser, current that may be caused by the reverse bias voltage does not flow to the surface-emitting type semiconductor laser, but flows to the electrostatic breakdown protection element, such that the electrostatic breakdown voltage of the element to a reverse bias can be substantially improved.

Also, in the optical semiconductor element in accordance with an aspect of the embodiment of the invention, a PN junction, a PIN junction, a heterojunction or a Schottky junction may be formed in the electrostatic breakdown protection element.

According to the embodiment described above, an electrical current caused by a reverse bias voltage flows through the electrostatic breakdown protection element with a PN junction, a PIN junction, a heterojunction or a Schottky junction formed therein, and circulation of the electrical current in the surface-emitting type semiconductor laser can be avoided.

Furthermore, in the optical semiconductor element in accordance with an aspect of the embodiment of the invention, the electrostatic breakdown protection element may preferably have a layer structure identical with at least a portion of the multilayered structure of at least one of the surface-emitting type semiconductor laser and the photodetecting element.

Also, in the method for manufacturing an optical semiconductor element in accordance with an aspect of the embodiment of the invention, the electrostatic breakdown protection element may preferably be formed to have a layer structure identical with at least a portion of the multilayered structure of at least one of the surface-emitting type semiconductor laser and the photodetecting element.

Also, in the method for manufacturing an optical semiconductor element in accordance with an aspect of the embodiment of the invention, the electrostatic breakdown protection element may preferably be formed concurrently with at least one of the surface-emitting type semiconductor laser and the photodetecting element.

According to the embodiment described above, because the electrostatic breakdown protection element is provided with a layer structure identical with at least a portion of the multilayered structure of the surface-emitting type semiconductor laser and/or the photodetecting element, the electrostatic breakdown protection element can be manufactured with the surface-emitting type semiconductor laser and/or the photodetecting element. Accordingly, the process for manufacturing an electrostatic breakdown protection element can be simplified and the process for manufacturing an optical semiconductor element can be simplified.

It is noted that, in the embodiments of the invention, an “identical layer structure” means that corresponding two layers have the same thickness and composition, and when the layer structure of each of corresponding two layers is a multilayered structure, the thickness and composition of corresponding two layers each composing the multilayered structure are identical with each other.

Also, in the optical semiconductor element in accordance with an aspect of the embodiment of the invention, the photodetecting element may preferably be equipped with a first semiconductor layer of a first conductivity type, a second semiconductor layer that functions as a absorption layer, and a third semiconductor layer of a second conductivity type, wherein a PIN junction with a layer structure identical with the layer structure of the first through third semiconductor layers is formed in the electrostatic breakdown protection element.

Then, in the optical semiconductor element in accordance with an aspect of the embodiment of the invention, an isolation layer that isolates the surface-emitting type semiconductor laser from the photodetecting element may preferably be provided between the surface-emitting type semiconductor laser and the photodetecting element.

In the optical semiconductor element in accordance with an aspect of the embodiment of the invention, a heterojunction may be formed in the electrostatic breakdown protection element with a layer structure identical with a portion of the multilayered structure of the photodetecting element, the isolation layer and a layer structure identical with a portion of the multilayered structure of the surface-emitting type semiconductor laser.

In the optical semiconductor element in accordance with an aspect of the embodiment of the invention, the electrostatic breakdown protection element may preferably have a layer structure different from the multilayered structure of the surface-emitting type semiconductor laser and the photodetecting element.

Further, in the method for manufacturing an optical semiconductor element in accordance with an aspect of the embodiment of the invention, the electrostatic breakdown protection element may preferably be formed to have a layer structure different from the multilayered structure of the surface-emitting type semiconductor laser and the photodetecting element.

Moreover, in the method for manufacturing an optical semiconductor element in accordance with an aspect of the embodiment of the invention, the electrostatic breakdown protection element may preferably be formed in a process different from the process of forming the surface-emitting type semiconductor laser and the photodetecting element.

According to the embodiment described above, because the electrostatic breakdown protection element is provided with a layer structure different from the multilayered structure of the surface-emitting type semiconductor laser and the photodetecting element, each of the surface-emitting type semiconductor laser, the photodetecting element and the electrostatic breakdown protection element can be provided with an optically and electrically optimum structure, respectively.

Also, in the optical semiconductor element in accordance with an aspect of the embodiment of the invention, the photodetecting element may preferably be equipped with a first semiconductor layer of a first conductivity type, a second semiconductor layer that functions as a absorption layer, and a third semiconductor layer of a second conductivity type, wherein the electrostatic breakdown protection element may preferably have a layer structure identical with that of the first semiconductor layer or the third semiconductor layer.

In the optical semiconductor element in accordance with an aspect of the embodiment of the invention, an isolation layer that isolates the surface-emitting type semiconductor laser from the photodetecting element may preferably be provided between the surface-emitting type semiconductor laser and the photodetecting element.

### BRIEF DESCRIPTION OF THE DRAWINGS

FIG. 1 is a plan view schematically showing an optical semiconductor element in accordance with a first embodiment of the invention.

FIG. 2 is a cross-sectional view taken along a line A-A of FIG. 1.

FIG. 3 is an equivalent circuit of the optical semiconductor element shown in FIG. 1.

FIG. 4 is a cross-sectional view schematically showing a step of a method for manufacturing an optical semiconductor element shown in FIG. 1.

FIG. 5 is a cross-sectional view schematically showing a step of the method for manufacturing an optical semiconductor element shown in FIG. 1.

FIG. 6 is a cross-sectional view schematically showing a step of the method for manufacturing an optical semiconductor element shown in FIG. 1.

FIG. 7 is a plan view schematically showing an optical semiconductor element in accordance with a second embodiment of the invention.

FIG. 8 is a cross-sectional view taken along a line B-B of FIG. 7.

FIG. 9 is a partially enlarged view showing the topmost portion of a third columnar section shown in FIG. 7.

FIG. 10 is a cross-sectional view schematically showing an optical semiconductor element in accordance with a third embodiment of the invention.

FIG. 11 is a cross-sectional view schematically showing an optical semiconductor element in accordance with a fourth embodiment of the invention.

FIG. 12 is a cross-sectional view taken along a line C-C of FIG. 11.

FIG. 13 is a cross-sectional view schematically showing a step of a method for manufacturing an optical semiconductor element shown in FIG. 11.

FIG. 14 is a cross-sectional view schematically showing a step of the method for manufacturing an optical semiconductor element shown in FIG. 11.

FIG. 15 is a cross-sectional view schematically showing a step of the method for manufacturing an optical semiconductor element shown in FIG. 11.

FIG. 16 is a cross-sectional view schematically showing a step of a method for manufacturing an optical semiconductor element shown in FIG. 1.

FIG. 17 is a plan view of an optical semiconductor element in accordance with a fifth embodiment of the invention.

FIG. 18 is a cross-sectional view taken along a line D-D of FIG. 17.

FIG. 19 is a plan view of an optical semiconductor element in accordance with a sixth embodiment of the invention.

FIG. 20 is a cross-sectional view taken along a line E-E of FIG. 19.

FIG. 21 is an equivalent circuit of the optical semiconductor element shown in FIG. 19.

FIG. 22 is a cross-sectional view schematically showing a step of a method for manufacturing an optical semiconductor element shown in FIG. 19.

FIG. 23 is a cross-sectional view schematically showing a step of the method for manufacturing an optical semiconductor element shown in FIG. 19.

FIG. 24 is a cross-sectional view schematically showing a step of the method for manufacturing an optical semiconductor element shown in FIG. 19.

FIG. 25 is a plan view schematically showing an optical semiconductor element in accordance with a seventh embodiment of the invention.

FIG. 26 is a cross-sectional view taken along a line F-F of FIG. 25.

FIG. 27 is a partially enlarged view showing the uppermost portion of a third columnar section.

FIG. 28 is a plan view schematically showing an optical semiconductor element in accordance with an eighth embodiment of the invention.

FIG. 29 is a plan view schematically showing an optical semiconductor element in accordance with a ninth embodiment of the invention.

FIG. 30 is a cross-sectional view taken along a line G-G of FIG. 29.

FIG. 31 is a plan view schematically showing an optical semiconductor element in accordance with a tenth embodiment of the invention.

FIG. 32 is a cross-sectional view taken along a line H-H of FIG. 31.

FIG. 33 is an equivalent circuit diagram of the optical semiconductor element shown in FIG. 31.

FIG. 34 is a cross-sectional view schematically showing a step of a method for manufacturing an optical semiconductor element shown in FIG. 31.

FIG. 35 is a cross-sectional view schematically showing a step of the method for manufacturing an optical semiconductor element shown in FIG. 31.

FIG. 36 is a cross-sectional view schematically showing a step of the method for manufacturing an optical semiconductor element shown in FIG. 31.

FIG. 37 is a cross-sectional view schematically showing a step of the method for manufacturing an optical semiconductor element shown in FIG. 31.

FIG. 38 is a plan view schematically showing an optical semiconductor element in accordance with an eleventh embodiment of the invention.

FIG. 39 is a cross-sectional view taken along a line I-I of FIG. 38.

### DESCRIPTION OF EXEMPLARY EMBODIMENTS

Optical semiconductor elements and methods for manufacturing the same in accordance with preferred embodiments of the invention are described below. In the drawings referred to below for describing the invention, the scale may be changed for each of the layers and each of the members such that the layers and the members can have appropriate sizes that can be recognized on the drawings.

### First Embodiment

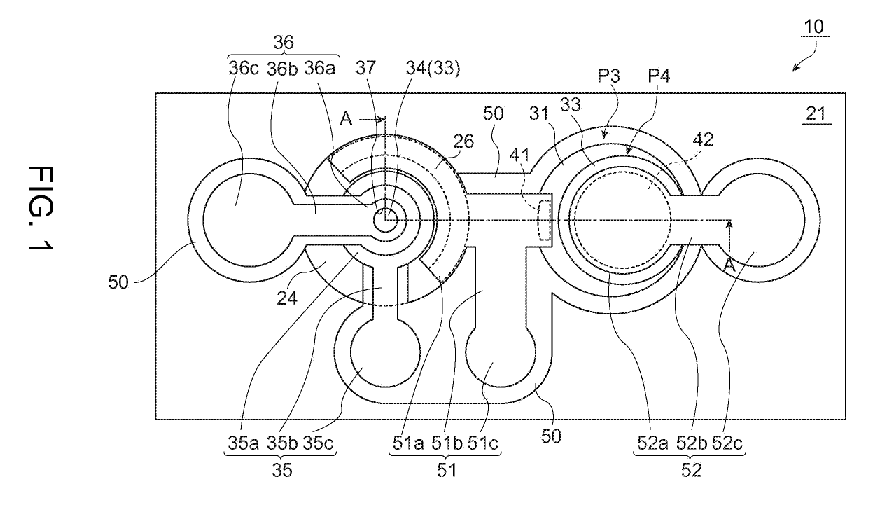

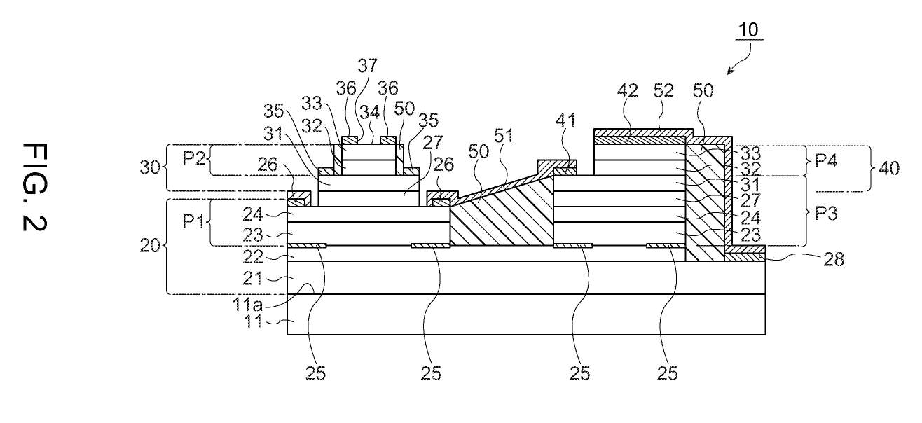

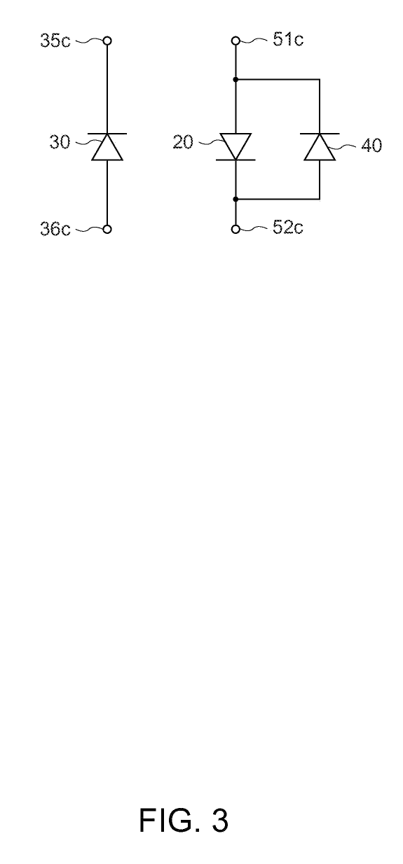

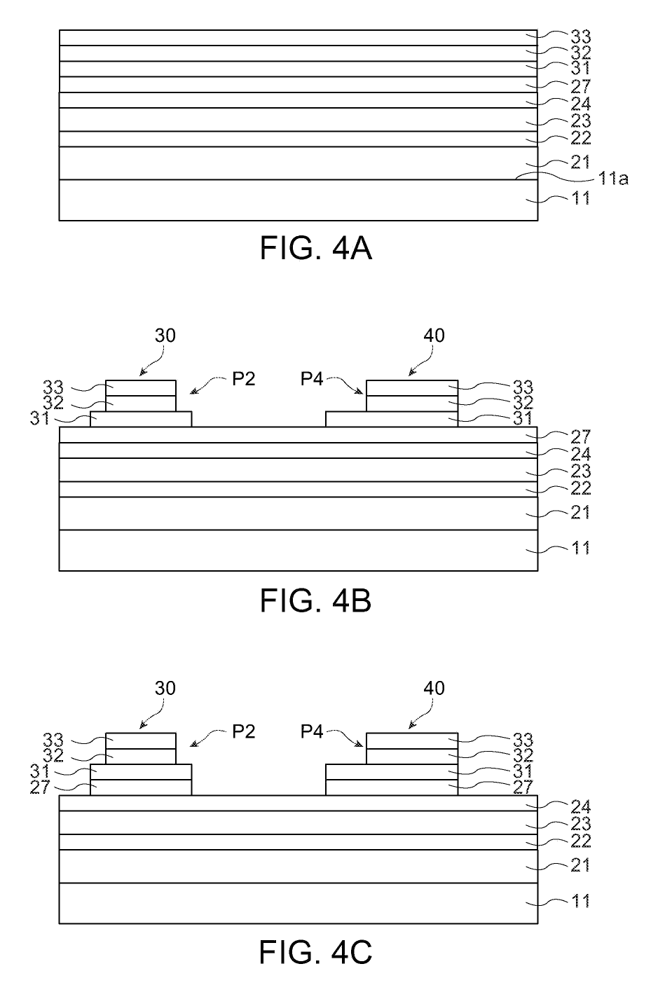

First, a first embodiment of the invention is described with reference to the accompanying drawings. FIG. 1 schematically shows a plan view of an optical semiconductor element 10, FIG. 2 schematically shows a cross-sectional view taken along a line A-A of FIG. 1, FIG. 3 is an equivalent circuit diagram of the optical semiconductor element 10 shown in FIG. 1, and FIGS. 4-6 are views showings steps of a process for manufacturing the optical semiconductor element 10. The optical semiconductor element 10 of the present embodiment is equipped with a surface-emitting type semiconductor laser 20, a photodetecting element 30 as a photodetecting element, and an electrostatic breakdown protection element 40.

Surface-Emitting Type Semiconductor Laser

The surface-emitting type semiconductor laser 20 is formed on a semiconductor substrate 11 composed of, for example, an n-type GaAs substrate. The surface-emitting type semiconductor laser 20 has a vertical resonator, wherein one of distributed Bragg reflectors that compose the vertical resonator is formed in a semiconductor deposited body (hereafter referred to as a first columnar section) P1. In other words, the surface-emitting type semiconductor laser 20 has a portion included in the first columnar section P1.

The surface-emitting type semiconductor laser 20 has a multilayered structure in which a distributed Bragg reflector (hereafter referred to as a first mirror) 21, an active layer 22, another distributed Bragg reflector (hereafter referred to as a second mirror) 23, and a contact layer 24 are sequentially laminated.

The first mirror layer 21 has a structure, for example, composed of 40 pairs of alternately laminated n-type Al_{0.9}Ga_{0.1}As layers and n-type Al_{0.15}Ga_{0.85}As layers. The first mirror 21 is made to be n-type by doping, for example, silicon (Si). The active layer 22 is composed of GaAs well layers and Al_{0.3}Ga_{0.7}As barrier layers in which the well layers include a quantum well structure composed of three layers. The second mirror 23 has a structure, for example, composed of 25 pairs of alternately laminated p-type Al_{0.9}Ga_{0.1}As layers and p-type Al_{0.15}Ga_{0.85}As layers. The second mirror 23 is made to be p-type by doping, for example, carbon (C). The contact layer 24 is composed of a p-type GaAs layer. Accordingly, the surface-emitting type semiconductor laser 20 forms a pin diode with the p-type second mirror 23, the active layer 22 in which no impurity is doped, and the n-type first mirror 21.

Among the surface-emitting type semiconductor laser 20, the second mirror 23 and the contact layer 24 are etched in a circular shape as viewed in a plan view from above the second mirror 23, thereby forming the first columnar section P1. It is noted that the first columnar section P1 is given a plane configuration of a circular shape in this embodiment, but is not limited to this particular shape.

In the present embodiment, the Al composition of an AlGaAs layer is a composition of aluminum (Al) with respect to gallium (Ga). The Al composition of an AlGaAs layer may range from “0” to “1.” In other words, an AlGaAs layer may include a GaAs layer (with the Al composition being “0”) and an AlAs layer (with the Al composition being “1”).

It is noted that the composition of each of the layers and the number of the layers forming the first mirror 21, the active layer 22, the second mirror 23 and the contact layer 24 are not limited to the above.

A current constricting layer 25, which is obtained by oxidizing an AlGaAs layer from its side surface, is formed in a region near the active layer 22 among the layers forming the second mirror 23. The current constricting layer 25 is formed in a ring shape. In other words, the current constricting layer 25 has a cross-sectional shape, as cut in a plane horizontal with a surface 11a of the semiconductor substrate 11, which defines a ring shape concentric with a circular plane configuration of the first columnar section P1, as shown in FIG. 1 and FIG. 2.

An electrode 26 in a C-letter shape in a plan view is formed along an outer circumference of the first columnar section P1 on the contact layer 24. The electrode 26 is formed from a multilayer film of, for example, an alloy of chrome (Cr), gold (Au) and zinc (Zn), and gold (Au), a multilayer film of, for example, platinum (Pt), titanium (Ti) and gold (Au), or the like. The electrode 26 is provided for driving the surface-emitting type semiconductor laser 20, and a current is injected into the active layer 22 from the electrode 26.

Isolation Layer

The optical semiconductor element 10 is also equipped with an isolation layer 27 formed on the surface-emitting type semiconductor laser 20, as shown in FIG. 2. In other words, the isolation layer 27 is provided between the surface-emitting type semiconductor laser 20 and a photodetecting element 30 to be described below, and is formed on the contact layer 24. It is noted that, because the electrode 26 having a C-letter shape in a plan view is formed on the contact layer 24, as described above, a part of the circumference of the isolation layer 27 is surrounded by the electrode 26.

The isolation layer 27 has a circular shape in a plan view. It is noted that the plane configuration of the isolation layer 27 is the same as the plane configuration of a first contact layer 31, as shown in FIG. 2, and formed such that their diameter is smaller than the diameter of the first columnar section P1. It is noted that the plane configuration of the isolation layer 27 may be formed to be greater than the plane configuration of the first contact layer 31.

Photodetecting Element

The photodetecting element 30 includes a first contact layer (first semiconductor layer) 31, a absorption layer (second semiconductor layer) 32, and a second contact layer (third semiconductor layer) 33, which are sequentially laminated to form a multilayered structure, and is provided on the isolation layer 27.

The first contact layer 31 is composed of an n-type GaAs layer that is made to be n-type (first conductivity type) by doping, for example, silicon (Si). The absorption layer 32 may be composed of, for example, a GaAs layer in which no impurity is doped. The second contact layer 33 is composed of a p-type (second conductivity type) GaAs layer that is made to be p-type by doping, for example, carbon (C). Accordingly, the photodetecting element 30 having the n-type first contact layer 31, the absorption layer 32 without an impurity being doped, and the p-type second contact layer 33 forms a pin diode.

The plane configuration of the absorption layer 32 and the contact layer 33 is formed to be smaller than the plane configuration of the first contact layer 31. The second contact layer 33 and the absorption layer 32 form a columnar semiconductor deposited body (hereafter referred to as a second columnar section) P2. In other words, the photodetecting element 30 has a portion included in the second columnar section P2. It is noted that the upper surface of the photodetecting element 30 defines an emission surface 34 for emitting laser light from the surface-emitting type semiconductor laser 20.

An electrode 35 is formed on the first contact layer 31 along an outer circumference thereof. The electrode 35 is provided in a manner to surround the second columnar section P2. The electrode 35 is formed from a multilayer film of, for example, an alloy of chrome (Cr), gold (Au) and germanium (Ge), nickel (Ni) and gold (Au).

The electrode 35 has, as shown in FIG. 1, a connection section 35a having a plane configuration in a ring shape, a liner lead-out section 35b as viewed in a plan view, and a pad section (output terminal) 35c having a circular plane configuration in a plan view. The connection section 35a is formed in a manner to surround the outer circumference of the second columnar section P2, and is electrically connected to the first contact layer 31. The lead-out section 35b connects the connection section 35a and the pad section 35c together. The pad section 35c is used as an electrode pad for output to extract output signals from the photodetecting element 30. It is noted that the connection section 35a has a ring shape in a plan view, but may be in any other shape if the connection section 35a contacts the first contact layer 31.

Further, an electrode 36 is formed on the second contact layer 33. The electrode 36 has, as shown in FIG. 1, a connection section 36a having a ring shape in a plan view, a liner lead-out section 36b as viewed in a plan view, and a pad section (output terminal) 36c having a circular plane configuration in a plan view. The electrode 36 is formed from a multilayer film of, for example, an alloy of chrome (Cr), gold (Au) and zinc (Zn), and gold (Au), a multilayer film of platinum (Pt), titanium (Ti) and gold (Au), or the like.

The connection section 36a is electrically connected to the second contact layer 33, and has an aperture section 37 formed in the center thereof through which a part of the upper surface of the second contact layer 33 is exposed. The exposed surface defines the aforementioned emission surface 34 for emitting laser light. Accordingly, by appropriately setting the plane configuration and the size of the aperture section 37, the configuration and the size of the emission surface 34 can be appropriately set. The lead-out section 36b connects the connection section 36a and the pad section 36c together. The pad section 36c is also used as an output electrode pad to extract output signals from the photodetecting element 30, like the pad section 35c. Accordingly, the pad sections 35c and 36c form a pair of output terminals of the photodetecting element 30.

Electrostatic Breakdown Protection Element

The electrostatic breakdown protection element 40 is formed on the semiconductor substrate 11 with a part of a columnar semiconductor deposited body (hereafter referred to as a third columnar section) P3 that is formed at a position different from the positions where the first columnar section P1 and the second columnar section P2 are formed, and a columnar semiconductor deposited body (hereafter referred to as a fourth columnar section) P4 that is formed on the third columnar section P3.

The third columnar section P3 has a structure in which the second mirror 23, the contact layer 24, the isolation layer 27 and the first contact layer 31 are sequentially laminated, and is formed by etching the aforementioned layers. Also, the fourth columnar section P4 has a structure in which the absorption layer 32 and the second contact layer 33 are laminated, and is formed by etching the aforementioned layers.

The third columnar section P3 is etched in a circular shape as viewed from above the first contact layer 31, and the fourth columnar section P4 is etched in a circular shape as viewed from above the second contact layer 33. Also, as shown in FIG. 1 and FIG. 2, the fourth columnar section P4 is formed to have a diameter smaller than the diameter of the third columnar section P3, and is formed in a state in which the fourth columnar section P4 is eccentric in a direction shifted away from the first columnar section P1 and the second columnar section P2 so as not to be concentric with the third columnar section P3. It is noted that, although the fourth columnar section P4 is eccentric with respect to the third columnar section P3 in this embodiment, the fourth columnar section P4 may be made concentric with the third columnar section P3.

As described above, the electrostatic breakdown protection element 40 has a structure including the first contact layer 31 of the third columnar section P3, and the absorption layer 32 and the second contact layer 33 of the fourth columnar section P4. For this reason, the first contact layer 31 composing the electrostatic breakdown protection element 40 has the same layer structure as (i.e., a layer structure identical with) that of the first contact layer 31 composing the photodetecting element 30. Also, the absorption layer 32 composing the electrostatic breakdown protection element 40 has the same layer structure as that of the absorption layer 32 composing the photodetecting element 30. Further, the second contact layer 33 composing the electrostatic breakdown protection element 40 has the same layer structure as that of the second contact layer 33 composing the photodetecting element 30.

Accordingly, the first contact layer 31, the absorption layer 32 and the second contact layer 33 composing the electrostatic breakdown protection element 40 also form a pin diode. It is noted that the “identical layer structure” means that corresponding two layers have the same thickness and composition, and when the layer structure of each of corresponding two layers is a multilayered structure, the thickness and composition of corresponding two layers each composing the multilayered structure are identical with each other.

An electrode 41 in a generally rectangular shape as viewed in a plan view is formed on the first contact layer 31 composing the electrostatic breakdown protection element 40 on the side opposite to the first columnar section P1 and the second columnar section P2. The electrode 41 is composed of the same material as that of the electrodes 35 and 36 described above. An electrode 42 in a circular shape similar to the plane configuration of the fourth columnar section P4 as viewed in a plan view is formed on the second contact layer 33 composing the electrostatic breakdown protection element 40. The electrode 42 is composed of the same material as that of the electrode 26 described above. These electrodes 41 and 42 are used for driving the electrostatic breakdown protection element 40.

Insulation Layer

Also, the optical semiconductor element 10 is provided with an insulation layer 50 formed mainly around circumferential surfaces of the first columnar section P1, the second columnar section P2 and the third columnar section P3 and a part of the side surface of the fourth columnar section. In other words, the insulation layer 50 is formed on the first mirror 21 or the active layer 22 in a manner to surround the first columnar section P1 and the third columnar section P3. Also, the insulation layer 50 is formed on the first contact layer 31 in a manner to surround the second columnar section P2. Furthermore, the insulation layer 50 is formed below the lead-out section 35b and the pad section 35c of the electrode 35, below the lead-out section 36b and the pad section 36c of the electrode 36, and below electrode wirings 51 and 52 to be described below.

Electrode Wiring

Also, the optical semiconductor element 10 is equipped with electrode wirings 51 and 52 to secure conduction between the surface-emitting type semiconductor laser 20 and the electrostatic breakdown protection element 40.

The electrode wiring 51 has a structure that electrically connects the electrode 26 of the surface-emitting type semiconductor laser 20 to the electrode 41 of the electrostatic breakdown protection element 40, and may be formed with, for example, gold (Au). The electrode wiring 51 is equipped with a connection section 51a in a C-letter shape as viewed in a plan view, a lead-out section 51b in a T-letter shape as viewed in a plan view, and a pad section (input terminal) 51c in a circular shape as viewed in a plan view, as shown in FIG. 1.

The connection section 51a is bonded and electrically connected to the electrode 26. Also, the lead-out section 51b connects the connection section 51a to the electrode 41 of the electrostatic breakdown protection element 40 and is connected to the pad section 51c. Further, the pad section 51c is used as an electrode pad for inputting driving signals to drive the surface-emitting type semiconductor laser 20.

Also, the electrode wiring 52 has a structure that electrically connects the electrode 28 formed on the first mirror 21 to the electrode 42 of the electrostatic breakdown protection element 40, and may be formed with, for example, gold (Au). It is noted that the electrode 28 is one of the electrodes of the surface-emitting type semiconductor laser 20, and is formed with the same material as that of the electrode 35 described above. As shown in FIG. 1, the electrode wiring 52 is equipped with a connection section 52a in a ring shape as viewed in a plan view, a lead-out section 52b in a rectangular shape as viewed in a plan view, and a pad section (input terminal) 52c in a circular shape as viewed in a plan view.

The connection section 51a is bonded and electrically connected to the electrode 42. Also, the lead-out section 52b connects the connection section 52a and the pad section 52c, and is also connected to the electrode 28. The pad section 52c is used as an electrode pad for inputting driving signals to drive the surface-emitting type semiconductor laser 20, like the pad section 51c.

It is noted that, instead of connecting the electrode 26 of the surface-emitting type semiconductor laser 20 and the electrode 41 of the electrostatic breakdown protection element 40 by the electrode wiring 51, and connecting the electrode 28 formed in a part of the upper surface of the first mirror 21 and the electrode 42 of the electrostatic breakdown protection element 40 by the electrode wiring 52, the electrode 26 and the electrode 41, and the electrode 28 and the electrode 42 may be connected together by wire bonding. In this case, a pair of input terminals can be formed with the electrode 26 and the electrode 28. However, as the wiring resistance can be lowered with the connection method using the electrode wirings 51 and 52, this connection method provides excellent high-frequency characteristic and highly reliable manufacturing process.

Overall Structure

In the optical element 10 in accordance with the present embodiment, the n-type first mirror 21 and the p-type second mirror 23 of the surface-emitting type semiconductor laser 20, and the n-type first contact layer 31 and the p-type second contact layer 33 of the photodetecting element 30 form a npnp structure as a whole. The photodetecting element 30 is provided to monitor outputs of laser light generated in the surface-emitting type semiconductor laser 20. Concretely, the photodetecting element 30 converts laser light generated in the surface-emitting type semiconductor laser 20 into electric current. With values of the electric current, outputs of laser light generated in the surface-emitting type semiconductor laser 20 are monitored.

More specifically, in the photodetecting element 30, a part of laser light generated in the surface-emitting type semiconductor laser 20 is absorbed in the absorption layer 32, and photoexcitation is caused by the absorbed light in the absorption layer 32, and electrons and holes are generated. Then, by an electric field that is applied from outside, the electrons move to the electrode 35 and the holes move to the electrode 36, respectively. As a result, a current is generated in the direction from the first contact layer 31 to the second contact layer 33 in the photodetecting element 30.

Also, intensity of the surface-emitting type semiconductor laser 20 is determined mainly by a bias voltage applied to the surface-emitting type semiconductor laser 20. In particular, intensity of the surface-emitting type semiconductor laser 20 greatly changes depending on the ambient temperature of the surface-emitting type semiconductor laser 20 and the lifetime of the surface-emitting type semiconductor laser 20. For this reason, it is necessary for the surface-emitting type semiconductor laser 20 to maintain a predetermined level of intensity.

In the optical element 10, intensity of the surface-emitting type semiconductor laser 20 is monitored in the photodetecting element 30, and the value of a voltage to be applied to the surface-emitting type semiconductor laser 20 is adjusted based on the value of a current generated in the photodetecting element 30, whereby the value of a current flowing within the surface-emitting type semiconductor laser 20 can be adjusted. Accordingly, a predetermined level of intensity can be maintained in the surface-emitting type semiconductor laser 20. The control to feed back the intensity of the surface-emitting type semiconductor laser 20 to the value of a voltage to be applied to the surface-emitting type semiconductor laser 20 can be performed by using an external electronic circuit (e.g., a drive circuit not shown).

Also, in the optical semiconductor element 10, the electrode 26 of the surface-emitting type semiconductor laser 20 and the electrode 41 of the electrostatic breakdown protection element 40 are connected to each other by the electrode wiring 51, and the electrode 28 of the surface-emitting type semiconductor laser 20 and the electrode 42 of the electrostatic breakdown protection element 40 are connected to each other by the electrode wiring 52. It is noted that the electrode 26 of the surface-emitting type semiconductor laser 20 is a p-electrode that is formed on the contact layer 24 composed of p-type GaAs, and the electrode 28 is an n-electrode formed on the n-type first mirror 21. On the other hand, the electrode 41 of the electrostatic breakdown protection element 40 is an n-electrode formed on the first contact layer 31 composed of the n-type GaAs layer, and the electrode 42 is a p-electrode formed on the second contact layer 33 composed of the p-type GaAs layer. Accordingly, the electrostatic breakdown protection element 40 is connected in parallel with the surface-emitting type semiconductor laser 20 by the electrode wirings 51 and 52 so as to have a reverse polarity (a rectification action in a reverse direction) with respect to the surface-emitting type semiconductor laser 20.

Also, the surface-emitting type semiconductor laser 20 has, as shown in FIG. 3, an anode electrode (positive electrode) connected to the pad section 51c of the electrode wiring 51, and a cathode electrode (negative electrode) connected to the pad section 52c of the electrode wiring 52. Further, the electrostatic breakdown protection element 40 has an anode electrode (positive electrode) connected to the pad section 52c of the electrode wiring 52, and a cathode electrode (negative electrode) connected to the pad section 51c of the electrode wiring 51. Further, the photodetecting element 30 has, as shown in FIG. 3, an anode electrode (positive electrode) connected to the pad section 36c of the electrode 36, and a cathode electrode (negative electrode) connected to the pad section 35c of the electrode 35. In other words, the pad sections 51c and 52c forming a pair of input terminals of the surface-emitting type semiconductor laser 20 are formed independently of the pad sections 35c and 36c forming a pair of output terminals of the photodetecting element 30.

Operation of Optical Semiconductor Element

General operations of the optical semiconductor element 10 having the structure described above are described below. It is noted that the following method for driving the optical semiconductor element 10 is described as an example, and various changes can be made within the scope of the invention.

First, when the pad sections 51c and 52c are connected to a power supply (illustration omitted), and a voltage in a forward direction is applied across the electrode 26 and the electrode 28, recombination of electrons and holes occur in the active layer 22 of the surface-emitting type semiconductor laser 20, thereby causing emission of light due to the recombination. Stimulated emission occurs during the period the generated light reciprocates between the second mirror 23 and the first mirror 21, whereby the light intensity is amplified. When the optical gain exceeds the optical loss, laser oscillation occurs, whereby laser light is emitted from the upper surface of the second mirror 23, and enters the isolation layer 27. Then, the laser light enters the first contact layer 31 of the photodetecting element 30.

Then, in the photodetecting element 30, the light entered the first contact layer 31 then enters the absorption layer 32. As a result of a part of the incident light being absorbed in the absorption layer 32, photoexcitation is caused in the absorption layer 32, and electrons and holes are generated. Then, by an electric field applied from an outside element, the electrons move to the electrode 35 and the holes move to the electrode 36, respectively. As a result, a current (photocurrent) is generated in the direction from the first contact layer 31 to the second contact layer 33 in the photodetector element 30. By retrieving the current from the pad sections 35c and 36c and measuring the value of the current, intensity of the surface-emitting type semiconductor laser 20 can be detected.

In this instance, because the pad sections 51c and 52c of the surface-emitting type semiconductor laser 20 are formed independently of the pad sections 35c and 36c of the photodetecting element 30, even when a drive signal capable of high-speed driving such as differential driving is applied to the pad sections 51c and 52c, the impact of the high-speed driving on the photodetecting element 30 is minimal. For this reason, the surface-emitting type semiconductor laser 20 can be driven at high speed.

Also, when a voltage in a reverse direction is applied across the electrode 26 and the electrode 28, the voltage in a reverse direction is a voltage in a reverse direction with respect to the surface-emitting type semiconductor laser 20, but is a voltage in a forward direction with respect to the electrostatic breakdown protection element 40. For this reason, even when a voltage in a reverse direction with respect to the surface-emitting type semiconductor laser 20 is applied, the current flows through the electrostatic breakdown protection element 40, and therefore the surface-emitting type semiconductor laser 20 can be protected from electrostatic destruction.

Method for Manufacturing Optical Semiconductor Element

Next, a method for manufacturing an optical semiconductor element 10 having the structure described above is described. First, on a surface 11a of a semiconductor substrate 11 composed of an n-type GaAs layer, a semiconductor multilayer film is formed by epitaxial growth while modifying its composition (see FIG. 4A).

The semiconductor multilayer film is formed from, for example, a first mirror 21 of 40 pairs of alternately laminated n-type Al_{0.9}Ga_{0.1}As layers and n-type Al_{0.15} Ga_{0.85}As layers, an active layer 22 composed of GaAs well layers and Al_{0.3}Ga_{0.7}As barrier layers in which the well layers include a quantum well structure composed of three layers, a second mirror 23 of 25 pairs of alternately laminated p-type Al_{0.9}Ga_{0.1}As layers and p-type Al_{0.15}Ga_{0.85}As layers, a contact layer 24 composed of p-type GaAs, an isolation layer 27 composed of an AlGaAs layer without impurities being doped, a first contact layer 31 composed of an n-type GaAs layer, a absorption layer 32 composed of a GaAs layer without impurities being doped, and a second contact layer 33 composed of a p-type GaAs layer. These layers are sequentially laminated on the semiconductor substrate 11, thereby forming the semiconductor multilayer film. It is noted that the isolation layer 27 can be composed of a p-type or n-type AlGaAs layer.

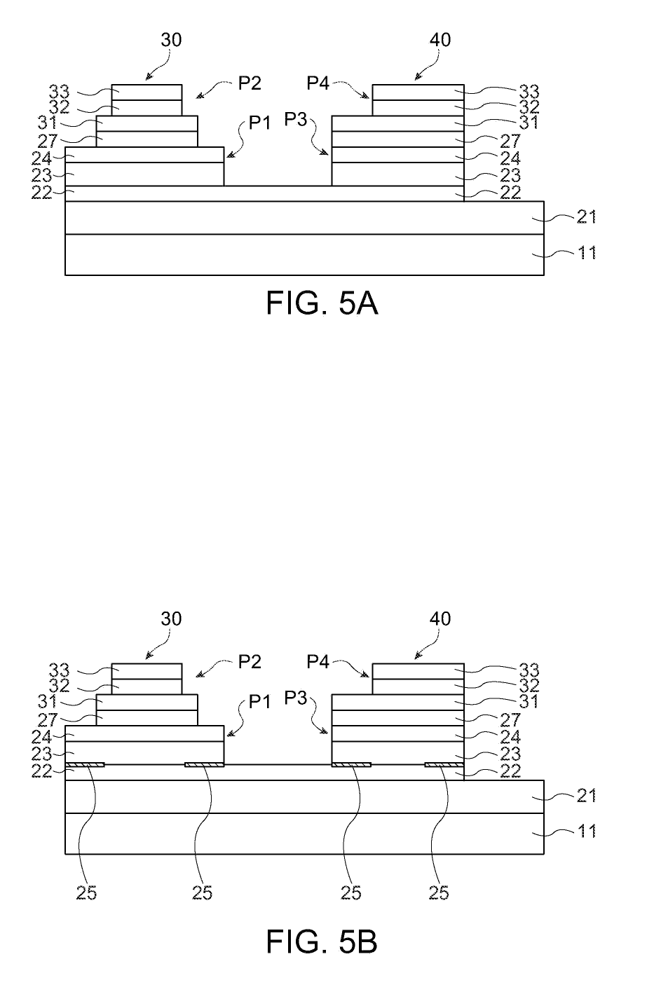

It is noted that, when the second mirror 23 is grown, at least one layer thereof near the active layer 22 is formed to be a layer that is later oxidized and becomes a current constricting layer 25 (see FIG. 5C). More concretely, the layer that becomes to be the current constricting layer 25 is formed to be an AlGaAs layer (including an AlAs layer) having an Al composition that is greater than an Al composition of the isolation layer 27. In other words, the isolation layer 27 may preferably be formed to be an AlGaAs layer whose Al composition is smaller than that of the layer that becomes to be the current constricting layer 25. By this, in an oxidizing process for forming the current constricting layer 25 to be described below, the isolation layer 27 is not oxidized. More specifically, the layer that becomes to be the current constricting layer 25 and the isolation layer 27 may preferably be formed such that the Al composition of the layer that becomes to be the current constricting layer 25 is 0.95 or greater, and the Al composition of the isolation layer 27 is less than 0.95. An optical film thickness of the isolation layer 27 may preferably be, for example, an odd multiple of λ/4, when a design wavelength of the surface-emitting type semiconductor laser 20 is λ.

Also, the sum of optical film thickness of the first contact layer 31, the absorption layer 32 and the second contact layer 33, in other words, the optical film thickness of the entire photodetecting element 30 may preferably be, for example, an odd multiple of λ/4. As a result, the entire photodetecting element 30 can function as a distributed reflection type mirror. In other words, the entire photodetecting element 30 can function as a distributed reflection type mirror above the active layer 22 in the surface-emitting type semiconductor laser 20. Accordingly, the photodetecting element 30 can function as a distributed reflection type mirror without adversely affecting the characteristics of the surface-emitting type semiconductor laser 20.

The temperature at which the epitaxial growth is conducted is appropriately decided depending on the growth method, the kind of raw material, the type of the semiconductor substrate 11, and the kind, thickness and carrier density of the semiconductor multilayer film to be formed, and may preferably be set generally at 450° C.-800° C. Also, the time required for conducting the epitaxial growth is appropriately decided like the temperature. Also, a metal-organic vapor phase deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

Next, a second columnar section P2 and a fourth columnar section P4 are formed (see FIG. 4B). To form the second columnar section P2 and the fourth columnar section P4, first, resist (not shown) is coated on the semiconductor multilayer film, and then the resist is patterned by a lithography method. As a result, a resist layer having a specified plane configuration is formed on the upper surface of the second contact layer 33. Then, by using the resist layer as a mask, the second contact layer 33 and the absorption layer 32 are etched by, for example, a dry etching method. By this, the second contact layer 33 and the absorption layer 32 having the same plane configuration as that of the second contact layer 33 are formed. As a result, the second columnar section P2 and the fourth columnar section P4 are formed. When the second columnar section P2 and the fourth columnar section P4 are formed, the resist layer is removed.

When the second columnar section P2 and the fourth columnar section P4 are formed, the first contact layer 31 is patterned into a specified configuration. More concretely, first, resist (not shown) is coated on the first contact layer 31, and then the resist is patterned by a photolithography method. As a result, a resist layer having a specified pattern that covers the second columnar section P2 and the fourth columnar section P4 is formed on the first contact layer 31. Then, by using the resist layer as a mask, the first contact layer 31 is etched to a specified thickness by, for example, dry etching.

Then, the remaining portion of the first contact layer 31 is etched by a wet etching method. It is noted that, for etching the first contact layer 31, for example, a mixed solution of ammonia, hydrogen peroxide and water can be used as an etchant. In this case, the mixing ratio of ammonia, hydrogen peroxide and water which is about 1:10:150 can be used, but this mixing ratio is not particularly limited, and may be appropriately decided. It is noted that, because the isolation layer 27 is disposed below the first contact layer 31, and the isolation layer 27 functions as an etching stopper layer, etching of the first contact layer 31 can be accurately and readily stopped at the time when the isolation layer 27 is exposed.

By the steps described above, the photodetecting element 30 and the electrostatic breakdown protection element 40 are formed. It is noted that each of the photodetecting element 30 and the electrostatic breakdown protection element 40 includes the second contact layer 33, the absorption layer 32 and the first contact layer 31. Moreover, the plane configuration of the first contact layer 31 is made to be greater than the plane configuration of the second contact layer 33 and the absorption layer 32. In this manner, the photodetecting element 30 and the electrostatic breakdown protection element 40 are formed by the same process. It is noted that, in the exemplary process described above, the second contact layer 33 and the absorption layer 32 are patterned, and then the first contact layer 31 is patterned. However, the first contact layer 31 may be patterned first, and then the second contact layer 33 and the absorption layer 32 may be patterned.

After the photodetecting element 30 and the electrostatic breakdown protection element 40 are formed, the isolation layer 27 is patterned into a specified configuration (see FIG. 4C). More specifically, by using the resist layer described above (the resist layer used for etching the first contact layer 31) as a mask, the isolation layer 27 is etched. In this instance, because the contact layer 24 is disposed below the isolation layer 27, and the contact layer 24 functions as an etching stopper layer, etching of the isolation layer 27 can be accurately and readily stopped at the time when the contact layer 24 is exposed. As an etchant for etching the isolation layer 27, for example, a hydrogen fluoride solution or a hydrofluoric acid system buffer solution can be used.

As a result, the isolation layer 27 that is patterned is formed. Then, the resist layer (the resist layer used for etching the first contact layer 31 and the isolation layer 27) is removed. In the illustrated example, the plane configuration of the isolation layer 27 is made to be the same as the plane configuration of the first contact layer 31. But the plane configuration of the isolation layer 27 can be made to be greater than the plane configuration of the first contact layer 31. For example, another resist layer having a larger plane configuration area than that of the resist layer used for patterning the isolation layer 27 described above may be used to pattern the isolation layer 27.

Next, the surface-emitting type semiconductor laser 20 including the first columnar section P1 and the remaining portion of the third columnar section P3 located below the electrostatic breakdown protection element 40 are formed (see FIG. 5A). More specifically, first, resist (not shown) is coated on the contact layer 24, and then the coated resist is patterned by a photolithography method. As a result, a resist layer having a specified pattern is formed. Then, by using the resist layer as a mask, the contact layer 24, the second mirror 23 and the active layer 22 are etched by, for example, a dry etching method. It is noted that the active layer 22 between the first columnar section P1 and the third columnar section P3 is left remained without being etched. In the manner described above, the first columnar section P1 and the third columnar section P3 are formed.

By the steps described above, a vertical resonator (the surface-emitting type semiconductor laser 20) including the first columnar section P1 is formed on the semiconductor substrate 11. By this, a laminated body of the surface-emitting type semiconductor laser 20, the isolation layer 27 and the photodetecting element 30 is formed, and the electrostatic breakdown protection element 40 is formed above the third columnar section P3. Then, the resist layer is removed. It is noted that, in the exemplary embodiment, after forming the photodetecting element 30, the electrostatic breakdown protection element 40 and the isolation layer 27, the first columnar section P1 and the third columnar section P3 are formed. However, the first columnar section P1 and the third columnar section P3 may be formed first, and then the photodetecting element 30, the electrostatic breakdown protection element 40 and the isolation layer 27 may be formed.

Then, a current constricting layer 25 is formed (see FIG. 5B). First, the semiconductor substrate 11 on which the first columnar section P1 and the third columnar section P3 are formed is placed in a water vapor atmosphere at, for example, about 400° C. As a result, a layer having a high Al composition in the second mirror 23 described above is oxidized from its side surface, whereby the current constricting layer 25 is formed.

The oxidation rate is decided according to the temperature of the furnace, the amount of water vapor supply, and the Al composition and the film thickness of the layer to be oxidized. When driving a surface-emitting type laser equipped with the current constricting layer 25 that is formed by oxidation, current flows only in a portion where the current constricting layer 25 is not formed (a portion that is not oxidized). Accordingly, in the process of forming the current constricting layer 25, the range of the current constricting layer 25 to be formed may be controlled, whereby the current density can be controlled. Also, the diameter of the current constricting layer 25 may preferably be adjusted such that a major portion of laser light that is emitted from the surface-emitting type semiconductor laser 20 enters the first contact layer 31.

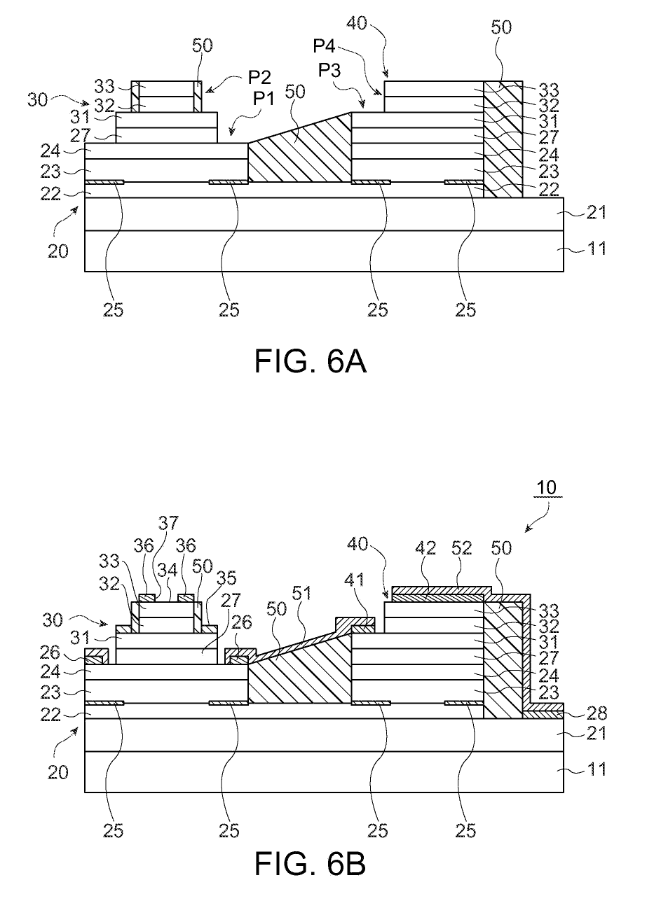

Next, an insulation layer 50 is formed on the active layer 22 and the first mirror 21, around the first columnar section P1 and the third columnar section P3, and around the second columnar section P2 (see FIG. 6A). The insulation layer 50 may preferably be composed of a material that is easier to make a thick film. The film thickness of the insulation layer 50 may be, for example, about 2-4 μm, but it is not particularly limited, and may be appropriately decided according to the height of the first columnar section P1 and the third columnar section P3.

For example, the insulation layer 50 can be formed from material that is obtained by hardening liquid material settable by energy, such as, heat, light or the like (for example, a precursor of ultraviolet setting type resin or thermosetting type resin). As the ultraviolet setting type resin, for example, an acrylic resin, an epoxy resin or the like that is an ultraviolet setting type can be enumerated. Also, as the thermosetting type resin, a polyimide resin or the like that is a thermosetting type can be enumerated. Furthermore, for example, the insulation layer 50 may be composed of a laminated layered film using a plurality of the materials described above.

In this exemplary embodiment, the case where a precursor of polyimide resin is used as the material for forming the insulation layer 50 is described. First, for example, by using a spin coat method, the precursor (precursor of polyimide resin) is coated on the semiconductor substrate 11, thereby forming a precursor layer. In this instance, the precursor layer is formed in a manner to cover the upper surface of the first columnar section P1. It is noted that, as the method for forming the precursor layer, besides the aforementioned spin coat method, other known techniques, such as, a dipping method, a spray coat method, an ink jet method or the like can be used. Then, the semiconductor substrate 11 is heated by using, for example, a hot plate or the like, thereby removing the solvent, and then is placed in a furnace at about 350° C. to thereby imidize the precursor layer, whereby a polyimide resin layer that is almost completely set is formed. Then, the polyimide resin layer is patterned by using a known lithography technique, thereby forming the insulation layer 50.

As the etching method used for patterning, a dry etching method or the like can be used. Dry etching can be conducted with, for example, oxygen or argon plasma. In the method for forming the insulation layer 50 described above, an example in which a precursor layer of polyimide resin is hardened and then patterning is conducted is described. However, before hardening the precursor layer of polyimide resin, patterning may be conducted. As the etching method used for this patterning, a wet etching method or the like may be used. The wet etching may be conducted with, for example, an alkaline solution or an organic solution.

When the steps described above are completed, an electrode 28 on the first mirror 21, and electrodes 35 and 41 on the upper surface of the first contact layer 31 are formed, and an electrode 26 on the contact layer 24 and electrodes 36 and 42 on the second contact layer 33 are formed (see FIG. 6B). In this exemplary embodiment, the electrode 36 has a connecting section 36a having a ring-shaped plane configuration, a lead-out section 36b having a linear plane configuration, and a pad section 36c having a circular plane configuration. It is noted that the connecting section 36a is formed on the upper surface of the second contact layer 33, and the lead-out section 36b and the pad section 36c are formed on the insulation layer 50.

An exemplary method for forming the electrodes 28, 35 and 41 is described below. First, before forming the electrodes 28, 35 and 41, the upper surface of the first mirror 21 and the upper surface of the first contact layer 31 are washed by a plasma processing method or the like, if necessary. As a result, an element with more stable characteristics can be formed. Next, a laminated layered film of, for example, an alloy of chrome (Cr), gold (Au) and germanium (Ge), nickel (Ni) and gold (Au) is formed by, for example, a vacuum deposition method. Then, the electrodes 28, 35 and 41 are formed by removing portions of the laminated layered film other than specified positions by a lift-off method.

Further, an exemplary method for forming the electrodes 26, 36 and 42 is described below. First, before forming the electrodes 26, 36 and 42, the upper surface of the contact layer 24 and the upper surface of the second contact layer 33 are washed by a plasma processing method or the like, if necessary. As a result, an element with more stable characteristics can be formed. Next, a laminated layered film of, for example, an alloy of chrome (Cr), gold (Au) and zinc (Zn), and gold (Au) is formed by, for example, a vacuum deposition method. Then, the electrodes 26, 36 and 42 are formed by removing portions of the laminated layered film other than specified positions by a lift-off method.

It is noted that in the process of forming the electrodes 28, 36 and 41 and electrodes 26, 36 and 42 described above, a dry etching method or a wet etching method may be used instead of a lift-off method. Also, in the above-described process, a sputtering method may be used instead of a vacuum deposition method. Moreover, although the electrodes 28, 36 and 41 are concurrently patterned, and the electrodes 26, 36 and 42 are concurrently patterned in the process described above, these electrodes may be formed individually from one another.

When the process described above is completed, electrode wirings 51 and 52 are formed. It is noted that the electrode wiring 51 is formed in a manner to electrically connect the electrode 26 of the surface-emitting type semiconductor laser 20 with the electrode 41 of the electrostatic breakdown protection element 40. Further, the electrode wiring 52 is formed in a manner to electrically connect the electrode 28 of the surface-emitting type semiconductor laser 20 with the electrode 42 of the electrostatic breakdown protection element 40. In other words, just like the aforementioned case of forming the electrodes, surfaces above the semiconductor substrate 11 are washed by using a plasma processing method or the like according to the necessity. Next, a metal film composed of, for example, gold (Au) is formed by, for example, a vacuum deposition method. Then, portions of the metal film other than the specified positions are removed, thereby forming the electrode wirings 51 and 52.

Finally, an annealing treatment is conducted. The temperature of the annealing treatment is decided according to the electrode material. For example, the annealing treatment is conducted at about 400° C. It is noted that the annealing treatment may be conducted before the electrode wirings 51 and 52 are formed, if necessary. By the process described above, the optical semiconductor element 10 is manufactured. In the present exemplary embodiment, the photodetecting element 30 and the electrostatic breakdown protection element 40 are formed through common process steps. For this reason, the optical semiconductor element 10 whose electrostatic breakdown voltage is improved can be manufactured without making the manufacturing process more complex.

According to the optical semiconductor element 10 and its manufacturing method in accordance with the embodiment of the invention, the pad sections 51c and 52c of the surface-emitting type semiconductor laser 20 are made independent from the pad sections 35c and 36c of the photodetecting element 30, such that drive signals capable of high-speed driving such as differential driving can be applied to the pad sections 51c and 52c. As a result, the surface-emitting type semiconductor laser 20 can be driven at high speed.

Furthermore, in accordance with the present embodiment, the electrostatic breakdown protection element 40 is connected in parallel with the surface-emitting type semiconductor laser 20, such that, even when a voltage in a reverse bias is applied to the surface-emitting type semiconductor laser 20, its electrostatic breakdown voltage against a reverse bias can be substantially improved.

According to the present embodiment, the electrostatic breakdown protection element 40 may be provided with a layer structure that is identical with at least a part of the surface-emitting type semiconductor laser 20 and the photodetecting element 30. As a result, the electrostatic breakdown protection element 40 can be manufactured concurrently with the surface-emitting type semiconductor laser 20 and the photodetecting element 30, and the process for manufacturing the electrostatic breakdown protection element 40 can be simplified.

### Second Embodiment

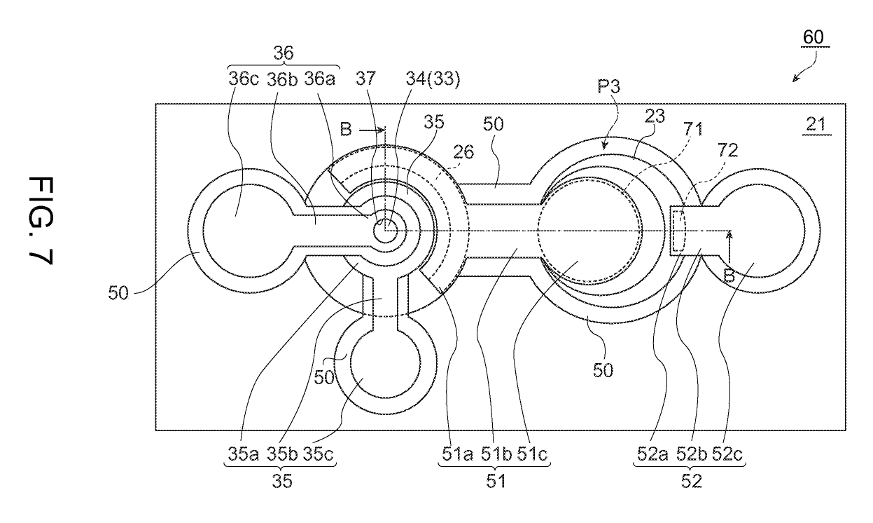

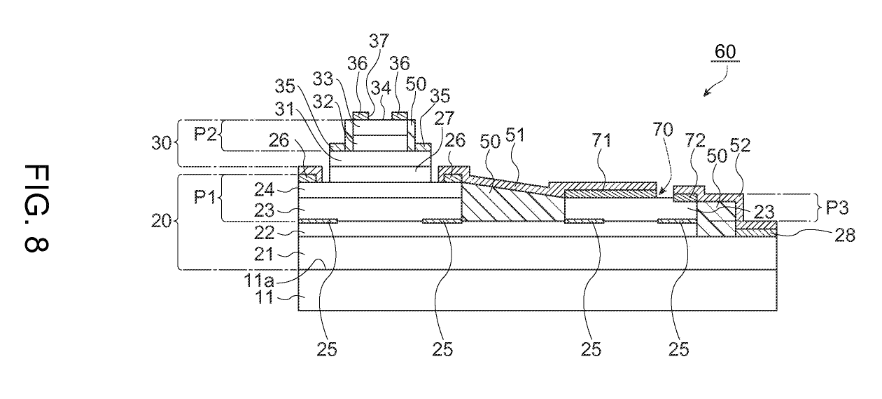

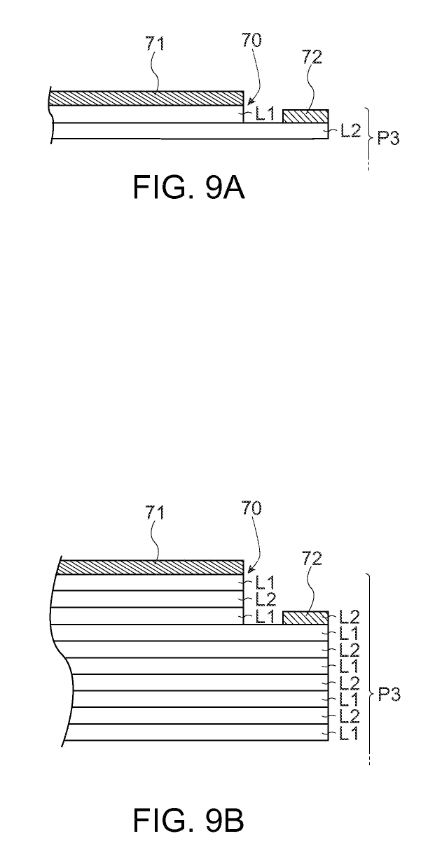

Next, a second embodiment of the invention is described with reference to the accompanying drawings. It is noted that, in the following description, components of the second embodiment similar to the components described in the first embodiment are appended with the same reference numerals, and their description is omitted. FIG. 7 is a plan view schematically showing an optical semiconductor element, FIG. 8 is a cross-sectional view taken along a line B-B of FIG. 7, and FIG. 9 is a partially enlarged view of a third columnar section shown in FIG. 8. The second embodiment is different from the first embodiment in that an electrostatic breakdown protection element 70 in an optical semiconductor element 60 of the second embodiment is formed only with a third columnar section P3.

More concretely, as shown in FIG. 7 and FIG. 8, the electrostatic breakdown protection element 70 is formed with a third columnar section P3 that is formed only with a second mirror 23, and does not have a fourth columnar section P4 formed therein. The second mirror 23 includes a structure of alternately laminated p-type Al_{0.9}Ga_{0.1}As layers (hereafter referred to as first layers) and p-type Al_{0.15}Ga_{0.85}As layers (hereafter referred to as second layers), like the first embodiment described above, and one of the layers is exposed at the top surface of the third columnar section P3. It is noted that, in this exemplary embodiment, the first layer is exposed at the top surface of the third columnar section P3.

As shown in FIG. 9A, a first layer L1 and a second layer L2 are laminated in the uppermost section of the third columnar section P3. Also, at the uppermost section of the third columnar section P3, a portion of the first layer L1 located at the top is removed, and the second layer L2 is exposed at the upper surface of the third columnar section P3 at this portion. Further, an electrode 71 is formed on the first layer L1 located at the top of the third columnar section P3, and an electrode 72 is formed on the second layer L2 that is exposed at the top surface of the third columnar section P3. The junction between the electrode 71 and the first layer L1 located at the top of the third columnar section P3 is a Schottky junction, which forms an electrostatic breakdown protection element 70. In other words, a layer structure identical with a portion of the first mirror 21 forming the surface-emitting type semiconductor laser 20 is used to form the electrostatic breakdown protection element 70.

As the electrode 71 that forms a Schottky junction, a multilayer film of titanium (Ti), platinum (Pt) and gold (Au), a metal film composed of aluminum (Al), a metal film composed of an alloy of aluminum (Al) and gold (Au), or the like can be used, as the first layer L1 is a p-type Al_{0.9}Ga_{0.1}As layer. Also, just like the electrodes 26, 36 and 42 described above, the electrode 72 that is formed on the second layer L2 can be formed with, for example, a multilayer film of an alloy of chrome (Cr), gold (Au) and zinc (Zn), and gold (Au), a multilayer film of platinum (Pt), titanium (Ti) and gold (Au), or the like.

Also, an electrode wiring 51 is formed on the electrode 71, as shown in FIG. 8. By this, the electrode 71 is electrically connected to the electrode 26 of the surface-emitting type semiconductor laser 20. Also, an electrode wiring 52 is formed on the electrode 72. By this, the electrode 72 is electrically connected to the electrode 28 of the surface-emitting type semiconductor laser 20. Accordingly, in the optical semiconductor element 60, the electrostatic breakdown protection element 70 is connected in parallel with the surface-emitting type semiconductor laser 20 by the electrode wirings 51 and 52 so as to have a reverse polarity (a rectification action in a reverse direction) with respect to the surface-emitting type semiconductor laser 20. For this reason, even when a voltage in a reverse direction is applied across the electrode 26 and the electrode 28 of the surface-emitting type semiconductor laser 20, the current flows through the electrostatic breakdown protection element 70, and therefore the surface-emitting type semiconductor laser 20 can be protected from electrostatic destruction.

In the present embodiment, as shown in FIG. 9A, the electrode 71 and the electrode 72 are formed on the first layer L1 and the second layer L2 that form a pair, respectively. However, as shown in FIG. 9B, the electrode 71 may be formed on the first layer L1 in one pair, and the electrode 72 may be formed on the second layer L2 in another pair different from the aforementioned pair. Also, FIG. 9B shows a structure in which a first layer L1 and a second layer L2 are formed between the first layer L1 (the first layer L1 located at the top) on which the electrode 71 is formed and the first layer L1 on which the electrode 72 is formed, but layers to be provided between them can be in any arbitrary number. Also, in the illustrated embodiment, the layer at the top of the third columnar section P3 is the first layer L1. However, the layer at the top of the third columnar section P3 can be the second layer L2. In other words, the electrode 71 may be formed on the second layer L2, and the electrode 72 may be formed on the first layer L1.

The optical semiconductor element 60 in accordance with the present embodiment exhibits action and effect similar to those of the first embodiment described above. In other words, although the step of forming the electrode 71 is necessary to obtain a Schottky junction, dedicated steps to form the electrostatic breakdown protection element 70 are not necessary.

### Third Embodiment

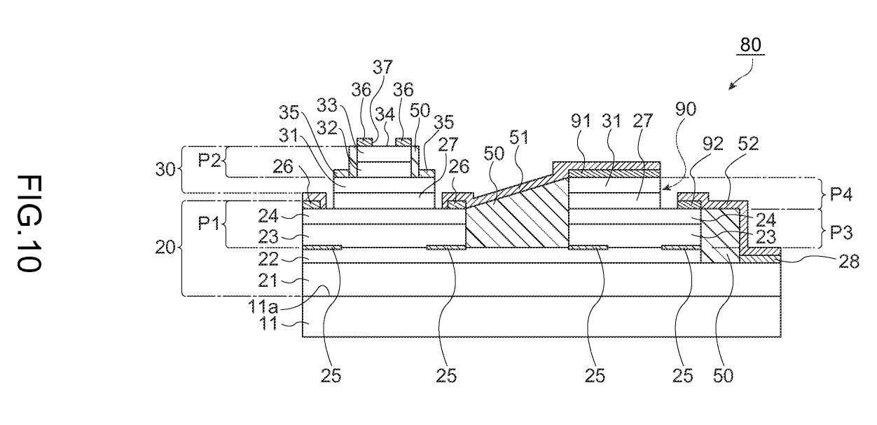

Next, a third embodiment of the invention is described with reference to the accompanying drawings. It is noted that, in the following description, components of the third embodiment similar to the components described in the above-described embodiments are appended with the same reference numerals, and their description is omitted. FIG. 10 is a plan view schematically showing an optical semiconductor element. The third embodiment is different from the first embodiment in that an electrostatic breakdown protection element 90 in an optical semiconductor element 80 of the third embodiment is composed of a contact layer 24, an isolation layer 27 and a first contact layer 31.

More concretely, as shown in FIG. 10, the third columnar section P3 is formed from the second mirror 23 and the contact layer 24. Further, a fourth columnar section P4 is formed from the isolation layer 27 and the first contact layer 31. It is noted that, in the present embodiment, the fourth columnar section P4 has a diameter smaller than that of the third columnar section P3. Also, the contact layer 24 and the isolation layer 27 form a heterojunction, and the first contact layer 31 and the isolation layer 27 form a heterojunction. In other words, the electrostatic breakdown protection element 90 is formed with the same layer structure as that of the contact layer 24 forming the surface-emitting type semiconductor laser 20 and the first contact layer 31 forming the photodetecting element 30.

Also, an electrode 91 is formed on an upper surface (on the first contact layer 31) of the fourth columnar section P4, and an electrode 92 is formed on an upper surface (on the contact layer 24) of the third columnar section P3. The electrode 91 may be formed from a multilayer film of, for example, an alloy of chrome (Cr), gold (Au) and germanium (Ge), nickel (Ni) and gold (Au). Also, the electrode 92 may be formed from a multilayer film of, for example, an alloy of chrome (Cr), gold (Au) and zinc (Zn), and gold (Au), a multilayer film of, for example, platinum (Pt), titanium (Ti) and gold (Au), or the like.

Also, an electrode wiring 51 is formed on the electrode 91, as shown in FIG. 10. By this, the electrode 91 is electrically connected to the electrode 26 of the surface-emitting type semiconductor laser 20. Also, an electrode wiring 52 is formed on the electrode 92. By this, the electrode 92 is electrically connected to the electrode 28 of the surface-emitting type semiconductor laser 20. Accordingly, in the optical semiconductor element 80, the electrostatic breakdown protection element 90 is connected in parallel with the surface-emitting type semiconductor laser 20 by the electrode wirings 51 and 52 so as to have a reverse polarity (a rectification action in a reverse direction) with respect to the surface-emitting type semiconductor laser 20. For this reason, when a voltage in a reverse direction is applied across the electrode 26 and the electrode 28 of the surface-emitting type semiconductor laser 20, the current flows through the electrostatic breakdown protection element 70, and therefore the surface-emitting type semiconductor laser 20 can be protected from electrostatic destruction.

The optical semiconductor element 80 in accordance with the present embodiment exhibits action and effect similar to those of the embodiments described above. In other words, the electrostatic breakdown protection element 90 is formed through devising the etching process for forming the surface-emitting type semiconductor laser 20 and the photodetecting element 30. Accordingly, dedicated steps to form the electrostatic breakdown protection element 90 are not necessary.

### Fourth Embodiment

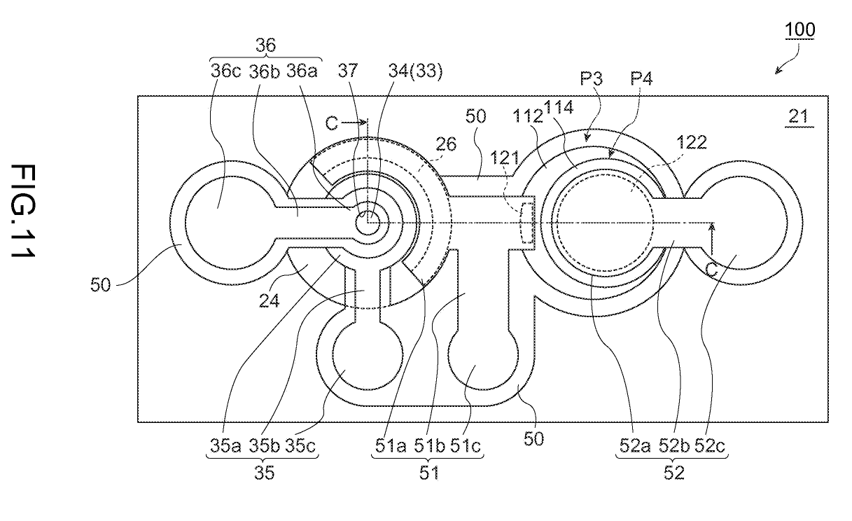

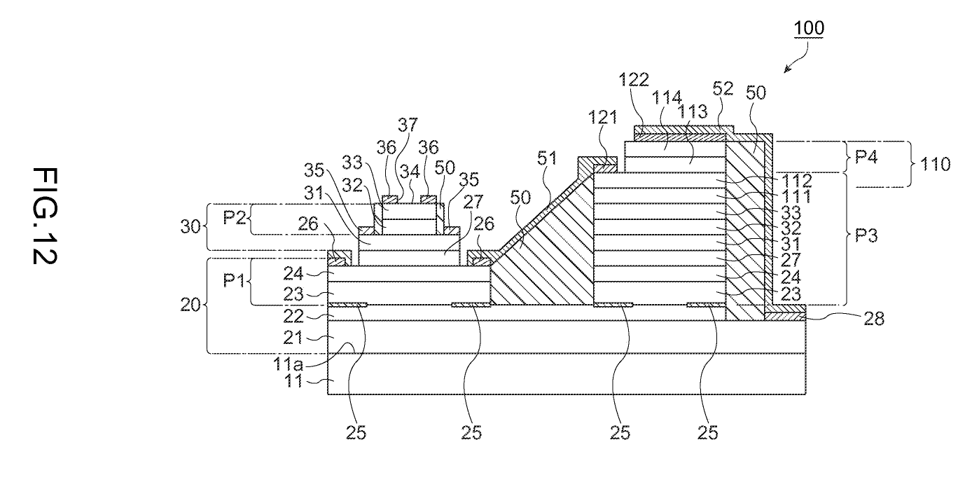

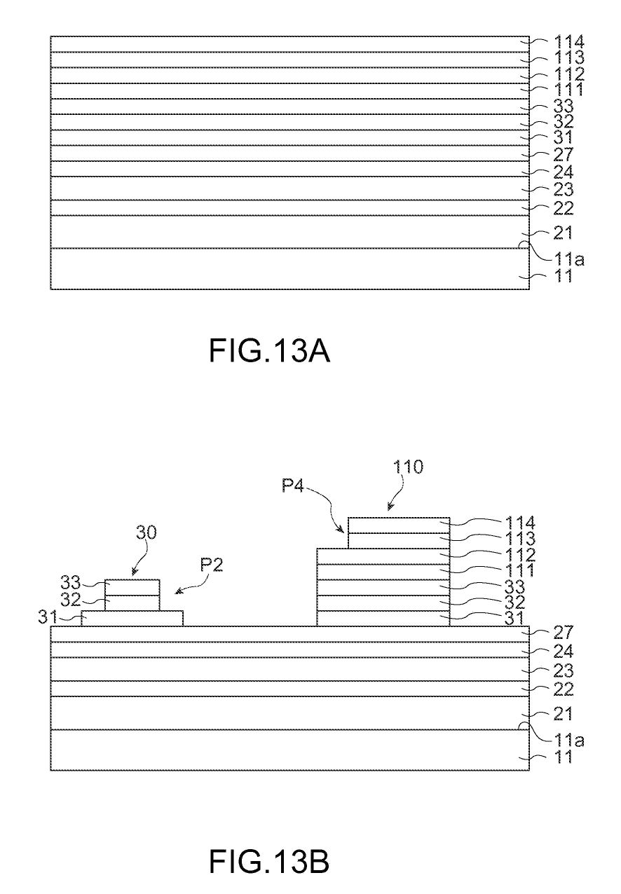

Next, a fourth embodiment of the invention is described with reference to the accompanying drawings. It is noted that, in the following description, components of the fourth embodiment similar to the components described in the above-described embodiments are appended with the same reference numerals, and their description is omitted. FIG. 11 is a plan view schematically showing an optical semiconductor element. FIG. 12 is a cross-sectional view taken along a line C-C of FIG. 11, and FIGS. 13-16 are views showing steps of manufacturing an optical semiconductor element in accordance with the present embodiment. The fourth embodiment is different from the first embodiment in that an electrostatic breakdown protection element 110 in an optical semiconductor element 100 of the fourth embodiment has a different layer structure from the layer structure of the surface-emitting type semiconductor laser 20 and the layer structure of the photodetecting element 30.

More specifically, the electrostatic breakdown protection element 110 has a third columnar section P3 that is composed of a second mirror 23, a contact layer 24, an isolation layer 27, a first contact layer 31, a absorption layer 32, a second contact layer 33, an isolation layer 111 and a first contact layer 112, and a fourth columnar section P4 that is composed of a dielectric breakdown protection layer 113 and a second contact layer 114. In this manner, the electrostatic breakdown protection element 110 has a layer structure that is different from the layer structure of the surface-emitting type semiconductor laser 20 and the layer structure of the photodetecting element 30. For this reason, the structures of the surface-emitting type semiconductor laser 20, the photodetecting element 30 and the electrostatic breakdown protection element 110 can be made optically and electrically optimum, respectively.

The isolation layer 111 formed in the third columnar section P3 is provided to isolate a pin diode composed of the first contact layer 31, the absorption layer 32 and the second contact layer 33 in a lower section of the third columnar section P3 from the electrostatic breakdown protection element 110, and is formed with compositions similar to those of the isolation layer 27. The first contact layer 112 composing the electrostatic breakdown protection element 110 may be composed of an n-type GaAs layer that is made to be n-type by doping, for example, silicon (Si). The dielectric breakdown protection layer 113 may be composed of a GaAs layer without impurity being doped. The second contact layer 114 may be composed of a p-type GaAs layer that is made to be p-type by doping, for example, carbon (C). Accordingly, the electrostatic breakdown protection element 110 includes a pin diode formed by the first contact layer 112, the dielectric breakdown protection layer 113 and the second contact layer 114.

Further, an electrode 121 in a generally rectangular shape as viewed in a plan view is formed on the first contact layer 112 composing the electrostatic breakdown protection element 110 on the side opposite to the first columnar section P1 and the second columnar section P2. The electrode 121 is formed with compositions similar to those of the electrode 41 of the embodiment described above. An electrode 122 is formed on the second contact layer 114 composing the electrostatic breakdown protection element 110. The electrode 122 is formed with compositions similar to those of the electrode 42 of the embodiment described above.

Also, an electrode wiring 51 is formed on the electrode 121, as shown in FIG. 12. By this, the electrode 121 is electrically connected to the electrode 26 of the surface-emitting type semiconductor laser 20. Also, an electrode wiring 52 is formed on the electrode 122. By this, the electrode 122 is electrically connected to the electrode 28 of the surface-emitting type semiconductor laser 20. Accordingly, in the optical semiconductor element 100, the electrostatic breakdown protection element 110 is connected in parallel with the surface-emitting type semiconductor laser 20 by the electrode wirings 51 and 52 so as to have a reverse polarity (a rectification action in a reverse direction) with respect to the surface-emitting type semiconductor laser 20. For this reason, when a voltage in a reverse direction is applied across the electrode 26 and the electrode 28 of the surface-emitting type semiconductor laser 20, the current flows through the electrostatic breakdown protection element 110, and therefore the surface-emitting type semiconductor laser 20 can be protected from electrostatic destruction.

Method for Manufacturing Optical Semiconductor Element

Next, a method for manufacturing an optical semiconductor element 100 having the structure described above is described. First, like the first embodiment described above, on a surface 11a of a semiconductor substrate 11 composed of an n-type GaAs layer, a semiconductor multilayer film is formed by epitaxial growth while modifying its composition (see FIG. 13A). The semiconductor multilayer film is composed of a first mirror 21, an active layer 22, a second mirror 23, an isolation layer 27, a first contact layer 31, a absorption layer 32, a second contact layer 33, an isolation layer 111 composed of an AlGaAs layer in which no impurity is doped, a first contact layer 112 composed of an n-type GaAs layer, a dielectric breakdown protection layer 113 composed of a GaAs layer in which no impurity is doped, and a second contact layer 114 composed of a p-type GaAs layer. The aforementioned layers are sequentially laminated on the semiconductor substrate 11, thereby forming the semiconductor multilayer film. It is noted that the isolation layer 111 may be made with a p-type or n-type AlGaAs layer.

Next, a second columnar section P2 and a fourth columnar section P4 are formed (see FIG. 13B). To form the fourth columnar section P4, first, resist (not shown) is coated on the semiconductor multilayer film, and then the resist is patterned by a photolithography method. As a result, a resist layer having a specified plane configuration is formed on the upper surface of the second contact layer 114. Then, by using the resist layer as a mask, the second contact layer 114 and the dielectric breakdown protection layer 113 are etched by, for example, dry etching. As a result, the second contact layer 114 and the dielectric breakdown protection layer 113 having the same plane configuration as that of the second contact layer 114 are formed. By the steps described above, the fourth columnar section P4 is formed. It is noted that the resist layer described above is removed after the fourth columnar section P4 is formed.

Then, a resist layer that covers the fourth columnar section P4 is formed. Then, by using the resist layer as a mask, the first contact layer 112 and a portion of the isolation layer 111 to an intermediate point thereof are etched by, for example, a dry etching method. By this, an electrostatic breakdown protection element is formed. The electrostatic breakdown protection element 110 includes a second contact layer 43, a dielectric breakdown protection layer 113, and a first contact layer 112. The first contact layer 112 is formed with a plane configuration greater than the plane configuration of the second contact layer 43 and the dielectric breakdown protection layer 113. The resist layer is removed after the electrostatic breakdown protection element 110 is formed. It is noted that, according to the present embodiment, the second contact layer 114 and the dielectric breakdown protection layer 113 are patterned first, and then the first contact layer 112 is patterned. However, the first contact layer 112 may be patterned first, and then the second contact layer 114 and the dielectric breakdown protection layer 113 may be patterned.

Next, to form the second columnar section P2, first, the step of exposing the second contact layer 33 at the uppermost section of the second columnar section P2 is conducted. It is noted that the second contact layer 33 is exposed because the characteristics of the surface-emitting type semiconductor laser 20 are deteriorated if the sum of optical film thickness of the layers (i.e., the first contact layer 31, the absorption layer 32 and the second contact layer 33) composing the photodetecting element 30 deviates from, for example, an odd multiple of λ/4.

Because it is difficult to accurately control the amount of etching by dry etching, the etching process described above is conducted in a manner that the isolation layer 111 is etched to an intermediate point thereof, and the remaining portion of the isolation layer 111 is etched by selective etching thereby exposing the second contact layer 33. In other words, first, a resist layer that covers the fourth columnar section P4 and the upper portion of the third columnar section P3 and is patterned in a predetermined shape is formed. Then, the remaining portion of the isolation layer 111 is etched by a wet etching method. As an etchant for etching the isolation layer 111, for example, a hydrogen fluoride solution or a hydrofluoric acid system buffer solution can be used. By this, the second contact layer 33 functions as an etching stopper layer, such that etching of the isolation layer 111 can be accurately and readily stopped at the time when the second contact layer 33 is exposed.

Next, after coating resist (not shown), the resist is patterned by a photolithography method. By this, a resist layer is formed in areas that cover the upper surface of the fourth columnar section P4 and the third columnar section P3, and at locations where the second columnar section P2 above the second contact layer 33 is to be formed. By using the resist layer as a mask, the second contact layer 33 and the absorption layer 32 are etched by, for example, a dry etching method. As a result, the second contact layer 33 and the absorption layer 32 having the same plane configuration as that of the second contact layer 33 are formed. By this, the second columnar section P2 and the fourth columnar section P4 are formed. It is noted that the resist layer is removed after the second columnar section P2 is formed.

After the fourth columnar section P4 and the second columnar section P2 are formed, the first contact layer 31 is patterned, like the first embodiment described above, whereby the photodetecting element 30 and the electrostatic breakdown protection element 110 are formed. In this manner, according to the present embodiment, the photodetecting element 30 and the electrostatic breakdown protection element 110 are formed by different steps.

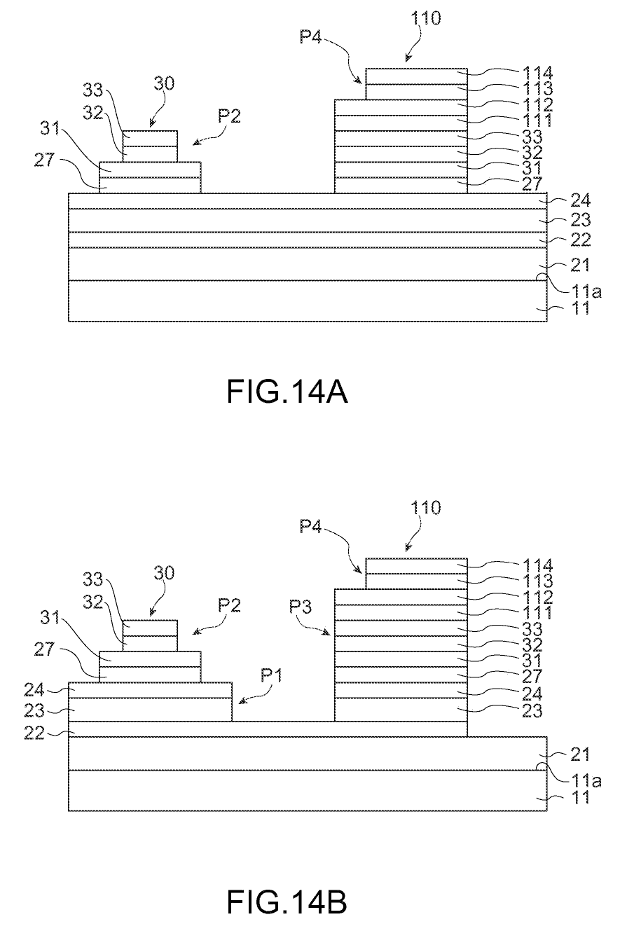

After the photodetecting element 30 and the electrostatic breakdown protection element 110 are formed, the isolation layer 27 is patterned in a predetermined configuration, like the first embodiment described above (see FIG. 14A), and the contact layer 24, the second mirror 23 and the active layer 22 are patterned, whereby the first columnar section P1 and the third columnar section P3 are formed (see FIG. 14B). As a result, a vertical resonator (surface-emitting type semiconductor laser 20) including the first columnar section P1 is formed on the semiconductor substrate 11.

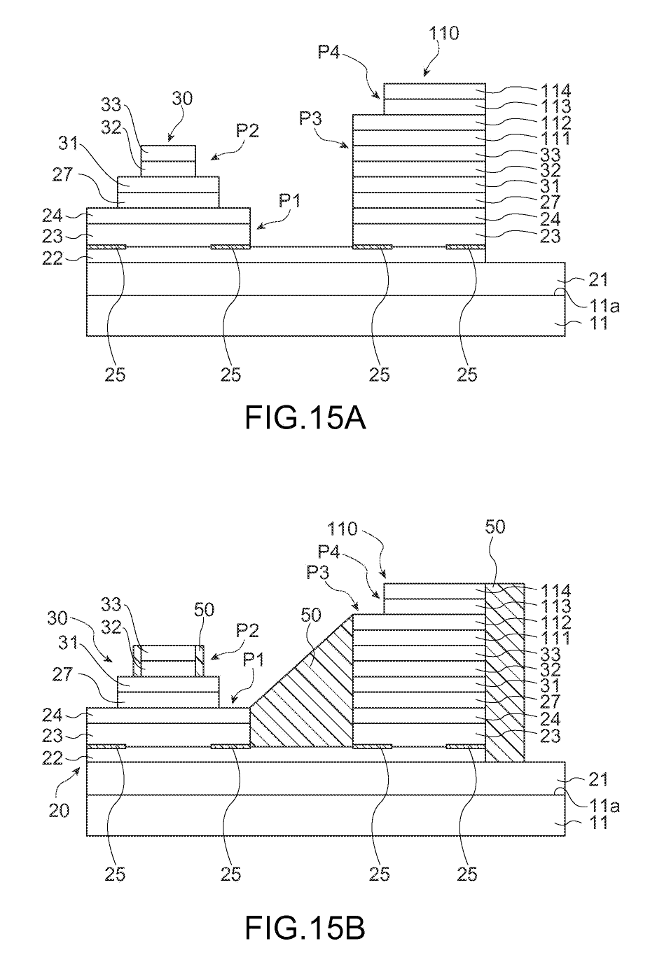

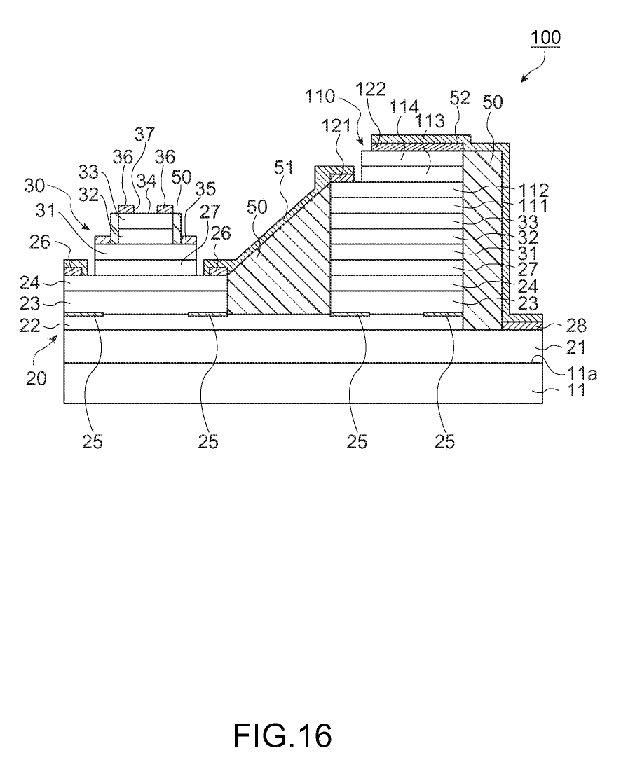

Then, a current constricting layer 25 is formed (see FIG. 15A), and an insulation layer 50 is formed on the active layer 22, around the first columnar section P1 and the third columnar section P3 on the first mirror 21, and around the second columnar section P2 (see FIG. 15B). Then, an electrode 28 on the first mirror 21 and an electrode 35 on the upper surface of the first contact layer 31 are formed; and an electrode 26 on the contact layer 24, an electrode 36 on the second contact layer 33, and electrode 121 on the first contact layer 112 and an electrode 122 on the second contact layer 114 are formed (see FIG. 16).

Then, electrode wirings 51 and 53 are formed. It is noted that the electrode wiring 51 is formed in a manner to electrically connect the electrode 26 of the surface-emitting type semiconductor laser 20 with the electrode 121 of the electrostatic breakdown protection element 110. Further, the electrode wiring 52 is formed in a manner to electrically connect the electrode 28 of the surface-emitting type semiconductor laser 20 with the electrode 122 of the electrostatic breakdown protection element 110. Finally, an annealing treatment is conducted. In this manner, the optical semiconductor element 100 is manufactured. It is noted here that the photodetecting element 30 and the electrostatic breakdown protection element 110 in accordance with the present embodiment are formed by independent steps. Accordingly, these elements can be readily formed by devising the etching steps, and therefore the optical semiconductor element 100 whose electrostatic breakdown voltage is improved can be manufactured without making the manufacturing process more complex.

It is noted here that, although the photodetecting element 30 and the electrostatic breakdown protection element 110 in accordance with the present embodiment are formed by independent steps, the optical semiconductor element 100 also exhibits action and effect similar to those of the other embodiments described above. Because these elements can be readily formed by devising the etching steps, the optical semiconductor element 100 with improved electrostatic breakdown voltage can be manufactured without complicating the manufacturing process.

### Fifth Embodiment

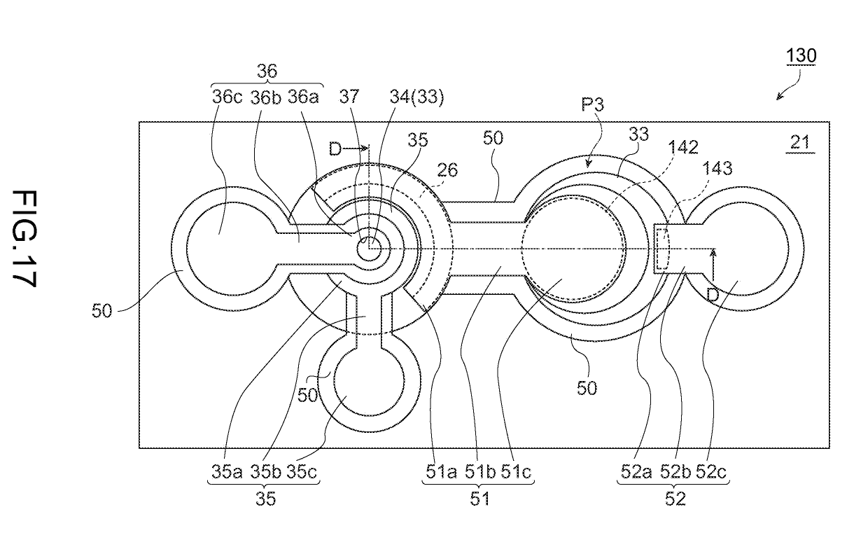

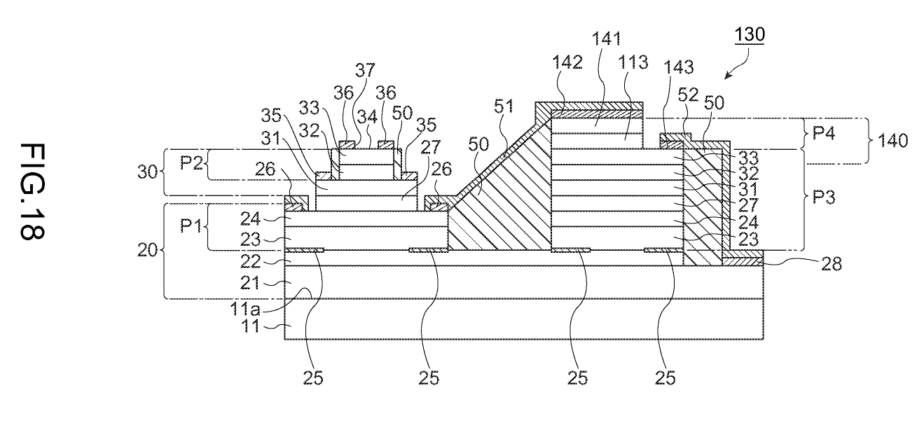

Next, a fifth embodiment of the invention is described with reference to the accompanying drawings. It is noted that, in the following description, components of the fifth embodiment similar to the components described in the above-described embodiments are appended with the same reference numerals, and their description is omitted. FIG. 17 is a plan view schematically showing an optical semiconductor element, and FIG. 18 is a cross-sectional view taken along a line D-D of FIG. 17. The fifth embodiment is different from the fourth embodiment in that an electrostatic breakdown protection element 140 in an optical semiconductor element 130 of the fifth embodiment is formed from a dielectric breakdown protection layer 113 and a contact layer 141 laminated on a second contact layer 33.

In other words, the electrostatic breakdown protection element 140 includes the same layer as the second contact layer 33 composing the photodetecting element 30. A contact layer 141 deposited on the dielectric breakdown protection layer 113 is composed of an n-type GaAs layer that is made to be n-type by doping, for example, silicon (Si), like the first contact layer 112. Accordingly, the electrostatic breakdown protection element 140 forms a pin diode by the p-type second contact layer 33, the dielectric breakdown protection layer 113 in which no impurity is doped, and the n-type contact layer 141.

It is noted that the second contact layer 33 is formed in a third columnar section P3 and the dielectric breakdown protection layer 113 and the contact layer 141 are formed in a fourth columnar section P4. The third columnar section P3 is etched in a circular shape as viewed in a plan view, and the fourth columnar section P4 is etched in a circular shape as viewed in a plan view. Also, as shown in FIG. 17 and FIG. 18, the fourth columnar section P4 is formed to have a diameter smaller than the diameter of the third columnar section P3, and is formed in a state in which the fourth columnar section P4 is eccentric in a direction shifted toward the first columnar section P1 and the second columnar section P2 so as not to be concentric with the third columnar section P3. It is noted that, although the fourth columnar section P4 is eccentric with respect to the third columnar section P3 in this embodiment, they can be made concentric with each other.

Also, an electrode 142 is formed on an upper surface of the fourth columnar section P4 (on the contact layer 141), and an electrode 143 is formed on an upper surface of the third columnar section P3 (on the second contact layer 33). The electrode 142 is formed from a multilayer film of, for example, an alloy of chrome (Cr), gold (Au) and germanium (Ge), nickel (Ni) and gold (Au). The electrode 143 is formed from a multilayer film of, for example, an alloy of chrome (Cr), gold (Au) and zinc (Zn), and gold (Au), a multilayer film of platinum (Pt), titanium (Ti) and gold (Au), or the like.

Further, an electrode wiring 51 is formed on the electrode 142. By this, the electrode 142 is electrically connected with the electrode 26 of the surface-emitting type semiconductor laser 20. Also, an electrode wiring 52 is formed on the electrode 143. By this, the electrode 143 is electrically connected with the electrode 28 of the surface-emitting type semiconductor laser 20. Accordingly, in the optical semiconductor element 130, the electrostatic breakdown protection element 140 is connected in parallel with the surface-emitting type semiconductor laser 20 by the electrode wirings 51 and 52 so as to have a reverse polarity (a rectification action in a reverse direction) with respect to the surface-emitting type semiconductor laser 20. For this reason, even when a voltage in a reverse direction is applied across the electrode 26 and the electrode 28 of the surface-emitting type semiconductor laser 20, the current flows through the electrostatic breakdown protection element 140, and therefore the surface-emitting type semiconductor laser 20 can be protected from electrostatic destruction.

In the fifth embodiment, the isolation layer 111 and the first contact layer 112 that are required in the fourth embodiment are omitted, and the second contact layer 33 is shared by the photodetecting element 30 and the electrostatic breakdown protection element 140. Accordingly, in the fifth embodiment, the epitaxial layers are reduced by two layers compared with the fourth embodiment, such that the number of manufacturing steps can be reduced and the material cost can also be reduced. Further, the dielectric breakdown protection layer 113 of the electrostatic breakdown protection element 140 is not used in the photodetecting element 30, and therefore the film thickness of the dielectric breakdown protection layer 113 can be appropriately set in a manner that the electrical characteristics of the electrostatic breakdown protection element 140 become optimized.

According to the optical semiconductor element 130 in accordance with the present embodiment, action and effect similar to those of the fourth embodiment described above can be obtained.

Exemplary embodiments of the invention are described above. However, the invention is not limited to the embodiments described above, and changes can be freely made within the scope of the invention. For example, in the embodiments described above, optical elements in which the photodetecting element 30 is provided above the surface-emitting type semiconductor laser 20 are described as examples. However, the invention is also applicable to optical elements having a structure described in, for example, Japanese Examined Patent Application Publication JP-B-7-56552 and Japanese Laid-open Patent Application JP-A-6-37299, in which a surface-emitting type semiconductor laser is provided above a photodetecting element.

Also, in the embodiments described above, the photodetecting element is provided to detect the light intensity of laser light emitted from the surface-emitting type semiconductor laser. However, the photodetecting element can also be used to detect external light. More specifically, for example, the optical element may be used for optical communications, wherein laser light emitted from the surface-emitting type semiconductor laser may be used for optical signals to be transmitted, and optical signals transmitted can be detected by the photodetecting element. Optical signals received by the photodetecting element are extracted as electrical signals. Moreover, for example, interchanging the p-type and n-type characteristics of each of the semiconductor layers in the above described embodiments does not deviate from the subject matter of the present invention. Moreover, in the embodiments described above, examples in which the electrostatic breakdown protection element is a pin diode (an element that forms a PIN junction) are described. However, an electrostatic breakdown protection element in accordance with the invention can be formed with an element that forms a PN junction, a heterojunction, or a Schottky junction.

### Sixth Embodiment

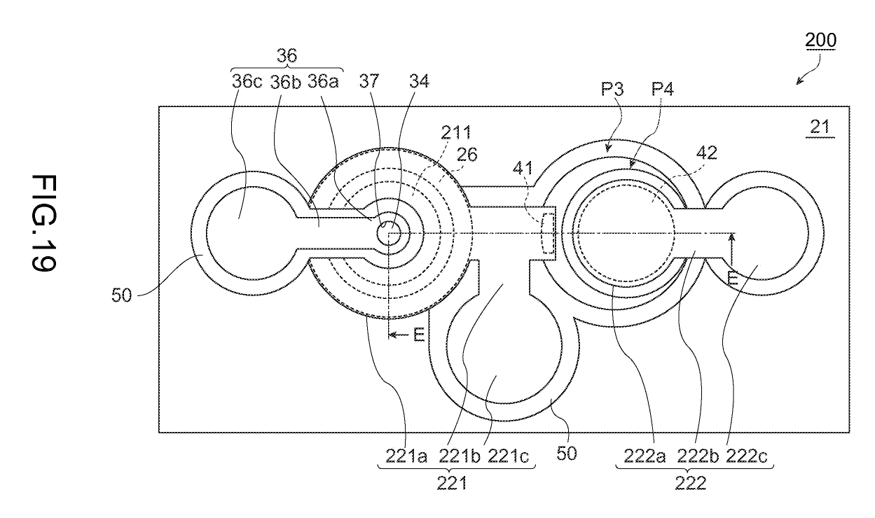

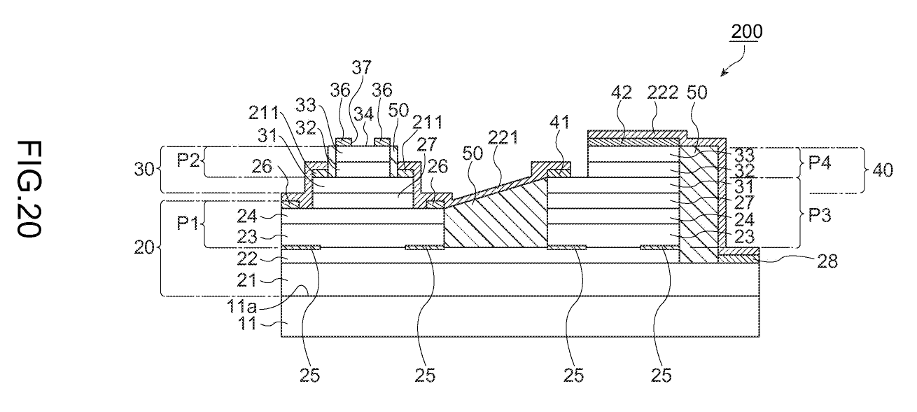

Next, a sixth embodiment of the invention is described with reference to the accompanying drawings. FIG. 19 is a plan view schematically showing an optical semiconductor element in accordance with a sixth embodiment of the invention, and FIG. 20 is a cross-sectional view taken along a line E-E of FIG. 19. As shown in FIG. 20, an optical semiconductor element 200 has a structure including a surface-emitting type semiconductor laser 20, a photodetecting element 30 as a photodetecting element, and an electrostatic breakdown protection element 40. The structure of each of the elements and the overall structure of the optical semiconductor element 200 are described below.

Surface-Emitting Type Semiconductor Laser

The surface-emitting type semiconductor laser 20 is formed on a semiconductor substrate 11 (an n-type GaAs substrate in the present embodiment). The surface-emitting type semiconductor laser 20 has a vertical resonator, wherein one of distributed Bragg reflectors that compose the vertical resonator is formed in a semiconductor deposited body (hereafter referred to as a first columnar section) P1. In other words, the surface-emitting type semiconductor laser 20 has a portion included in the first columnar section P1.

The surface-emitting type semiconductor laser 20 has a multilayered structure and is formed from, for example, a distributed Bragg reflector of 40 pairs of alternately laminated n-type Al_{0.9}Ga_{0.1}As layers and n-type Al_{0.15} Ga_{0.85}As layers (hereafter called a “first mirror”) 21, an active layer 22 composed of GaAs well layers and Al_{0.3}Ga_{0.7}As barrier layers in which the well layers include a quantum well structure composed of three layers, a distributed Bragg reflector of 25 pairs of alternately laminated p-type Al_{0.9}Ga_{0.1}As layers and p-type Al_{0.15} Ga_{0.85}As layers (hereafter called a “second mirror”) 23, and a contact layer 24 composed of p-type GaAs, which are successively stacked in layers.

In the present embodiment, the Al composition of an AlGaAs layer is a composition of aluminum (Al) with respect to gallium (Ga). The Al composition of an AlGaAs layer may range from “0” to “1.” In other words, an AlGaAs layer may include a GaAs layer (with the Al composition being “0”) and an AlAs layer (with the Al composition being “1”). Also, the composition of each of the layers and the number of the layers forming the first mirror 21, the active layer 22, the second mirror 23 and the contact layer 24 are not limited to the above.

The first mirror 21 composing the surface-emitting type semiconductor laser 20 is made to be n-type by doping, for example, silicon (Si), and the second mirror 23 is made to be p-type by doping, for example, carbon (C). Accordingly, the p-type second mirror 23, the active layer 22 in which no impurity is doped and the n-type first mirror 21 form a pin diode. Also, among the surface-emitting type semiconductor laser 20, the second mirror 23 and the contact layer 24 are etched in a circular shape as viewed in a plan view from above the second mirror 23, thereby forming the first columnar section P1. It is noted that the first columnar section P1 is given a plane configuration of a circular shape in this embodiment, but can be in any another shape.

A current constricting layer 25, which is obtained by oxidizing an AlGaAs layer from its side surface, is formed in a region near the active layer 22 among the layers forming the second mirror 23. The current constricting layer 25 is formed in a ring shape. In other words, the current constricting layer 25 has a cross-sectional shape, as cut in a plane horizontal with a surface 11a of the semiconductor substrate 11, which defines a ring shape concentric with a circular plane configuration of the first columnar section P1, as shown in FIG. 19 and FIG. 20.

An electrode 26 having a plane configuration in a ring shape is formed along an outer circumference of the first columnar section P1 on the contact layer 24. The electrode 26 may be formed from a multilayer film of, for example, an alloy of chrome (Cr), gold (Au) and zinc (Zn), and gold (Au), or a multilayer film of platinum (Pt), titanium (Ti) and gold (Au). The electrode 26 is provided for driving the surface-emitting type semiconductor laser 20, and a current is injected into the active layer 22 from the electrode 26.

Isolation Layer

The optical semiconductor element 200 in accordance with the present embodiment is equipped with an isolation layer 27 formed on the surface-emitting type semiconductor laser 20. In other words, the isolation layer 27 is provided between the surface-emitting type semiconductor laser 20 and a photodetecting element 30 to be described below. Concretely, as shown in FIG. 20, the isolation layer 27 is formed on the contact layer 24. In other words, the isolation layer 27 is provided between the contact layer 24 of the surface-emitting type semiconductor laser 20 and a first contact layer 31 to be described below of the photodetecting element 30 to be described below. It is noted that, because the electrode 26 in a ring shape is formed on the upper surface of the contact layer 24, as described above, the circumference of the isolation layer 27 is surrounded by the electrode 26.

The isolation layer 27 has a plane configuration in a circular shape. It is noted that the plane configuration of the isolation layer 27 is the same as the plane configuration of a first contact layer 31 in the illustrated example, and formed in a manner that their diameter is smaller than the diameter of the first columnar section P1. It is noted that the plane configuration of the isolation layer 27 may be formed to be greater than the plane configuration of the first contact layer 31. The isolation layer 27 is described in greater detail in conjunction with a method for manufacturing an optical element to be described below.

Photodetecting Element

The photodetecting element 30 is provided on the isolation layer 27. The photodetecting element 30 includes a first contact layer 31, a absorption layer 32, and a second contact layer 33. The first contact layer 31 is provided on the isolation layer 27, the absorption layer 32 is provided on the first contact layer 31, and the second contact layer 33 is provided on the absorption layer 32. The plane configuration of the absorption layer 32 and the second contact layer 33 is made to be smaller than the plane configuration of the first contact layer 31. The second contact layer 33 and the absorption layer 32 compose a columnar semiconductor deposited body (hereafter referred to as a second columnar section) P2. In other words, the photodetecting element 30 has a structure having a portion thereof included in the second columnar section P2. It is noted that the upper surface of the photodetecting element 30 defines an emission surface 34 for emitting laser light from the surface-emitting type semiconductor laser 20.

The first contact layer 31 forming the photodetecting element 30 may be composed of, for example, an n-type GaAs layer, the absorption layer 32 may be composed of, for example, a GaAs layer in which no impurity is doped, and the second contact layer 33 may be composed of, for example, a p-type GaAs layer. More specifically, the first contact layer 31 is made to be n-type by doping, for example, silicon (Si), and the second contact layer 33 is made to be p-type by doping, for example, carbon (C). Accordingly, the n-type first contact layer 31, the absorption layer 32 in which no impurity is doped, and the p-type second contact layer 33 form a pin diode.

An electrode 211 having a plane configuration in a ring shape is formed on the first contact layer 31 along an outer circumference thereof. In other words, the electrode 211 is provided in a manner to surround the second columnar section P2. The electrode 211 is formed from a multilayer film of, for example, an alloy of chrome (Cr), gold (Au) and germanium (Ge), nickel (Ni) and gold (Au).

Further, an electrode 36 is formed on the upper surface of the photodetecting element 30 (on the second contact layer 33). The electrodes 36 and 211 are used for driving the photodetecting element 30. The electrode 36 is provided with an aperture section 37, and a part of the upper surface of the second contact layer 33 is exposed through the aperture section 37. The exposed surface defines an emission surface 34 for emitting laser light. Accordingly, by appropriately setting the plane configuration and the size of the aperture section 37, the configuration and the size of the emission surface 34 can be appropriately set. In accordance with the present embodiment, as shown in FIG. 19, the emission surface 34 may be circular. Also, the electrode 36 may be formed with the same material as that of the electrode 26 formed on the contact layer 24 of the surface-emitting type semiconductor laser 20.

The electrode 36 has, as shown in FIG. 19, a connection section 36a having a ring-shaped plane configuration, a lead-out section 36b having a linear plane configuration, and a pad section 36c having a circular plane configuration. The electrode 36 is electrically connected to the second contact layer 33 at the connection section 36a. The lead-out section 36b of the electrode 36 connects the connection section 36a and the pad section 36c together. The pad section 36c of the electrode 36 is used as an electrode pad. It is noted that, in the present exemplary embodiment, the configuration of the connection section 36a of the electrode 36 is in a ring shape. However, the plane configuration of the connection section 36a may be in any arbitrary shape as long as the connection section 36a is in contact with the second contact layer 33.

Electrostatic Breakdown Protection Element

The electrostatic breakdown protection element 40 is formed on the semiconductor substrate 11 at a columnar semiconductor deposited body (hereafter referred to as a third columnar section) P3 and a columnar semiconductor deposited body (hereafter referred to as a fourth columnar section) P4 formed on the third columnar section P3, which are formed at a position different from the positions where the first columnar section P1 and the second columnar section P2 are formed. The third columnar section P3 is formed through etching the second mirror 23, the contact layer 24, the isolation layer 27 and the first contact layer 31. Also, the fourth columnar section P4 is formed through etching the absorption layer 32 and the second contact layer 33.

The third columnar section P3 is etched in a circular shape as viewed from above the first contact layer 31, and the fourth columnar section P4 is etched in a circular shape as viewed from above the second contact layer 33. Also, as shown in FIG. 19 and FIG. 20, the fourth columnar section P4 is formed to have a diameter smaller than the diameter of the third columnar section P3, and is formed in a state in which the fourth columnar section P4 is eccentric in a direction shifted away from the first columnar section P1 and the second columnar section P2 so as not to be concentric with the third columnar section P3. It is noted that the present embodiment is described as to an example in which the fourth columnar section P4 is eccentric with respect to the third columnar section P3. However, the fourth columnar section P4 may be made concentric with the third columnar section P3.

The electrostatic breakdown protection element 40 has a structure including the first contact layer 31 of the third columnar section P3, and the absorption layer 32 and the second contact layer 33 of the fourth columnar section P4. The first contact layer 31 composing the electrostatic breakdown protection element 40 has the same layer structure as (i.e., a layer structure identical with) that of the first contact layer 31 composing the photodetecting element 30. Also, the absorption layer 32 composing the electrostatic breakdown protection element 40 has the same layer structure as that of the absorption layer 32 composing the photodetecting element 30. Further, the second contact layer 33 composing the electrostatic breakdown protection element 40 has the same layer structure as that of the second contact layer 33 composing the photodetecting element 30.

Accordingly, the first contact layer 31, the absorption layer 32 and the second contact layer 33 composing the electrostatic breakdown protection element 40 also form a pin diode. It is noted that the “identical layer structure” means that corresponding two layers have the same thickness and composition, and when the layer structure of each of corresponding two layers is a multilayered structure, the thickness and composition of corresponding two layers each composing the multilayered structure are identical with each other.

An electrode 41 having a generally rectangular plane configuration is formed on the first contact layer 31 composing the electrostatic breakdown protection element 40 on the side opposite to the first columnar section P1 and the second columnar section P2. The electrode 41 may be composed of the same material as that of the electrodes 211 that is formed on the first contact layer 31 composing the photodetecting element 30. More specifically, the electrode 41 may be formed from a multilayer film of, for example, an alloy of chrome (Cr), gold (Au) and germanium (Ge), nickel (Ni) and gold (Au).

An electrode 42 is formed on the second contact layer 33 composing the electrostatic breakdown protection element 40. The electrodes 41 and 42 are used for driving the electrostatic breakdown protection element 40. The electrode 42 may be composed of the same material as that of the electrode 26 formed on the contact layer 24 of the surface-emitting type semiconductor laser 20. The electrode 42 can be formed with, for example, a multilayer film of an alloy of chrome (Cr), gold (Au) and zinc (Zn), and gold (Au). The electrode 42 may preferably be provided with a circular plane configuration that is similar to the plane configuration of the fourth columnar section P4.

Insulation Layer

The optical semiconductor element 200 in accordance with the present embodiment is provided with an insulation layer 50 formed mainly around circumferences of the first columnar section P1, the second columnar section P2 and the third columnar section P3, on the first mirror 21 or on the active layer 22, as shown in FIG. 19 and FIG. 20. Also, the insulation layer 50 is formed in a manner to cover a portion of the side surface of the fourth columnar section P4. Furthermore, the insulation layer 50 is formed below the lead-out section 35b and the pad section 35c of the electrode 35, and below electrode wirings 221 and 222 to be described below.

Electrode Wiring

An electrode wiring 221 is provided for electrically connecting the electrode 26 of the surface-emitting type semiconductor laser 20 with the electrode 211 of the photodetecting element 30 and the electrode 41 of the electrostatic breakdown protection element 40. The electrode wiring 221 has a connection section 221a having a ring-shaped plane configuration, a lead-out section 221b having a plane configuration in a T-letter shape, and a pad section 221c having a circular plane configuration, as shown in FIG. 19. The electrode wiring 221 is bonded and electrically connected to the upper surface of the electrodes 26 and 211 at the connection section 221a. The lead-out section 221b of the electrode wiring 221 connects the connection section 221a to the electrode 41 of the electrostatic breakdown protection element 40 and is connected to the pad section 221c. The pad section 221c of the electrode wiring 221 is used as an electrode pad.

An electrode wiring 222 is provided for electrically connecting the electrode 28 formed on a portion of the first mirror 21 with the electrode 42 of the electrostatic breakdown protection element 40. It is noted that the electrode 28 is one of the electrodes of the surface-emitting type semiconductor laser 20, and may be formed with the same material as that of the electrode 211 that is formed on the first contact layer 31 of the photodetecting element 30 and the electrode 41 that is formed on the first contact layer 31 of the electrostatic breakdown protection element 40. In other words, the electrode 28 may be formed from a multilayer film of, for example, an alloy of chrome (Cr), gold (Au) and germanium (Ge), nickel (Ni) and gold (Au). As shown in FIG. 19, the electrode wiring 222 has a connection section 222a in a ring-shaped plane configuration, a lead-out section 222b in a rectangular plane configuration, and a pad section 222c. The electrode wiring 222 is bonded and electrically connected to the upper surface of the electrode 42 at the connection section 222a. The lead-out section 222b of the electrode wiring 222 connects the connection section 222a to the pad section 222c, and is connected to the electrode 28. The pad section 222c of the electrode wiring 222 is used as an electrode pad. The electrode wirings 221 and 222 may be formed with, for example, gold (Au).

It is noted that, in the present embodiment, the electrode 26 of the surface-emitting type semiconductor laser 20, the electrode 211 of the photodetecting element 30 and the electrode 41 of the electrostatic breakdown protection element 40 are connected by the electrode wiring 221, and the electrode 28 formed on a portion of the upper surface of the first mirror 21 and the electrode 42 of the electrostatic breakdown protection element 40 are connected by the electrode wiring 222. However, the electrode 26, the electrode 211 and the electrode 41 may be connected together by wire bonding, and the electrode 28 and the electrode 42 may be connected together by wire bonding. However, as the wiring resistance can be lowered with the connection method using the electrode wirings 221 and 222, the connection method of the embodiment provides excellent high-frequency characteristic and highly reliable manufacturing process.

Overall Structure

In the optical element 200 in accordance with the present embodiment, the n-type first mirror 21 and the p-type second mirror 23 of the surface-emitting type semiconductor laser 20, and the n-type first contact layer 31 and the p-type second contact layer 33 of the photodetecting element 30 form a npnp structure as a whole. The photodetecting element 30 is provided to monitor outputs of laser light generated in the surface-emitting type semiconductor laser 20. Concretely, the photodetecting element 30 converts laser light generated in the surface-emitting type semiconductor laser 20 into electric current. With values of the electric current, outputs of laser light generated in the surface-emitting type semiconductor laser 20 are monitored.

More specifically, in the photodetecting element 30, a part of laser light generated in the surface-emitting type semiconductor laser 20 is absorbed in the absorption layer 32, and photoexcitation is caused by the absorbed light in the absorption layer 32, and electrons and holes are generated. Then, by an electric field that is applied from outside, the electrons move to the electrode 211 and the holes move to the electrode 36, respectively. As a result, a current is generated in the direction from the first contact layer 31 to the second contact layer 33 in the photodetecting element 30.

Also, intensity of the surface-emitting type semiconductor laser 20 is determined mainly by a bias voltage applied to the surface-emitting type semiconductor laser 20. In particular, intensity of the surface-emitting type semiconductor laser 20 greatly changes depending on the ambient temperature of the surface-emitting type semiconductor laser 20 and the lifetime of the surface-emitting type semiconductor laser 20. For this reason, it is necessary for the surface-emitting type semiconductor laser 20 to maintain a predetermined level of intensity.

In the optical element 200 in accordance with the present embodiment, intensity of the surface-emitting type semiconductor laser 20 is monitored in the photodetecting element 30, and the value of a voltage to be applied to the surface-emitting type semiconductor laser 20 is adjusted based on the value of a current generated in the photodetecting element 30, whereby the value of a current flowing within the surface-emitting type semiconductor laser 20 can be adjusted. Accordingly, a predetermined level of intensity can be maintained in the surface-emitting type semiconductor laser 20. The control to feed back the intensity of the surface-emitting type semiconductor laser 20 to the value of a voltage to be applied to the surface-emitting type semiconductor laser 20 can be performed by using an external electronic circuit (e.g., a drive circuit not shown).

Also, in the optical semiconductor element 200 in accordance with the present embodiment, the electrode 26 of the surface-emitting type semiconductor laser 20 and the electrode 41 of the electrostatic breakdown protection element 40 are electrically connected to each other by the electrode wiring 221, and the electrode 28 of the surface-emitting type semiconductor laser 20 and the electrode 42 of the electrostatic breakdown protection element 40 are electrically connected to each other by the electrode wiring 222. It is noted that the electrode 26 of the surface-emitting type semiconductor laser 20 is a p-electrode that is formed on the contact layer 24 composed of p-type GaAs, and the electrode 28 is an n-electrode formed on the n-type first mirror 21. On the other hand, the electrode 41 of the electrostatic breakdown protection element 40 is an n-electrode formed on the first contact layer 31 composed of the n-type GaAs layer, and the electrode 42 is a p-electrode formed on the second contact layer 33 composed of the p-type GaAs layer. Accordingly, the electrostatic breakdown protection element 40 is connected in parallel with the surface-emitting type semiconductor laser 20 by the electrode wirings 221 and 222 so as to have a reverse polarity (a rectification action in a reverse direction) with respect to the surface-emitting type semiconductor laser 20.

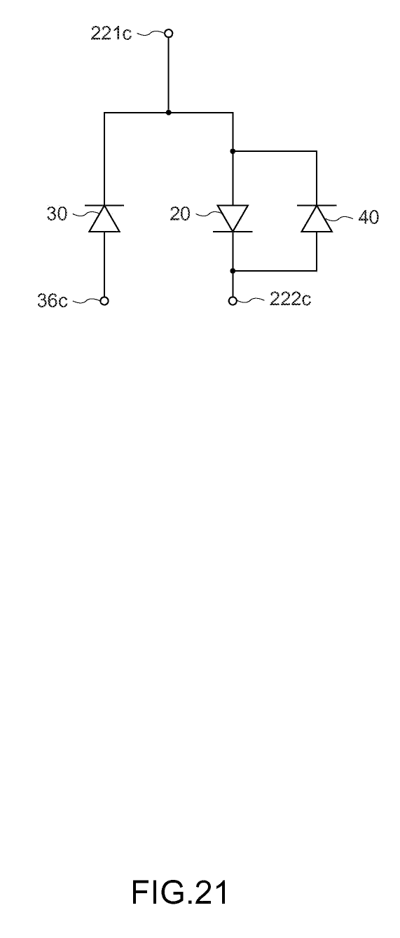

FIG. 21 is an electrical equivalent circuit diagram of the optical semiconductor element 200 in accordance with the sixth embodiment of the invention. As shown in FIG. 21, the photodetecting element 30 has an anode electrode (positive electrode) connected to the pad section 36c of the electrode 36, and a cathode electrode (negative electrode) connected to the pad section 221c of the electrode wiring 221. The surface-emitting type semiconductor laser 20 has an anode electrode (positive electrode) connected to the pad section 221c of the electrode wiring 221, and a cathode electrode (negative electrode) connected to the pad section 222c of the electrode wiring 222. The electrostatic breakdown protection element 40 has an anode electrode (positive electrode) connected to the pad section 222c of the electrode wiring 222, and a cathode electrode (negative electrode) connected to the pad section 221c of the electrode wiring 221.

Operation of Optical Semiconductor Element

Next, general operations of the optical semiconductor element 200 in accordance with the present embodiment are described. It is noted that the following method for driving the optical semiconductor element 200 is described as an example, and various changes can be made within the scope of the invention. First, when the pad sections 221c and 222c are connected to a power supply (illustration omitted), and a voltage in a forward direction is applied across the electrode 26 and the electrode 28, recombination of electrons and holes occur in the active layer 22 of the surface-emitting type semiconductor laser 20, thereby causing emission of light due to the recombination. Stimulated emission occurs during the period the generated light reciprocates between the second mirror 23 and the first mirror 21, whereby the light intensity is amplified. When the optical gain exceeds the optical loss, laser oscillation occurs, whereby laser light is emitted from the upper surface of the second mirror 23, and enters the isolation layer 27. Then, the laser light enters the first contact layer 31 of the photodetecting element 30.

Then, the light entered the first contact layer 31 composing the photodetecting element 30 then enters the absorption layer 32. As a result of a part of the incident light being absorbed in the absorption layer 32, photoexcitation is caused in the absorption layer 32, and electrons and holes are generated. Then, by an electric field applied from outside, the electrons move to the electrode 211 and the holes move to the electrode 36, respectively. As a result, a current (photocurrent) is generated in the direction from the first contact layer 31 to the second contact layer 33 in the photodetector element 30. By retrieving the current from the pad sections 36c and 221c and measuring the value of the current, intensity of the surface-emitting type semiconductor laser 20 can be detected.

If a voltage in a reverse direction is applied across the electrode 26 and the electrode 28, the voltage in a reverse direction is a voltage in a reverse direction with respect to the surface-emitting type semiconductor laser 20, but is a voltage in a forward direction with respect to the electrostatic breakdown protection element 40. For this reason, even when a voltage in a reverse direction with respect to the surface-emitting type semiconductor laser 20 is applied, the current flows through the electrostatic breakdown protection element 40, and therefore the surface-emitting type semiconductor laser 20 can be protected from electrostatic destruction.

Method for Manufacturing Optical Semiconductor Element

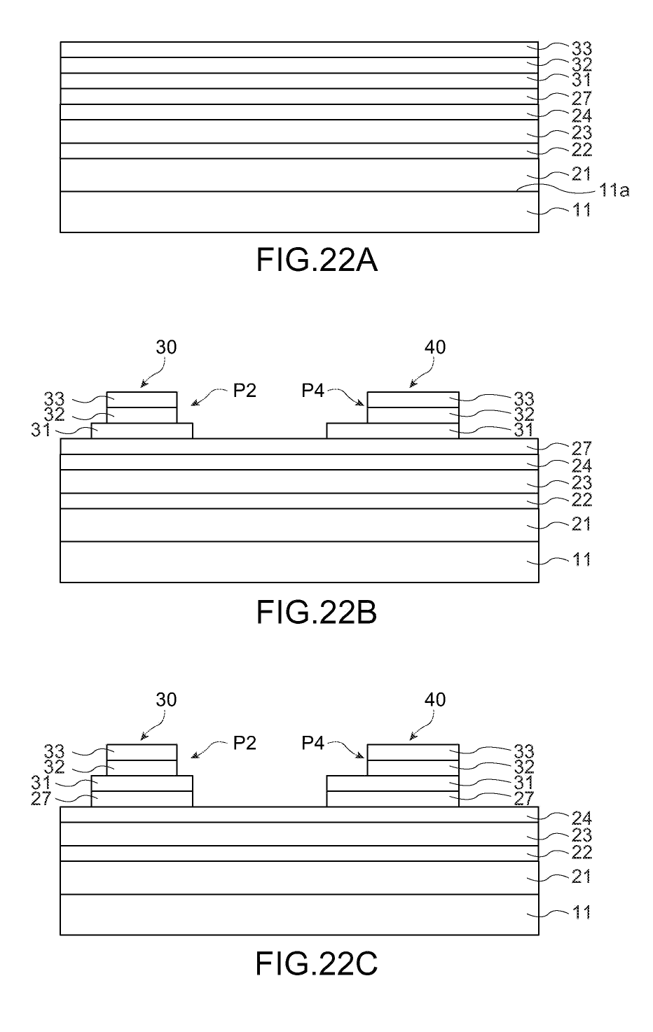

Next, a method for manufacturing an optical semiconductor element 200 described above is described. FIGS. 22-24 are cross-sectional views schematically showing steps of a method for manufacturing an optical semiconductor element in accordance with the sixth embodiment of the invention. It is noted that those figures correspond to the cross-sectional view shown in FIG. 20. To manufacture the optical semiconductor element 200 in accordance with the present embodiment, first, on a surface 11a of a semiconductor substrate 11 composed of an n-type GaAs layer, a semiconductor multilayer film is formed by epitaxial growth while modifying its composition (see FIG. 22A).

The semiconductor multilayer film may be formed from, for example, a first mirror 21 of 40 pairs of alternately laminated n-type Al_{0.9}Ga_{0.1}As layers and n-type Al_{0.15}Ga_{0.85}As layers, an active layer 22 composed of GaAs well layers and Al_{0.3}Ga_{0.7}As barrier layers in which the well layers include a quantum well structure composed of three layers, a second mirror 23 of 25 pairs of alternately laminated p-type Al_{0.9}Ga_{0.1}As layers and p-type Al_{0.15}Ga_{0.85}As layers, a contact layer 24 composed of p-type GaAs, an isolation layer 27 composed of an AlGaAs layer in which no impurity is doped, a first contact layer 31 composed of an n-type GaAs layer, a absorption layer 32 composed of a GaAs layer in which no impurity is doped, and a second contact layer 33 composed of a p-type GaAs layer. These layers are sequentially laminated on the semiconductor substrate 11, thereby forming the semiconductor multilayer film. It is noted that the isolation layer 27 can be composed of a p-type or n-type AlGaAs layer.

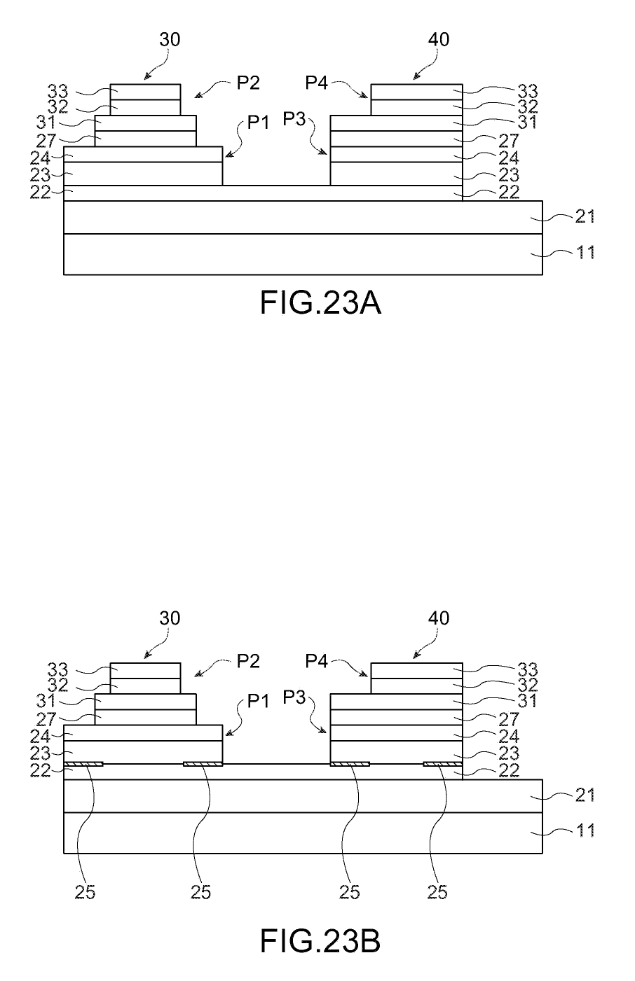

It is noted that, when the second mirror 23 is grown, at least one layer thereof near the active layer 22 is formed to be a layer that is later oxidized and becomes a current constricting layer 25 (see FIG. 23C). More concretely, the layer that becomes to be the current constricting layer 25 is formed to be an AlGaAs layer (including an AlAs layer) having an Al composition that is greater than an Al composition of the isolation layer 27. In other words, the isolation layer 27 may preferably be formed to be an AlGaAs layer whose Al composition is smaller than that of the layer that becomes to be the current constricting layer 25. By this, in an oxidizing process for forming the current constricting layer 25 to be described below, the isolation layer 27 is not oxidized. More specifically, the layer that becomes to be the current constricting layer 25 and the isolation layer 27 may preferably be formed such that the Al composition of the layer that becomes to be the current constricting layer 25 is 0.95 or greater, and the Al composition of the isolation layer 27 is less than 0.95. An optical film thickness of the isolation layer 27 may preferably be, for example, an odd multiple of λ/4, when a design wavelength of the surface-emitting type semiconductor laser 20 (see FIG. 20) is λ.

Also, the sum of optical film thickness of the first contact layer 31, the absorption layer 32 and the second contact layer 33, in other words, the optical film thickness of the entire photodetecting element 30 (see FIG. 20) may preferably be, for example, an odd multiple of λ/4. As a result, the entire photodetecting element 30 can function as a distributed reflection type mirror. In other words, the entire photodetecting element 30 can function as a distributed reflection type mirror above the active layer 22 in the surface-emitting type semiconductor laser 20. Accordingly, the photodetecting element 30 can function as a distributed reflection type mirror without adversely affecting the characteristics of the surface-emitting type semiconductor laser 20.

The temperature at which the epitaxial growth is conducted is appropriately decided depending on the growth method, the kind of raw material, the type of the semiconductor substrate 11, and the kind, thickness and carrier density of the semiconductor multilayer film to be formed, and may preferably be set generally at 450° C.-800° C. Also, the time required for conducting the epitaxial growth is appropriately decided like the temperature. Also, a metal-organic vapor phase deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

Next, a second columnar section P2 and a fourth columnar section P4 are formed, as shown in FIG. 22B. To form the second columnar section P2 and the fourth columnar section P4, first, resist (not shown) is coated on the semiconductor multilayer film, and then the resist is patterned by a lithography method. As a result, a resist layer having a specified plane configuration is formed on the upper surface of the second contact layer 33. Then, by using the resist layer as a mask, the second contact layer 33 and the absorption layer 32 are etched by, for example, a dry etching method. By this, the second contact layer 33 and the absorption layer 32 having the same plane configuration as that of the second contact layer 33 are formed. As a result, the second columnar section P2 and the fourth columnar section P4 are formed. When the second columnar section P2 and the fourth columnar section P4 are formed, the resist layer is removed.

When the second columnar section P2 and the fourth columnar section P4 are formed, the first contact layer 31 is patterned into a specified configuration. More concretely, first, resist (not shown) is coated on the first contact layer 31, and then the coated resist is patterned by a photolithography method. As a result, a resist layer having a specified pattern that covers the second columnar section P2 and the fourth columnar section P4 is formed on the first contact layer 31. Then, by using the resist layer as a mask, the first contact layer 31 is etched to a specified thickness by, for example, dry etching.

Then, the remaining portion of the first contact layer 31 is etched by a wet etching method. It is noted that, for etching the first contact layer 31, for example, a mixed solution of ammonia, hydrogen peroxide and water can be used as an etchant. In this case, the mixing ratio of ammonia, hydrogen peroxide and water which is about 1:10:150 can be used, but this mixing ratio is not particularly limited, and may be appropriately decided. It is noted that, because the isolation layer 27 is disposed below the first contact layer 31, and the isolation layer 27 functions as an etching stopper layer, etching of the first contact layer 31 can be accurately and readily stopped at the time when the isolation layer 27 is exposed.

By the steps described above, the photodetecting element 30 and the electrostatic breakdown protection element 40 are formed, as shown in FIG. 22B. It is noted that each of the photodetecting element 30 and the electrostatic breakdown protection element 40 includes the second contact layer 33, the absorption layer 32 and the first contact layer 31. Moreover, the plane configuration of the first contact layer 31 is made to be greater than the plane configuration of the second contact layer 33 and the absorption layer 32. In this manner, in accordance with the present embodiment, the photodetecting element 30 and the electrostatic breakdown protection element 40 are formed by the same process. It is noted that, in the process described above, the second contact layer 33 and the absorption layer 32 are patterned, and then the first contact layer 31 is patterned. However, the first contact layer 31 may be patterned first, and then the second contact layer 33 and the absorption layer 32 may be patterned.

When the photodetecting element 30 and the electrostatic breakdown protection element 40 are formed, the isolation layer 27 is patterned into a specified configuration, as shown in FIG. 22C. More concretely, by using the resist layer described above (the resist layer used for etching the first contact layer 31) as a mask, the isolation layer 27 is etched. In this instance, because the contact layer 24 is disposed below the isolation layer 27, and the contact layer 24 functions as an etching stopper layer, etching of the isolation layer 27 can be accurately and readily stopped at the time when the contact layer 24 is exposed. As an etchant for etching the isolation layer 27, for example, a hydrogen fluoride solution or a hydrofluoric acid system buffer solution can be used.

As a result, the isolation layer 27 that is patterned is formed, as shown in FIG. 22C. Then, the resist layer (the resist layer used for etching the first contact layer 31 and the isolation layer 27) is removed. In the illustrated example, the plane configuration of the isolation layer 27 is made to be the same as the plane configuration of the first contact layer 31. But the plane configuration of the isolation layer 27 can be made to be greater than the plane configuration of the first contact layer 31. For example, another resist layer having a larger plane configuration area than that of the resist layer used for patterning the isolation layer 27 described above may be used to pattern the isolation layer 27.

Next, as shown in FIG. 23A, the surface-emitting type semiconductor laser 20 including the first columnar section P1 and the remaining portion of the third columnar section P3 located below and the electrostatic breakdown protection element 40 are formed. More concretely, first, resist (not shown) is coated on the contact layer 24, and then the coated resist is patterned by a lithography method. As a result, a resist layer having a specified pattern is formed. Then, by using the resist layer as a mask, the contact layer 24, the second mirror 23 and the active layer 22 are etched by, for example, a dry etching method. It is noted that the active layer 22 between the first columnar section P1 and the third columnar section P3 is left remained without being etched. In the manner described above, the first columnar section P1 and the third columnar section P3 are formed, as shown in FIG. 23A.

By the steps described above, a vertical resonator (the surface-emitting type semiconductor laser 20) including the first columnar section P1 is formed on the semiconductor substrate 11. By this, a laminated body of the surface-emitting type semiconductor laser 20, the isolation layer 27 and the photodetecting element 30 is formed, and the electrostatic breakdown protection element 40 is formed above the third columnar section P3. Then, the resist layer is removed. It is noted that, in the present embodiment, after the photodetecting element 30, the electrostatic breakdown protection element 40 and the isolation layer 27 are formed, the first columnar section P1 and the third columnar section P3 are formed. However, the first columnar section P1 and the third columnar section P3 may be formed first, and then the photodetecting element 30, the electrostatic breakdown protection element 40 and the isolation layer 27 may be formed.

Then, a current constricting layer 25 is formed, as shown in FIG. 23B. To form the current constricting layer 25, first, the semiconductor substrate 11 on which the first columnar section P1 and the third columnar section P3 are formed is placed in a water vapor atmosphere at, for example, about 400° C. As a result, a layer having a high Al composition in the second mirror 23 described above is oxidized from its side surface, whereby the current constricting layer 25 is formed.

The oxidation rate depends on the temperature of the furnace, the amount of water vapor supply, and the Al composition and the film thickness of the layer to be oxidized. When driving a surface-emitting type laser equipped with the current constricting layer 25 that is formed by oxidation, current flows only in a portion where the current constricting layer 25 is not formed (a portion that is not oxidized). Accordingly, in the process of forming the current constricting layer 25, the range of the current constricting layer 25 to be formed may be controlled, whereby the current density can be controlled. Also, the diameter of the current constricting layer 25 may preferably be adjusted such that a major portion of laser light that is emitted from the surface-emitting type semiconductor laser 20 enters the first contact layer 31.

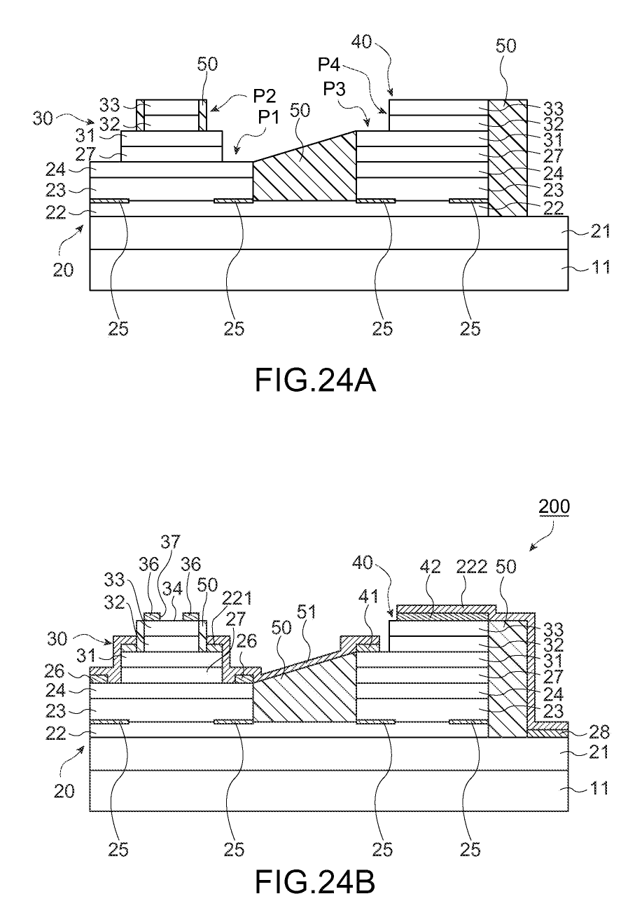

Next, an insulation layer 50 is formed on the active layer 22 and the first mirror 21, around the first columnar section P1 and the third columnar section P3, and around the second columnar section P2, as shown in FIG. 24A. The insulation layer 50 may preferably be composed of a material that is easier to make a thick film. The film thickness of the insulation layer 50 may be, for example, about 2-4 μm, but it is not particularly limited, and may be appropriately decided according to the height of the first columnar section P1 and the third columnar section P3.

For example, the insulation layer 50 can be formed from material that is obtained by hardening liquid material settable by energy, such as, heat, light or the like (for example, a precursor of ultraviolet setting type resin or thermosetting type resin). As the ultraviolet setting type resin, for example, an acrylic resin, an epoxy resin or the like that is an ultraviolet setting type can be enumerated. Also, as the thermosetting type resin, a polyimide resin or the like that is a thermosetting type can be enumerated. Furthermore, for example, the insulation layer 50 may be composed of a laminated layered film using a plurality of the materials described above.

In the present exemplary embodiment, the case where a precursor of polyimide resin is used as the material for forming the insulation layer 50 is described. First, for example, by using a spin coat method, the precursor (precursor of polyimide resin) is coated on the semiconductor substrate 11, thereby forming a precursor layer. In this instance, the precursor layer is formed in a manner to cover the upper surface of the first columnar section P1. It is noted that, as the method for forming the precursor layer, besides the aforementioned spin coat method, another known technique, such as, a dipping method, a spray coat method, an ink jet method or the like can be used. Then, the semiconductor substrate 11 is heated by using, for example, a hot plate or the like, thereby removing the solvent, and then is placed in a furnace at about 350° C. to thereby imidize the precursor layer, whereby a polyimide resin layer that is almost completely set is formed. Then, as shown in FIG. 24A, the polyimide resin layer is patterned by using a known lithography technique, thereby forming the insulation layer 50.

As the etching method used for patterning, a dry etching method or the like can be used. Dry etching can be conducted with, for example, oxygen or argon plasma. In the method for forming the insulation layer 50 described above, an example in which a precursor layer of polyimide resin is hardened and then patterning is conducted is described. However, before hardening the precursor layer of polyimide resin, patterning may be conducted. As the etching method used for this patterning, a wet etching method or the like may be used. The wet etching may be conducted with, for example, an alkaline solution or an organic solution.

When the steps described above are completed, an electrode 28 on the first mirror 21, and electrodes 211 and 41 on the upper surface of the first contact layer 31 are formed. Also, an electrode 26 on the contact layer 24 and electrodes 36 and 42 on the second contact layer 33 are formed, as shown in FIG. 24B. In this exemplary embodiment, the electrode 36 has a connecting section 36a having a ring-shaped plane configuration, a lead-out section 36b having a linear plane configuration, and a pad section 36c having a circular plane configuration. It is noted that the connecting section 36a is formed on the upper surface of the second contact layer 33, and the lead-out section 36b and the pad section 36c are formed on the insulation layer 50.

An exemplary method for forming the electrodes 28, 41 and 211 is conducted as follows. First, before forming the electrodes 28, 41 and 211, the upper surface of the first mirror 21 and the upper surface of the first contact layer 31 are washed by a plasma processing method or the like, if necessary. As a result, an element with more stable characteristics can be formed. Next, a laminated layered film of, for example, an alloy of chrome (Cr), gold (Au) and germanium (Ge), nickel (Ni) and gold (Au) is formed by, for example, a vacuum deposition method. Then, the electrodes 28, 41 and 211 are formed by removing portions of the laminated layered film other than specified positions by a lift-off method.

Further, an exemplary method for forming the electrodes 26, 36 and 42 is described below. First, before forming the electrodes 26, 36 and 42, the upper surface of the contact layer 24 and the upper surface of the second contact layer 33 are washed by a plasma processing method or the like, if necessary. As a result, an element with more stable characteristics can be formed. Next, a laminated layered film of, for example, an alloy of chrome (Cr), gold (Au) and zinc (Zn), and gold (Au) is formed by, for example, a vacuum deposition method. Then, the electrodes 26, 36 and 42 are formed by removing portions of the laminated layered film other than specified positions by a lift-off method.

It is noted that in the process of forming the electrodes 28, 41 and 211 and the electrodes 26, 36 and 42 described above, a dry etching method or a wet etching method may be used instead of a lift-off method. Also, in the above-described process, a sputtering method may be used instead of a vacuum deposition method. Moreover, although the electrodes 28, 41 and 211 are concurrently patterned, and the electrodes 26, 36 and 42 are concurrently patterned in the process described above, these electrodes may be formed individually from one another.

When the process described above is completed, electrode wirings 221 and 222 are formed, as shown in FIG. 24B. It is noted that the electrode wiring 221 is formed in a manner to electrically connect the electrode 26 of the surface-emitting type semiconductor laser 20, the electrode 211 of the photodetecting element 30, and the electrode 41 of the electrostatic breakdown protection element 40. Further, the electrode wiring 222 is formed in a manner to electrically connect the electrode 28 of the surface-emitting type semiconductor laser 20 with the electrode 42 of the electrostatic breakdown protection element 40. Concretely, like the aforementioned case of forming the electrodes, surfaces above the semiconductor substrate 11 are washed by using a plasma processing method or the like if necessary. Next, a metal film composed of, for example, gold (Au) is formed by, for example, a vacuum deposition method. Then, portions of the metal film other than the specified positions are removed, thereby forming the electrode wirings 221 and 222.

Finally, an annealing treatment is conducted. The temperature of the annealing treatment depends on the electrode material. For example, the annealing treatment may be conducted at about 400° C. for the electrode material used in the present embodiment. It is noted that the annealing treatment may be conducted before the electrode wirings 221 and 222 are formed, if necessary. By the process described above, the optical semiconductor element 200 in accordance with the present embodiment shown in FIG. 19 and FIG. 20 is manufactured. In the present exemplary embodiment, the photodetecting element 30 and the electrostatic breakdown protection element 40 are formed through common process steps. For this reason, the optical semiconductor element 200 whose electrostatic breakdown voltage is improved can be manufactured without complicating the manufacturing process.

### Seventh Embodiment

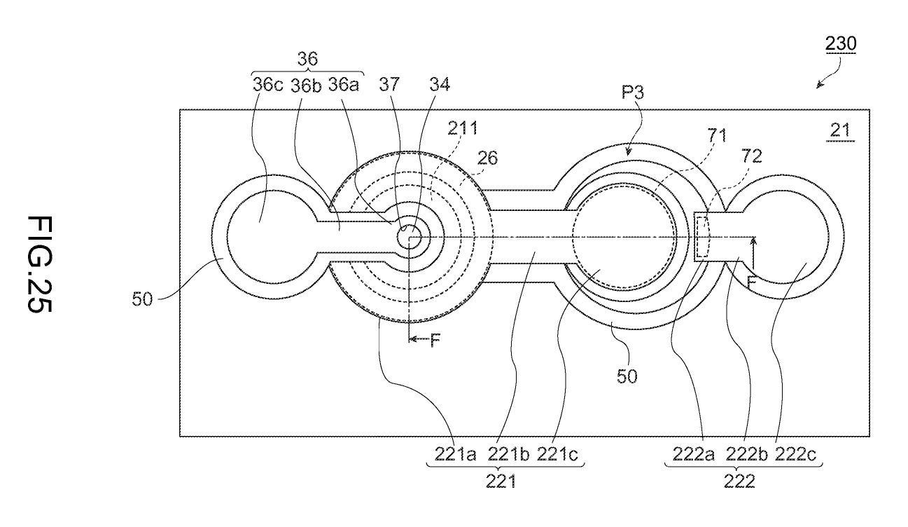

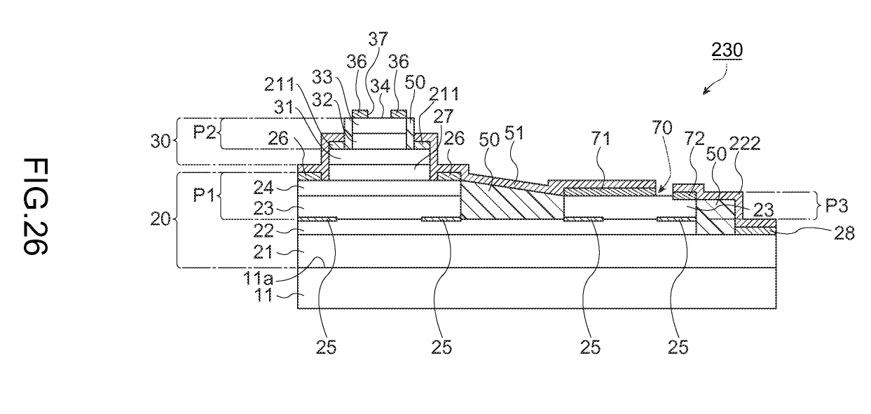

FIG. 25 is a plan view schematically showing an optical semiconductor element in accordance with a seventh embodiment of the invention, and FIG. 26 is a cross-sectional view taken along a line F-F of FIG. 25. In FIG. 25 and FIG. 26, components corresponding to the components shown in FIG. 19 and FIG. 20 are appended with the same reference numerals. As shown in FIG. 25 and FIG. 26, an optical semiconductor element 230 in accordance with the present embodiment includes a surface-emitting type semiconductor laser 20, a photodetecting element 30 and an electrostatic breakdown protection element 70. The surface-emitting type semiconductor laser 20 and the photodetecting element 30 of the optical semiconductor element 230 of the present embodiment have the same structure as those of the optical semiconductor element 200 of the sixth embodiment shown in FIG. 19 and FIG. 20, but the electrostatic breakdown protection element 70 has a structure different from that of the electrostatic breakdown protection element 40 of the optical semiconductor element 200.

In accordance with the present embodiment, a third columnar section P3 is formed only with a second mirror 23, and a fourth columnar section P4 is not formed. As described above, the second mirror 23 composing the third columnar section P3 has a structure in which p-type Al_{0.9}Ga_{0.1}As layers (hereafter referred to as first layers) and p-type Al_{0.15}Ga_{0.85}As layers (hereafter referred to as second layers) are alternately laminated, and one of the layers is exposed at the top surface of the third columnar section P3. It is noted that, in this exemplary embodiment, the first layer is exposed at the top surface of the third columnar section P3.

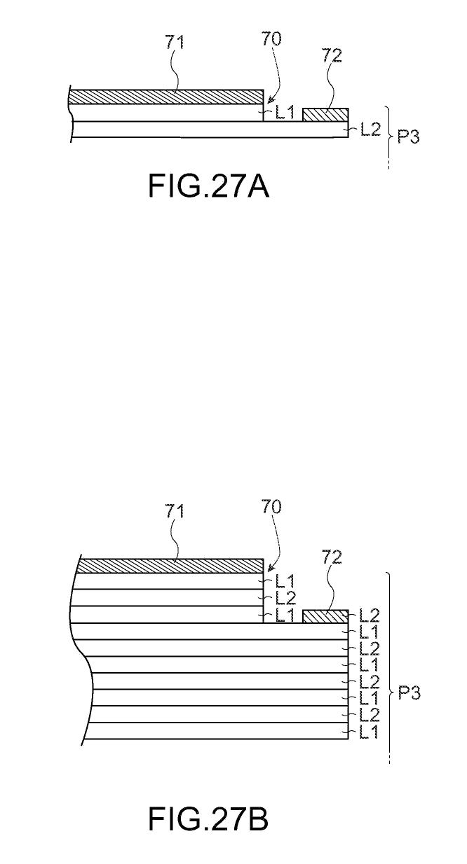

FIG. 27 is an enlarged cross-sectional view of the uppermost portion of the third columnar section P3. As shown in FIG. 27A, a first layer L1 and a second layer L2 are laminated in the uppermost section of the third columnar section P3. Also, at the uppermost section of the third columnar section P3, a portion of the first layer L1 located at the top is removed, and the second layer L2 is exposed at the upper surface of the third columnar section P3 at this portion. Further, an electrode 71 is formed on the first layer L1 located at the top of the third columnar section P3, and an electrode 72 is formed on the second layer L2 that is exposed at the top surface of the third columnar section P3. In the present embodiment, the junction between the electrode 71 and the first layer L1 located at the top of the third columnar section P3 is a Schottky junction, which forms an electrostatic breakdown protection element 70. In other words, a layer structure identical with a portion of the first mirror 21 forming the surface-emitting type semiconductor laser 20 is used to form the electrostatic breakdown protection element 70.

As the electrode 71 that forms a Schottky junction, a multilayer film of titanium (Ti), platinum (Pt) and gold (Au) may be used, as the first layer L1 is a p-type Al_{0.9}Ga_{0.1}As layer. Alternatively, a metal film composed of aluminum (Al), a metal film composed of an alloy of aluminum (Al) and gold (Au), or the like can be used. Also, like the electrodes 26, 36 and 42 formed on the optical semiconductor element 200 of the sixth embodiment, the electrode 72 that is to be formed on the second layer L2 can be formed with, for example, a multilayer film of an alloy of chrome (Cr), gold (Au) and zinc (Zn), and gold (Au), a multilayer film of platinum (Pt), titanium (Ti) and gold (Au), or the like.

In the example shown in FIG. 27A, the electrode 71 and the electrode 72 are formed on the first layer L1 and the second layer L2 that form a pair, respectively. However, as shown in FIG. 27B, the electrode 71 may be formed on the first layer L1 in one pair, and the electrode 72 may be formed on the second layer L2 in another pair different from the aforementioned pair. Also, FIG. 27B shows an exemplary structure in which a first layer L1 and a second layer L2 are formed between the first layer L1 (the first layer L1 located at the top) on which the electrode 71 is formed and the first layer L1 on which the electrode 72 is formed, but the number of layers to be provided between them can be any arbitrary number. Also, in the example shown in FIG. 27, the layer located at the top of the third columnar section P3 is the first layer L1. However, the layer located at the top of the third columnar section P3 can be the second layer L2. In other words, the electrode 71 may be formed on the second layer L2, and the electrode 72 may be formed on the first layer L1.

Furthermore, as shown in FIG. 26, an electrode wiring 221 is formed on the electrode 71. By this, the electrode 71 is electrically connected to an electrode 26 of the surface-emitting type semiconductor laser 20 and an electrode 211 of the photodetecting element 30. Also, an electrode wiring 222 is formed on the electrode 72. By this, the electrode 72 is electrically connected to the electrode 28 of the surface-emitting type semiconductor laser 20. Accordingly, in the optical semiconductor element 230 of the present embodiment, the electrostatic breakdown protection element 70 is connected in parallel with the surface-emitting type semiconductor laser 20 by the electrode wirings 221 and 222 so as to have a reverse polarity (a rectification action in a reverse direction) with respect to the surface-emitting type semiconductor laser 20. For this reason, even when a voltage in a reverse direction is applied across the electrode 26 and the electrode 28 of the surface-emitting type semiconductor laser 20, the current flows through the electrostatic breakdown protection element 70, and therefore the surface-emitting type semiconductor laser 20 can be protected from electrostatic destruction.

Furthermore, in accordance with the present embodiment, although the step of forming the electrode 71 is necessary to obtain a Schottky junction, dedicated steps to form the electrostatic breakdown protection element 70 are not necessary. For this reason, the optical semiconductor element 230 whose electrostatic breakdown voltage is improved can be manufactured without making the manufacturing process more complex.

### Eighth Embodiment

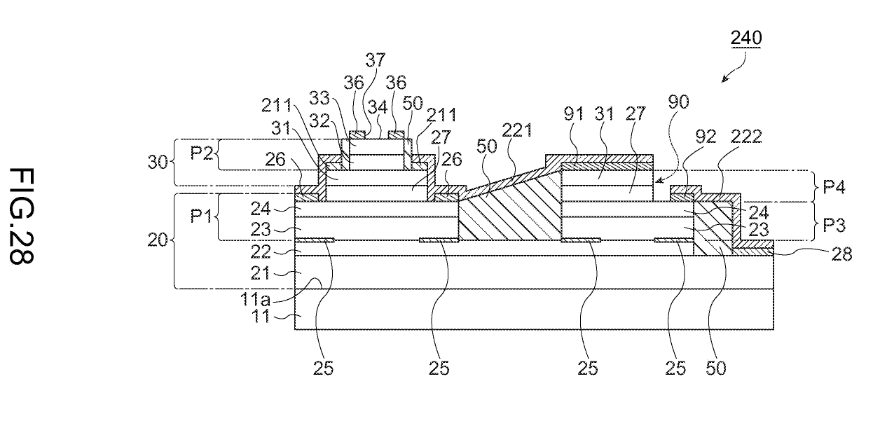

FIG. 28 is a cross-sectional view schematically showing an optical semiconductor element 240 in accordance with an eighth embodiment of the invention. It is noted that the optical semiconductor element 240 of the present embodiment has a structure in a plan view similar to the structure shown in FIG. 25. Accordingly, it can be said that FIG. 28 is a cross-sectional view taken along a line F-F of FIG. 25. It is noted that components in FIG. 28 corresponding to the components shown in FIG. 19 and FIG. 20 are appended with the same reference numerals. As shown in FIG. 28, the optical semiconductor element 240 in accordance with the present embodiment includes a surface-emitting type semiconductor laser 20, a photodetecting element 30 and an electrostatic breakdown protection element 90. The surface-emitting type semiconductor laser 20 and the photodetecting element 30 of the optical semiconductor element 240 of the present embodiment have the same structure as those of the optical semiconductor element 200 of the sixth embodiment shown in FIG. 19 and FIG. 20. However, the electrostatic breakdown protection element 90 has a structure different from that of the electrostatic breakdown protection element 40 of the optical semiconductor element 200 or the electrostatic breakdown protection element 70 of the optical semiconductor element 230.

In the present embodiment, a third columnar section P3 is formed from a second mirror 23 and a contact layer 24. Further, a fourth columnar section P4 is formed from an isolation layer 27 and a first contact layer 31. It is noted that the fourth columnar section P4 is formed to have a diameter smaller than that of the third columnar section P3. In accordance with the present embodiment, the electrostatic breakdown protection element 90 is formed from the contact layer 24, the isolation layer 27 and the first contact layer 31. The contact layer 24 and the isolation layer 27 form a heterojunction, and the first contact layer 31 and the isolation layer 27 form a heterojunction. In other words, the electrostatic breakdown protection element 90 is formed with the same layer structure as the contact layer 24 forming the surface-emitting type semiconductor laser 20 and the first contact layer 31 forming the photodetecting element 30.

An electrode 91 is formed on an upper surface (on the first contact layer 31) of the fourth columnar section P4, and an electrode 92 is formed on an upper surface (on the contact layer 24) of the third columnar section P3. The electrode 91 may be formed from a multilayer film of, for example, an alloy of chrome (Cr), gold (Au) and germanium (Ge), nickel (Ni) and gold (Au). Also, the electrode 92 may be formed from a multilayer film of, for example, an alloy of chrome (Cr), gold (Au) and zinc (Zn), and gold (Au), or a multilayer film of, for example, platinum (Pt), titanium (Ti) and gold (Au).

Furthermore, as shown in FIG. 28, an electrode wiring 221 is formed on the electrode 91. By this, the electrode 91 is electrically connected to the electrode 26 of the surface-emitting type semiconductor laser 20 and the electrode 211 of the photodetecting element 30. Also, an electrode wiring 222 is formed on the electrode 92. By this, the electrode 92 is electrically connected to the electrode 28 of the surface-emitting type semiconductor laser 20. Accordingly, in the optical semiconductor element 240, the electrostatic breakdown protection element 90 is connected in parallel with the surface-emitting type semiconductor laser 20 by the electrode wirings 221 and 222 so as to have a reverse polarity (a rectification action in a reverse direction) with respect to the surface-emitting type semiconductor laser 20. For this reason, when a voltage in a reverse direction is applied across the electrode 26 and the electrode 28 of the surface-emitting type semiconductor laser 20, the current flows through the electrostatic breakdown protection element 90, and therefore the surface-emitting type semiconductor laser 20 can be protected from electrostatic destruction. Also, in accordance with the present embodiment, the electrostatic breakdown protection element 90 is formed through devising the etching process for forming the surface-emitting type semiconductor laser 20 and the photodetecting element 30. Accordingly, dedicated steps to form the electrostatic breakdown protection element 90 are not necessary. Therefore, the optical semiconductor element 240 whose electrostatic breakdown voltage is improved can be manufactured without making the manufacturing process more complex.

### Ninth Embodiment

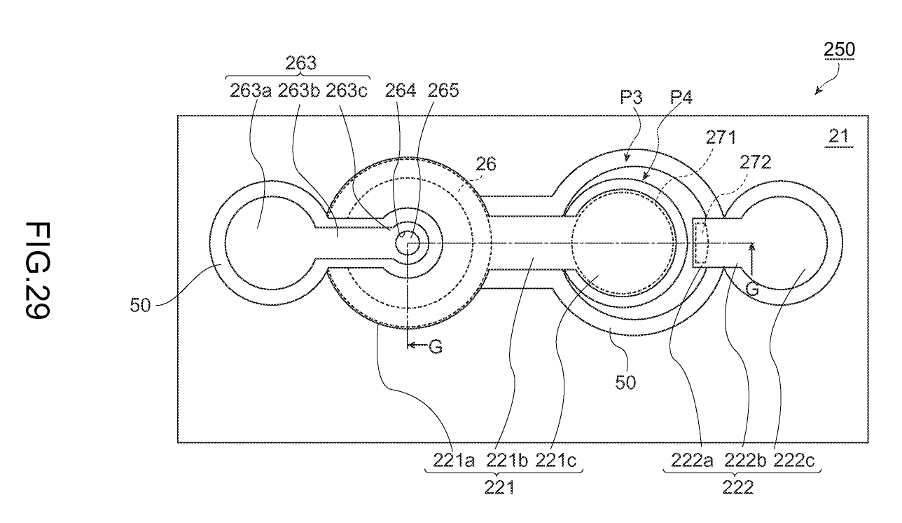

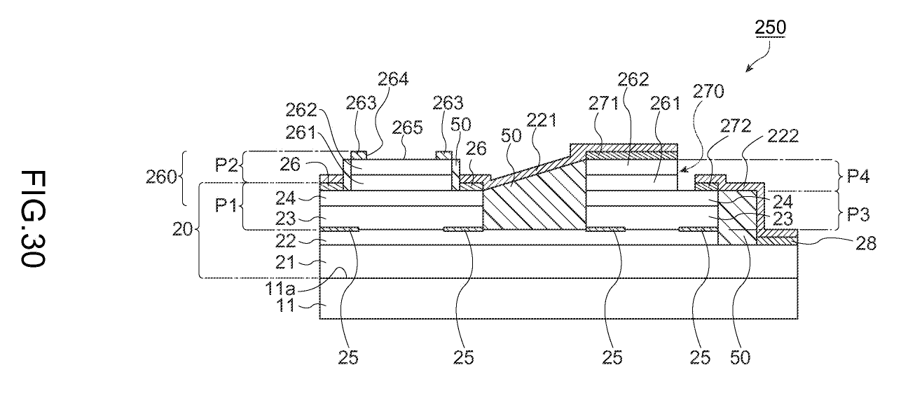

FIG. 29 is a plan view schematically showing an optical semiconductor element in accordance with a ninth embodiment of the invention, and FIG. 30 is a cross-sectional view taken along a line G-G of FIG. 29. In FIG. 29 and FIG. 30, components corresponding to the components shown in FIG. 19 and FIG. 20 are appended with the same reference numerals. As shown in FIG. 29 and FIG. 30, an optical semiconductor element 250 in accordance with the present embodiment includes a surface-emitting type semiconductor laser 20, a photodetecting element 260 and an electrostatic breakdown protection element 270. The surface-emitting type semiconductor laser 20 of the optical semiconductor element 250 of the present embodiment has the same structure as that of the optical semiconductor element 200 of the sixth embodiment shown in FIG. 19 and FIG. 20, but the photodetecting element 260 and the electrostatic breakdown protection element 270 have structures different from those of the optical semiconductor element 200.

As shown in FIG. 30, the surface-emitting type semiconductor laser 20 is formed from a first mirror 21, an active layer 22, a second mirror 23 and a contact layer 24. In the sixth through eighth embodiments described above, the isolation layer 27 is formed on the contact layer 24. However, in the present embodiment, an isolation layer 27 is omitted, and a absorption layer 261 and a contact layer 262 are sequentially laminated on the contact layer 24, thereby forming a second columnar section P2. In the present embodiment, the photodetecting element 260 is formed from the contact layer 24 composing the surface-emitting type semiconductor laser 20, the absorption layer 261 and the contact layer 262.

The contact layer 24 is composed of p-type GaAs, the absorption layer 216 is composed of a GaAs layer in which no impurity is doped, and the contact layer 262 is composed of a n-type GaAs layer. Concretely, the contact layer 24 is made to be p-type by doping, for example, carbon (C), and the contact layer 262 is made to be n-type by doping, for example, silicon (Si). Accordingly, a pin diode is formed by the p-type contact layer 24, the absorption layer 216 in which no impurity is doped, and the n-type contact layer 262.

An electrode 26 having a ring-shaped plane configuration that extends along an outer circumference of the first columnar section P1 and surrounds the second columnar section P2 is formed on the contact layer 24. In the present embodiment, the contact layer 24 is shared by the surface-emitting type semiconductor laser 20 and the photodetecting element 260, such that the electrode 26 is shared as one of the electrodes of the surface-emitting type semiconductor laser 20 and one of the electrodes of the absorption layer 260.

Furthermore, an electrode 263 is formed on an upper surface (on the contact layer 262) of the photodetecting element 260. The electrode 263 is used as the other of the electrodes of the photodetecting element 260. The electrode 263 is provided with an aperture section 264, and a portion of the upper surface of the contact layer 262 is exposed through the aperture section 264. The exposed surface defines an emission surface 265 for emitting laser light. Accordingly, by appropriately setting the plane configuration and the size of the aperture section 264, the configuration and the size of the emission surface 265 can be appropriately set. In accordance with the present embodiment, as shown in FIG. 29, the emission surface 265 may be circular. Also, the electrode 263 may be formed from a multilayer film of, for example, an alloy of chrome (Cr), gold (Au) and germanium (Ge), nickel (Ni) and gold (Au).

The electrode 263 has, as shown in FIG. 29, a connection section 263a having a ring-shaped plane configuration, a lead-out section 263b having a linear plane configuration, and a pad section 263c having a circular plane configuration. The electrode 263 is electrically connected to the contact layer 262 at the connection section 263a. The lead-out section 263b of the electrode 263 connects the connection section 263a and the pad section 263c together. The pad section 263c of the electrode 263 is used as an electrode pad. It is noted that, in the present exemplary embodiment, the configuration of the connection section 263a of the electrode 263 is in a ring shape. However, the plane configuration of the connection section 263a may be in any arbitrary shape as long as the connection section 263a is in contact with the contact layer 262.

Furthermore, in accordance with the present embodiment, a third columnar section P3 is formed from the second mirror 23 and the contact layer 24, and a fourth columnar section P4 is formed from the absorption layer 261 and the contact layer 262. It is noted that the fourth columnar section P4 is formed to have a diameter smaller than that of the third columnar section P3. In the present embodiment, the electrostatic breakdown protection element 270 is formed from the contact layer 24, the absorption layer 261 and the contact layer 262, like the photodetecting element 260. In other words, the electrostatic breakdown protection element 270 is formed with the same layer structure as that of the photodetecting element 260.

Also, an electrode 271 is formed on an upper surface of the fourth columnar section P4 (on the contact layer 262), and an electrode 272 is formed on an upper surface of the third columnar section P3 (on the contact layer 24). The electrode 271 may be formed from a multilayer film of, for example, an alloy of chrome (Cr), gold (Au) and germanium (Ge), nickel (Ni) and gold (Au). The electrode 272 may be formed from a multilayer film of, for example, an alloy of chrome (Cr), gold (Au) and zinc (Zn), and gold (Au), or a multilayer film of platinum (Pt), titanium (Ti) and gold (Au).

Further, as shown in FIG. 30, an electrode wiring 221 is formed on the electrode 271. By this, the electrode 271 is electrically connected with the electrode 26 of the surface-emitting type semiconductor laser 20 and the photodetecting element 260. Also, an electrode wiring 222 is formed on the electrode 272. By this, the electrode 272 is electrically connected with the electrode 28 of the surface-emitting type semiconductor laser 20. Accordingly, in the optical semiconductor element 250, the electrostatic breakdown protection element 270 is connected in parallel with the surface-emitting type semiconductor laser 20 by the electrode wirings 221 and 222 so as to have a reverse polarity (a rectification action in a reverse direction) with respect to the surface-emitting type semiconductor laser 20. For this reason, even when a voltage in a reverse direction is applied across the electrode 26 and the electrode 28 of the surface-emitting type semiconductor laser 20, the current flows through the electrostatic breakdown protection element 270, and therefore the surface-emitting type semiconductor laser 20 can be protected from electrostatic destruction. Also, in accordance with the present embodiment, the electrostatic breakdown protection element 270 and the photodetecting element 30 are formed by the same manufacturing process. Accordingly, dedicated steps for forming the electrostatic breakdown protection element 270 are not required. For this reason, the optical semiconductor element 250 whose electrostatic breakdown voltage is improved can be manufactured without making the manufacturing process more complex.

Exemplary embodiments of the invention are described above. However, the invention is not limited to the embodiments described above, and changes can be freely made within the scope of the invention. For example, in the embodiments described above, optical elements in which the photodetecting element 30 or 260 is provided above the surface-emitting type semiconductor laser 20 are described as examples. However, the invention is also applicable to optical elements having a structure described in, for example, Japanese Examined Patent Application Publication JP-B-7-56552 and Japanese Laid-open Patent Application JP-A-6-37299, in which a surface-emitting type semiconductor laser is provided above a photodetecting element.

Also, in the embodiments described above, the photodetecting elements 30 and 260 are provided to detect the light intensity of laser light emitted from the surface-emitting type semiconductor laser 20. However, the photodetecting elements 30 and 260 can also be used to detect external light. More specifically, for example, the optical element may be used for optical communications, wherein laser light emitted from the surface-emitting type semiconductor laser 20 may be used for optical signals to be transmitted, and optical signals transmitted can be detected by the photodetecting element 30 or 260. Optical signals received by the photodetecting element 30 or 260 are extracted as electrical signals through the electrodes 36 and 211 or the electrodes 26 and 263. Moreover, interchanging the p-type and n-type characteristics of each of the semiconductor layers in the above described embodiments does not deviate from the subject matter of the present invention.

### Tenth Embodiment

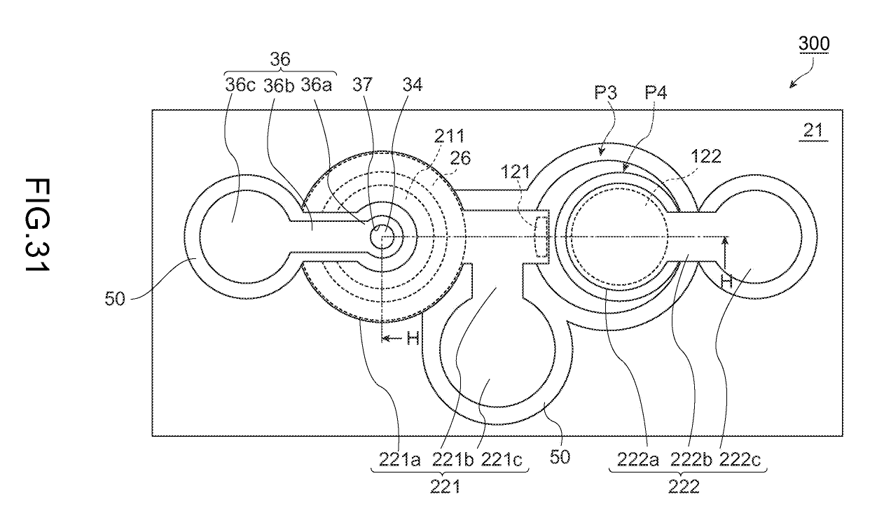

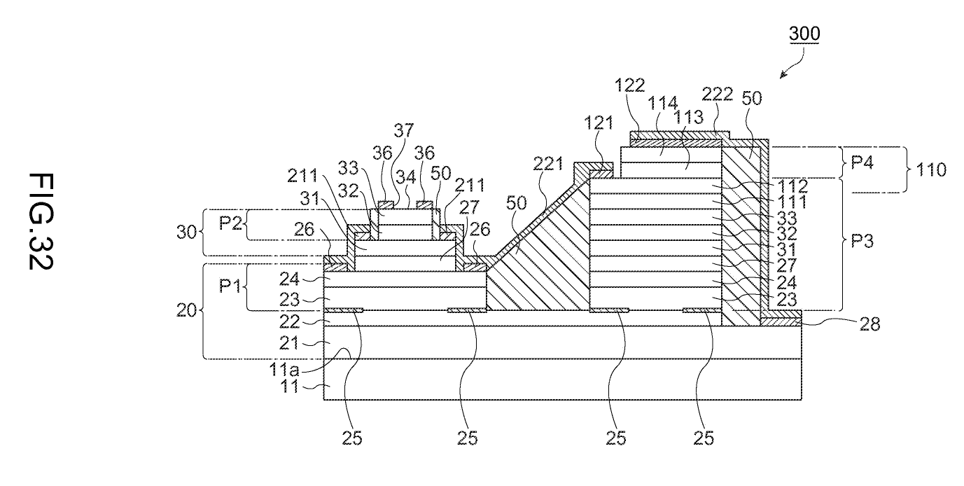

Next, a tenth embodiment of the invention is described with reference to the accompanying drawings. FIG. 31 is a plan view schematically showing an optical semiconductor element in accordance with a tenth embodiment of the invention, and FIG. 32 is a cross-sectional view taken along a line H-H of FIG. 31. As shown in FIG. 32, an optical semiconductor element 300 in accordance with the present embodiment includes a surface-emitting type semiconductor laser 20, a photodetecting element 30 as a photodetecting element, and an electrostatic breakdown protection element 110. The structure of each of the elements and the overall structure of the optical semiconductor element 300 are described below.

Surface-Emitting Type Semiconductor Laser

The surface-emitting type semiconductor laser 20 is formed on a semiconductor substrate 11 an n-type GaAs substrate in the present embodiment). The surface-emitting type semiconductor laser 20 has a vertical resonator, wherein, in accordance with the present embodiment, one of distributed Bragg reflectors that compose the vertical resonator is formed in a semiconductor deposited body (hereafter referred to as a first columnar section) P1. In other words, the surface-emitting type semiconductor laser 20 has a portion included in the first columnar section P1.

The surface-emitting type semiconductor laser 20 has a multilayered structure and is formed from, for example, a distributed Bragg reflector of 40 pairs of alternately laminated n-type Al_{0.9}Ga_{0.1}As layers and n-type Al_{0.15}Ga_{0.85}As layers (hereafter called a “first mirror”) 21, an active layer 22 composed of GaAs well layers and Al_{0.3}Ga_{0.7}As barrier layers in which the well layers include a quantum well structure composed of three layers, a distributed Bragg reflector of 25 pairs of alternately laminated p-type Al_{0.9}Ga_{0.1}As layers and p-type Al_{0.15} Ga_{0.85}As layers (hereafter called a “second mirror”) 23, and a contact layer 24 composed of p-type GaAs, which are successively stacked in layers.

In the present embodiment, the Al composition of an AlGaAs layer is a composition of aluminum (Al) with respect to gallium (Ga). The Al composition of an AlGaAs layer may range from “0” to “1.” In other words, an AlGaAs layer may include a GaAs layer (with the Al composition being “0”) and an AlAs layer (with the Al composition being “1”). It is noted that the composition of each of the layers and the number of the layers forming the first mirror 21, the active layer 22, the second mirror 23 and the contact layer 24 are not particularly limited to the above.

The first mirror 21 composing the surface-emitting type semiconductor laser 20 is made to be n-type by doping, for example, silicon (Si), and the second mirror 23 is made to be p-type by doping, for example, carbon (C). Accordingly, the p-type second mirror 23, the active layer 22 in which no impurity is doped and the n-type first mirror 21 form a pin diode. Also, among the surface-emitting type semiconductor laser 20, the second mirror 23 and the contact layer 24 are etched in a circular shape as viewed in a plan view from above the second mirror 23, whereby the first columnar section P1 is formed. It is noted that the first columnar section P1 is formed to have a plane configuration of a circular shape in this embodiment, but can be in any another shape.

A current constricting layer 25, which is obtained by oxidizing an AlGaAs layer from its side surface, is formed in a region near the active layer 22 among the layers forming the second mirror 23. The current constricting layer 25 is formed in a ring shape. In other words, the current constricting layer 25 has a cross-sectional shape, as cut in a plane horizontal with a surface 11a of the semiconductor substrate 11 shown in FIG. 31 and FIG. 32, which defines a ring shape concentric with a circular plane configuration of the first columnar section P1.

An electrode 26 having a plane configuration in a ring shape is formed along an outer circumference of the first columnar section P1 on the contact layer 24. The electrode 26 may be formed from a multilayer film of, for example, an alloy of chrome (Cr), gold (Au) and zinc (Zn), and gold (Au), or a multilayer film of platinum (Pt), titanium (Ti) and gold (Au). The electrode 26 is provided for driving the surface-emitting type semiconductor laser 20, and a current is injected into the active layer 22 through the electrode 26.

Isolation Layer

The optical semiconductor element 300 in accordance with the present embodiment is equipped with an isolation layer 27 formed on the surface-emitting type semiconductor laser 20. In other words, the isolation layer 27 is provided between the surface-emitting type semiconductor laser 20 and a photodetecting element 30 to be described below. Concretely, as shown in FIG. 32, the isolation layer 27 is formed on the contact layer 24. In other words, the isolation layer 27 is provided between the contact layer 24 of the surface-emitting type semiconductor laser 20 and a first contact layer 31 to be described below of the photodetecting element 30 to be described below. It is noted that, because the electrode 26 in a ring shape is formed on the upper surface of the contact layer 24, as described above, the circumference of the isolation layer 27 is surrounded by the electrode 26.

The plane configuration of the isolation layer 27 is circular. The plane configuration of the isolation layer 27 is the same as the plane configuration of the first contact layer 31 in the illustrated example, and formed in a manner that their diameter is smaller than the diameter of the first columnar section P1. It is noted that the plane configuration of the isolation layer 27 may be formed to be greater than the plane configuration of the first contact layer 31. The isolation layer 27 is described in greater detail in conjunction with a method for manufacturing an optical element to be described below.

Photodetecting Element

The photodetecting element 30 is provided on the isolation layer 27. The photodetecting element 30 includes a first contact layer 31, a absorption layer 32, and a second contact layer 33. The first contact layer 31 is provided on the isolation layer 27, the absorption layer 32 is provided on the first contact layer 31, and the second contact layer 33 is provided on the absorption layer 32. The plane configuration of the absorption layer 32 and the second contact layer 33 is made to be smaller than the plane configuration of the first contact layer 31. The second contact layer 33 and the absorption layer 32 compose a columnar semiconductor deposited body (hereafter referred to as a second columnar section) P2. In other words, the photodetecting element 30 has a structure having a portion thereof included in the second columnar section P2. It is noted that the upper surface of the photodetecting element 30 defines an emission surface 34 for emitting laser light from the surface-emitting type semiconductor laser 20.

The first contact layer 31 forming the photodetecting element 30 is composed of an n-type GaAs layer, the absorption layer 32 is composed of a GaAs layer in which no impurity is doped, and the second contact layer 33 is composed of a p-type GaAs layer. More specifically, the first contact layer 31 is made to be n-type by doping, for example, silicon (Si), and the second contact layer 33 is made to be p-type by doping, for example, carbon (C). Accordingly, the n-type first contact layer 31, the absorption layer 32 in which no impurity is doped, and the p-type second contact layer 33 form a pin diode.

An electrode 211 having a plane configuration in a ring shape is formed on the first contact layer 31 along an outer circumference thereof. In other words, the electrode 211 is provided in a manner to surround the second columnar section P2. The electrode 211 may be formed from a multilayer film of, for example, an alloy of chrome (Cr), gold (Au) and germanium (Ge), nickel (Ni) and gold (Au).

Further, an electrode 36 is formed on the upper surface of the photodetecting element 30 (on the second contact layer 33). The electrodes 36 and 211 are used for driving the photodetecting element 30. The electrode 36 is provided with an aperture section 37, and a part of the upper surface of the second contact layer 33 is exposed through the aperture section 37. The exposed surface defines an emission surface 34 for emitting laser light. Accordingly, by appropriately setting the plane configuration and the size of the aperture section 37, the configuration and the size of the emission surface 34 can be appropriately set. In accordance with the present embodiment, as shown in FIG. 31, the emission surface 34 may be circular. Also, the electrode 36 may be formed with the same material as that of the electrode 26 formed on the contact layer 24 of the surface-emitting type semiconductor laser 20.

The electrode 36 has, as shown in FIG. 31, a connection section 36a having a ring-shaped plane configuration, a lead-out section 36b having a linear plane configuration, and a pad section 36c having a circular plane configuration. The electrode 36 is electrically connected to the second contact layer 33 at the connection section 36a. The lead-out section 36b of the electrode 36 connects the connection section 36a and the pad section 36c together. The pad section 36c of the electrode 36 is used as an electrode pad. It is noted that, in the present exemplary embodiment, the configuration of the connection section 36a of the electrode 36 is in a ring shape. However, the plane configuration of the connection section 36a may be in any arbitrary shape as long as the connection section 36a is in contact with the second contact layer 33.

Electrostatic Breakdown Protection Element

The electrostatic breakdown protection element 110 is formed on the semiconductor substrate 11 at a columnar semiconductor deposited body (hereafter referred to as a third columnar section) P3 and a columnar semiconductor deposited body (hereafter referred to as a fourth columnar section) P4 formed on the third columnar section P3, which are formed at a position different from the positions where the first columnar section P1 and the second columnar section P2 are formed. The third columnar section P3 is formed through etching the second mirror 23, the contact layer 24, the isolation layer 27, the first contact layer 31, the absorption layer 32, the second contact layer 33, the isolation layer 111, and the first contact layer 112. Also, the fourth columnar section P4 is formed through etching a dielectric breakdown protection layer 113 and the second contact layer 114.

The third columnar section P3 is etched in a circular shape as viewed from above the upper surface of the first contact layer 112, and the fourth columnar section P4 is etched in a circular shape as viewed from above the upper surface of the second contact layer 114. Also, as shown in FIG. 31 and FIG. 32, the fourth columnar section P4 is formed to have a diameter smaller than the diameter of the third columnar section P3, and is formed in a state in which the fourth columnar section P4 is eccentric in a direction shifted away from the first columnar section P1 and the second columnar section P2 so as not to be concentric with the third columnar section P3. The isolation layer 111 formed in the third columnar section P3 is provided to isolate the pin diode composed of the first contact layer 31, the absorption layer 32 and the second contact layer 33 below the third columnar section P3 from the electrostatic breakdown protection element 110, and may be composed of a composition similar to that of the isolation layer 27. It is noted that, although the fourth columnar section P4 is eccentric with respect to the third columnar section P3 in the present embodiment, they can be made concentric with each other.

The electrostatic breakdown protection element 110 includes the first contact layer 112 of the third columnar section P3, and the dielectric breakdown protection layer 113 and the second contact layer 114 of the fourth columnar section P4. In this manner, the electrostatic breakdown protection element 110 is formed to have a layer structure that is different from the layer structure of the surface-emitting type semiconductor laser 20 and the layered structure of the photodetecting element 30. For this reason, the structures of the surface-emitting type semiconductor laser 20, the photodetecting element 30 and the electrostatic breakdown protection element 110 can be made optically and electrically optimum, respectively.

The first contact layer 112 composing the electrostatic breakdown protection element 110 may be composed of an n-type GaAs layer, the dielectric breakdown protection layer 113 is composed of a GaAs layer in which no impurity is doped, and the second contact layer 114 is composed of a p-type GaAs layer. More specifically, the first contact layer 112 is made to be n-type by doping, for example, silicon (Si), and the second contact layer 114 is made to be p-type by doping, for example, carbon (C). Accordingly, a pin diode is formed by the n-type first contact layer 112, the dielectric breakdown protection layer 113 in which no impurity is doped, and the p-type second contact layer 114.

An electrode 121 having a plane configuration in a generally rectangular shape is formed on the first contact layer 112 composing the electrostatic breakdown protection element 110 on the side opposite to the first columnar section P1 and the second columnar section P2. The electrode 121 may be composed of the same material as that of the electrode 211 formed on the first contact layer 31 composing the photodetecting element 30. In other words, the electrode 121 may be formed from a multilayer film of, for example, an alloy of chrome (Cr), gold (Au) and germanium (Ge), nickel (Ni) and gold (Au).

Also, an electrode 122 is formed on the second contact layer 114 composing the electrostatic breakdown protection element 110. The electrodes 121 and 122 are used for driving the electrostatic breakdown protection element 110. The electrode 122 may be composed of the same material as that of the electrode 26 formed on the contact layer 24 of the surface-emitting type semiconductor laser 20. Concretely, the electrode 122 can be formed from, for example, a multilayer film of an alloy of chrome (Cr), gold (Au) and zinc (Zn), and gold (Au). The electrode 122 may preferably be provided with a circular plane configuration that is similar to the plane configuration of the fourth columnar section P4.

Insulation Layer

The optical semiconductor element 300 in accordance with the present embodiment is provided with an insulation layer 50 formed mainly around circumferences of the first columnar section P1, the second columnar section P2 and the third columnar section P3, on the first mirror 21 or on the active layer 22, as shown in FIG. 31 and FIG. 32. Also, the insulation layer 50 is formed in a manner to cover a portion of the side surface of the fourth columnar section P4. Furthermore, the insulation layer 50 is formed below the lead-out section 36b and the pad section 36c of the electrode 36, and below electrode wirings 221 and 222 to be described below.

Electrode Wiring

An electrode wiring 221 is provided for electrically connecting the electrode 26 of the surface-emitting type semiconductor laser 20, the electrode 211 of the photodetecting element 30 and the electrode 121 of the electrostatic breakdown protection element 110 to one another. As shown in FIG. 31, the electrode wiring 221 has a connection section 221a having a ring-shaped plane configuration, a lead-out section 221b having a plane configuration in a T-letter shape, and a pad section 221c having a circular plane configuration. The electrode wiring 221 is bonded and electrically connected to the upper surface of the electrodes 26 and 211 at the connection section 221a. The lead-out section 221b of the electrode wiring 221 connects the connection section 221a to the electrode 121 of the electrostatic breakdown protection element 110 and is connected to the pad section 221c. The pad section 221c of the electrode wiring 221 is used as an electrode pad.

An electrode wiring 222 is provided for electrically connecting the electrode 28 formed on a portion of the first mirror 21 with the electrode 122 of the electrostatic breakdown protection element 110. It is noted that the electrode 28 is one of the electrodes of the surface-emitting type semiconductor laser 20, and may be formed with the same material as that of the electrode 211 that is formed on the first contact layer 31 of the photodetecting element 30 and the electrode 121 that is formed on the first contact layer 112 of the electrostatic breakdown protection element 110. In other words, the electrode 28 may be formed from a multilayer film of, for example, an alloy of chrome (Cr), gold (Au) and germanium (Ge), nickel (Ni) and gold (Au). As shown in FIG. 31, the electrode wiring 222 has a connection section 222a in a ring-shaped plane configuration, a lead-out section 222b in a rectangular plane configuration, and a pad section 222c. The electrode wiring 222 is bonded and electrically connected to the upper surface of the electrode 122 at the connection section 222a. The lead-out section 222b of the electrode wiring 222 connects the connection section 222a to the pad section 222c, and is connected to the electrode 28. The pad section 222c of the electrode wiring 222 is used as an electrode pad. The electrode wirings 221 and 222 may be formed with, for example, gold (Au).

It is noted that, in the present embodiment, the electrode 26 of the surface-emitting type semiconductor laser 20, the electrode 211 of the photodetecting element 30 and the electrode 121 of the electrostatic breakdown protection element 110 are connected by the electrode wiring 221, and the electrode 28 formed on a portion of the upper surface of the first mirror 21 and the electrode 122 of the electrostatic breakdown protection element 110 are connected by the electrode wiring 222. However, the electrode 26, the electrode 211 and the electrode 121 may be connected together by wire bonding, and the electrode 28 and the electrode 122 may be connected together by wire bonding. However, as the wiring resistance can be lowered with the connection method using the electrode wirings 221 and 222, the connection method of the embodiment provides excellent high-frequency characteristic and highly reliable manufacturing process.

Overall Structure

In the optical element 300 in accordance with the present embodiment, the n-type first mirror 21 and the p-type second mirror 23 of the surface-emitting type semiconductor laser 20, and the n-type first contact layer 31 and the p-type second contact layer 33 of the photodetecting element 30 form a npnp structure as a whole. The photodetecting element 30 is provided to monitor outputs of laser light generated in the surface-emitting type semiconductor laser 20. Concretely, the photodetecting element 30 converts laser light generated in the surface-emitting type semiconductor laser 20 into electric current. With values of the electric current, outputs of laser light generated in the surface-emitting type semiconductor laser 20 are monitored.

More specifically, in the photodetecting element 30, a part of laser light generated in the surface-emitting type semiconductor laser 20 is absorbed in the absorption layer 32, and photoexcitation is caused by the absorbed light in the absorption layer 32, and electrons and holes are generated. Then, by an electric field that is applied from outside, the electrons move to the electrode 211 and the holes move to the electrode 36, respectively. As a result, a current is generated in the direction from the first contact layer 31 to the second contact layer 33 in the photodetecting element 30.

Also, intensity of the surface-emitting type semiconductor laser 20 is determined mainly by a bias voltage applied to the surface-emitting type semiconductor laser 20. In particular, intensity of the surface-emitting type semiconductor laser 20 greatly changes depending on the ambient temperature of the surface-emitting type semiconductor laser 20 and the lifetime of the surface-emitting type semiconductor laser 20. For this reason, it is necessary for the surface-emitting type semiconductor laser 20 to maintain a predetermined level of intensity.

In the optical element 300 in accordance with the present embodiment, intensity of the surface-emitting type semiconductor laser 20 is monitored in the photodetecting element 30, and the value of a voltage to be applied to the surface-emitting type semiconductor laser 20 is adjusted based on the value of a current generated in the photodetecting element 30, whereby the value of a current flowing within the surface-emitting type semiconductor laser 20 can be adjusted. Accordingly, a predetermined level of intensity can be maintained in the surface-emitting type semiconductor laser 20. The control to feed back the intensity of the surface-emitting type semiconductor laser 20 to the value of a voltage to be applied to the surface-emitting type semiconductor laser 20 can be performed by using an external electronic circuit (e.g., a drive circuit not shown).

Also, in the optical semiconductor element 300 in accordance with the present embodiment, the electrode 26 of the surface-emitting type semiconductor laser 20 and the electrode 121 of the electrostatic breakdown protection element 110 are electrically connected to each other by the electrode wiring 221, and the electrode 28 of the surface-emitting type semiconductor laser 20 and the electrode 122 of the electrostatic breakdown protection element 110 are electrically connected to each other by the electrode wiring 222. It is noted that the electrode 26 of the surface-emitting type semiconductor laser 20 is a p-electrode that is formed on the contact layer 24 composed of p-type GaAs, and the electrode 28 is an n-electrode formed on the n-type first mirror 21. On the other hand, the electrode 121 of the electrostatic breakdown protection element 110 is an n-electrode formed on the first contact layer 112 composed of an n-type GaAs layer, and the electrode 122 is a p-electrode formed on the second contact layer 114 composed of a p-type GaAs layer. Accordingly, the electrostatic breakdown protection element 110 is connected in parallel with the surface-emitting type semiconductor laser 20 by the electrode wirings 221 and 222 so as to have a reverse polarity (a rectification action in a reverse direction) with respect to the surface-emitting type semiconductor laser 20.

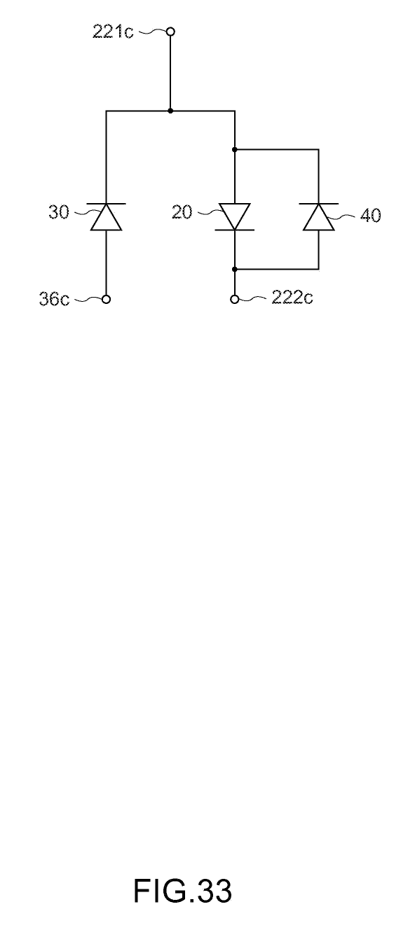

FIG. 33 is an electrical equivalent circuit diagram of the optical semiconductor element 300 in accordance with the tenth embodiment of the invention. As shown in FIG. 33, the photodetecting element 30 has an anode electrode (positive electrode) connected to the pad section 36c of the electrode 36, and a cathode electrode (negative electrode) connected to the pad section 221c of the electrode wiring 221. The surface-emitting type semiconductor laser 20 has an anode electrode (positive electrode) connected to the pad section 221c of the electrode wiring 221, and a cathode electrode (negative electrode) connected to the pad section 222c of the electrode wiring 222. The electrostatic breakdown protection element 110 has an anode electrode (positive electrode) connected to the pad section 222c of the electrode wiring 222, and a cathode electrode (negative electrode) connected to the pad section 221c of the electrode wiring 221.

Operation of Optical Semiconductor Element

Next, general operations of the optical semiconductor element 300 in accordance with the present embodiment are described. It is noted that the following method for driving the optical semiconductor element 300 is described as an example, and various changes can be made within the scope of the invention. First, when the pad sections 221c and 222c are connected to a power supply (illustration omitted), and a voltage in a forward direction is applied across the electrode 26 and the electrode 28, recombination of electrons and holes occur in the active layer 22 of the surface-emitting type semiconductor laser 20, thereby causing emission of light due to the recombination. Stimulated emission occurs during the period the generated light reciprocates between the second mirror 23 and the first mirror 21, whereby the light intensity is amplified. When the optical gain exceeds the optical loss, laser oscillation occurs, whereby laser light is emitted from the upper surface of the second mirror 23, and enters the isolation layer 27. Then, the laser light enters the first contact layer 31 of the photodetecting element 30.

Then, the light entered the first contact layer 31 composing the photodetecting element 30 then enters the absorption layer 32. As a result of a part of the incident light being absorbed in the absorption layer 32, photoexcitation is caused in the absorption layer 32, and electrons and holes are generated. Then, by an electric field applied from outside, the electrons move to the electrode 211 and the holes move to the electrode 36, respectively. As a result, a current (photocurrent) is generated in the direction from the first contact layer 31 to the second contact layer 33 in the photodetector element 30. By retrieving the current from the pad sections 36c and 221c and measuring the value of the current, intensity of the surface-emitting type semiconductor laser 20 can be detected.

If a voltage in a reverse direction is applied across the electrode 26 and the electrode 28, the voltage in a reverse direction is a voltage in a reverse direction with respect to the surface-emitting type semiconductor laser 20, but is a voltage in a forward direction with respect to the electrostatic breakdown protection element 110. For this reason, even when a voltage in a reverse direction with respect to the surface-emitting type semiconductor laser 20 is applied, the current flows through the electrostatic breakdown protection element 110, and therefore the surface-emitting type semiconductor laser 20 can be protected from electrostatic destruction.

Method for Manufacturing Optical Semiconductor Element

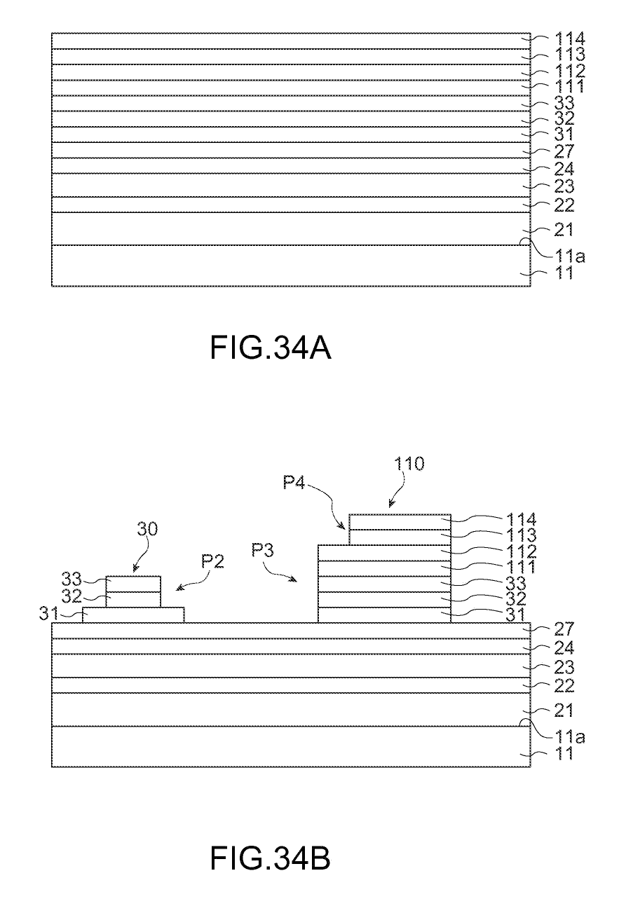

Next, a method for manufacturing an optical semiconductor element 300 described above is described. FIGS. 34-37 are cross-sectional views schematically showing steps of a method for manufacturing an optical semiconductor element in accordance with the tenth embodiment of the invention. It is noted that those figures correspond to the cross-sectional view shown in FIG. 32. To manufacture the optical semiconductor element 300 in accordance with the present embodiment, first, on a surface 11a of a semiconductor substrate 11 composed of an n-type GaAs layer, a semiconductor multilayer film is formed by epitaxial growth while modifying its composition, as shown in FIG. 34A.

The semiconductor multilayer film may be formed from, for example, a first mirror 21 of 40 pairs of alternately laminated n-type Al_{0.9}Ga_{0.1}As layers and n-type Al_{0.15} Ga_{0.85}As layers, an active layer 22 composed of GaAs well layers and Al_{0.3}Ga_{0.7}As barrier layers in which the well layers include a quantum well structure composed of three layers, a second mirror 23 of 25 pairs of alternately laminated p-type Al_{0.9}Ga_{0.1}As layers and p-type Al_{0.15}Ga_{0.85}As layers, a contact layer 24 composed of p-type GaAs, an isolation layer 27 composed of an AlGaAs layer in which no impurity is doped, a first contact layer 31 composed of an n-type GaAs layer, a absorption layer 32 composed of a GaAs layer in which no impurity is doped, a second contact layer 33 composed of a p-type GaAs layer, an isolation layer 111 composed of an AlGaAs layer in which no impurity is doped, a first contact layer 112 composed of an n-type GaAs layer, a dielectric breakdown protection layer 113 composed of a GaAs layer in which no impurity is doped, and a second contact layer 114 composed of a p-type GaAs layer. These layers are sequentially laminated on the semiconductor substrate 11, thereby forming the semiconductor multilayer film. It is noted that the isolation layers 27 and 111 can be composed of p-type or n-type AlGaAs layers.

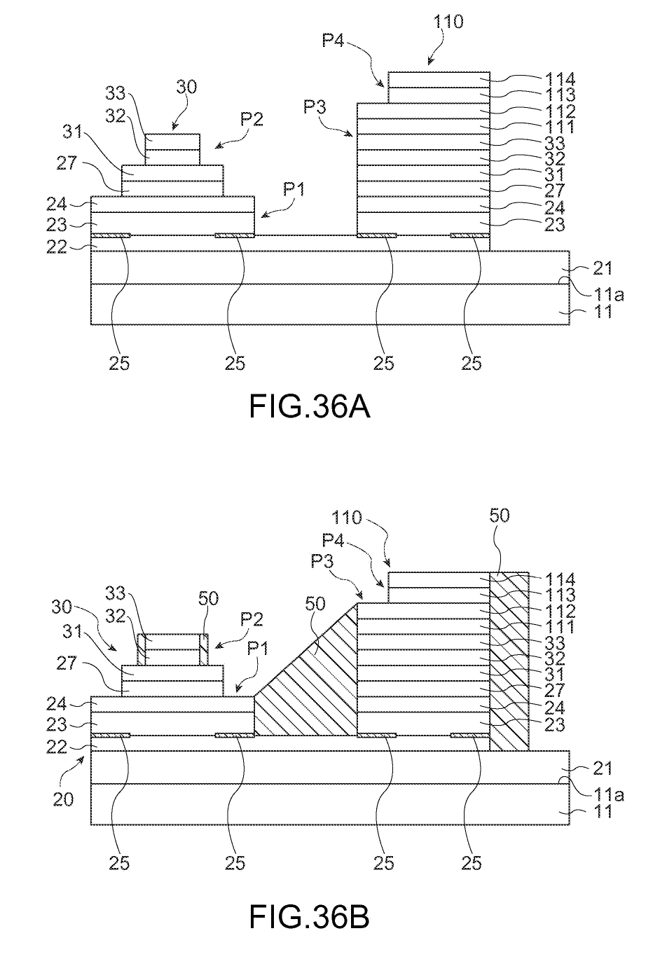

It is noted that, when the second mirror 23 is grown, at least one layer thereof near the active layer 22 is formed to be a layer that is later oxidized and becomes a current constricting layer 25 (see FIG. 36A). More concretely, the layer that becomes to be the current constricting layer 25 is formed to be an AlGaAs layer (including an AlAs layer) having an Al composition that is greater than an Al composition of the isolation layer 27 and the isolation layer 111. In other words, each of the isolation layer 27 and isolation layer 111 may preferably be formed to be an AlGaAs layer whose Al composition is smaller than that of the layer that becomes to be the current constricting layer 25. By this, in an oxidizing process for forming the current constricting layer 25 to be described below (see FIG. 36A), the isolation layer 27 is not oxidized. More specifically, the layer that becomes to be the current constricting layer 25 and the isolation layers 27 and 111 may preferably be formed such that the Al composition of the layer that becomes to be the current constricting layer 25 is 0.95 or greater, and the Al composition of the isolation layers 27 and 111 is less than 0.95. An optical film thickness of the isolation layer 27 may preferably be, for example, an odd multiple of λ/4, when a design wavelength of the surface-emitting type semiconductor laser 20 (see FIG. 32) is λ. Also, the film thickness of the isolation layer 111 may preferably be decided in consideration of its insulating characteristic, dielectric breakdown voltage characteristic and parasitic capacitance.

Also, the sum of optical film thickness of the first contact layer 31, the absorption layer 32 and the second contact layer 33, in other words, the optical film thickness of the entire photodetecting element 30 (see FIG. 32) may preferably be, for example, an odd multiple of λ/4. As a result, the entire photodetecting element 30 can function as a distributed reflection type mirror. In other words, the entire photodetecting element 30 can function as a distributed reflection type mirror above the active layer 22 in the surface-emitting type semiconductor laser 20. Accordingly, the photodetecting element 30 can function as a distributed reflection type mirror without adversely affecting the characteristics of the surface-emitting type semiconductor laser 20.

The temperature at which the epitaxial growth is conducted is appropriately decided depending on the growth method, the kind of raw material, the type of the semiconductor substrate 11, and the kind, thickness and carrier density of the semiconductor multilayer film to be formed, and may preferably be set generally at 450° C.-800° C. Also, the time required for conducting the epitaxial growth is appropriately decided like the temperature. Also, a metal-organic vapor phase deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

Next, a fourth columnar section P4 is formed, as shown in FIG. 34B. To form the fourth columnar section P4, first, resist (not shown) is coated on the semiconductor multilayer film, and then the resist is patterned by a lithography method. As a result, a resist layer having a specified plane configuration is formed on the upper surface of the second contact layer 114. Then, by using the resist layer as a mask, the second contact layer 114 and the dielectric breakdown protection layer 113 are etched by, for example, a dry etching method. By this, the second contact layer 114 and the dielectric breakdown protection layer 113 having the same plane configuration as that of the second contact layer 114 are formed. As a result, the fourth columnar section P4 is formed. When the fourth columnar section P4 is formed, the resist layer is removed.

Then, a resist layer that covers the fourth columnar section P4 is formed. By using the resist layer as a mask, the first contact layer 112 and a portion of the isolation layer 111 to an intermediate point thereof are etched by, for example, a dry etching method. By this, an upper portion of a third columnar section P3 is formed. By the process described above, an electrostatic breakdown protection element 110 is formed, as shown in FIG. 34B. The electrostatic breakdown protection element 110 includes a second contact layer 114, a dielectric breakdown protection layer 113, and a first contact layer 112. The first contact layer 112 is formed with a plane configuration greater than the plane configuration of the second contact layer 114 and the dielectric breakdown protection layer 113.

The resist layer is removed after the steps described above are completed. It is noted that, according to the process described above, the second contact layer 114 and the dielectric breakdown protection layer 113 are patterned first, and then the first contact layer 112 is patterned. However, the first contact layer 112 may be patterned first, and then the second contact layer 114 and the dielectric breakdown protection layer 113 may be patterned.

Next, a second columnar section P2 is formed, as shown in FIG. 34B. To form the second columnar section P2, first, the step of exposing the second contact layer 33 at the uppermost section of the second columnar section P2 is conducted. It is noted that the second contact layer 33 is exposed because the characteristics of the surface-emitting type semiconductor laser 20 are deteriorated if the sum of optical film thickness of the layers (i.e., the first contact layer 31, the absorption layer 32 and the second contact layer 33) composing the photodetecting element 30 deviates from, for example, an odd multiple of λ/4.

Because it is difficult to accurately control the amount of etching by dry etching, the etching process described above is conducted in a manner that the isolation layer 111 is etched to an intermediate point thereof, and the remaining portion of the isolation layer 111 is etched by selective etching thereby exposing the second contact layer 33. Concretely, first, a resist layer that covers the fourth columnar section P4 and the upper portion of the third columnar section P3 and is patterned in a predetermined shape is formed. Then, the remaining portion of the isolation layer 111 is etched by a wet etching method. As an etchant for etching the isolation layer 111, for example, a hydrogen fluoride solution or a hydrofluoric acid system buffer solution can be used. By this, the second contact layer 33 functions as an etching stopper layer, such that etching of the isolation layer 111 can be accurately and readily stopped at the time when the second contact layer 33 is exposed.

Next, after coating resist (not shown), the resist is patterned by a lithography method. By this, a resist layer is formed in areas that cover the upper surface of the fourth columnar section P4 and the third columnar section P3, and at locations where the second columnar section P2 above the second contact layer 33 is to be formed. By using the resist layer as a mask, the second contact layer 33 and the absorption layer 32 are etched by, for example, a dry etching method. As a result, the second contact layer 33 and the absorption layer 32 having the same plane configuration as that of the second contact layer 33 are formed. By this, the second columnar section P2 is formed. It is noted that the resist layer is removed after the second columnar section P2 is formed.

When the fourth columnar section P4 and the second columnar section P2 are formed, the first contact layer 31 is patterned. Concretely, resist (not shown) is coated, and then the coated resist is patterned by a lithography method. By this, a resist layer having a predetermined pattern that covers the second columnar section P2 and the upper surface of the fourth columnar section P4 and the third columnar section P3 is formed. Then, by using the resist layer as a mask, the first contact layer 31 is etched to a predetermined thickness by, for example, dry etching.

Then, the remaining portion of the first contact layer 31 is etched by a wet etching method. It is noted that, for etching the first contact layer 31, for example, a mixed solution of ammonia, hydrogen peroxide and water can be used as an etchant. In this case, the mixing ratio of ammonia, hydrogen peroxide and water which is about 1:10:150 can be used, but this mixing ratio is not particularly limited, and may be appropriately decided. It is noted that, because the isolation layer 27 is disposed below the first contact layer 31, and the isolation layer 27 functions as an etching stopper layer, etching of the first contact layer 31 can be accurately and readily stopped at the time when the isolation layer 27 is exposed.

By the steps described above, the photodetecting element 30 is formed, as shown in FIG. 34B. It is noted that the photodetecting element 30 includes the second contact layer 33, the absorption layer 32 and the first contact layer 31. The plane configuration of the first contact layer 31 is made to be greater than the plane configuration of the second contact layer 33 and the absorption layer 32. In this manner, in accordance with the present embodiment, the photodetecting element 30 and the electrostatic breakdown protection element 110 are formed by different processes. It is noted that, in the process described above, the second contact layer 33 and the absorption layer 32 are patterned, and then the first contact layer 31 is patterned. However, the first contact layer 31 may be patterned first, and then the second contact layer 33 and the absorption layer 32 may be patterned.

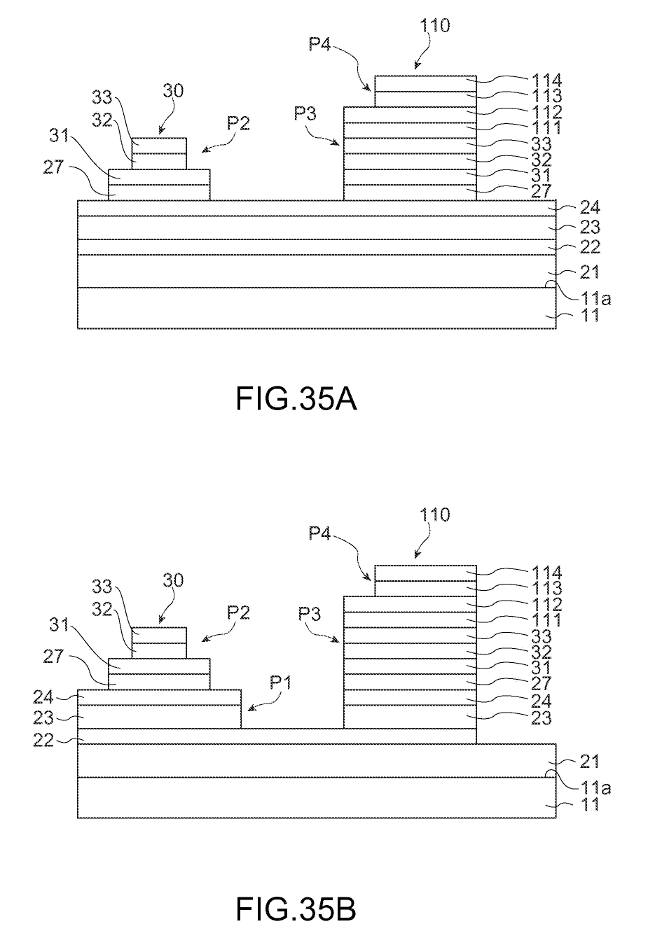

When the photodetecting element 30 and the electrostatic breakdown protection element 110 are formed, the isolation layer 27 is patterned into a specified configuration, as shown in FIG. 35A. More concretely, by using the resist layer described above (the resist layer used for etching the first contact layer 31) as a mask, the isolation layer 27 is etched. In this instance, because the contact layer 24 is disposed below the isolation layer 27, and the contact layer 24 functions as an etching stopper layer, etching of the isolation layer 27 can be accurately and readily stopped at the time when the contact layer 24 is exposed. As an etchant for etching the isolation layer 27, for example, a hydrogen fluoride solution or a hydrofluoric acid system buffer solution can be used.

As a result, the isolation layer 27 that is patterned is formed, as shown in FIG. 235A. Then, the resist layer (the resist layer used for etching the first contact layer 31 and the isolation layer 27) is removed. In the illustrated example, the plane configuration of the isolation layer 27 is made to be the same as the plane configuration of the first contact layer 31. But the plane configuration of the isolation layer 27 can be made to be greater than the plane configuration of the first contact layer 31. For example, another resist layer having a larger plane configuration area than that of the resist layer used for patterning the isolation layer 27 described above may be used to pattern the isolation layer 27.

Next, as shown in FIG. 35B, the surface-emitting type semiconductor laser 20 including the first columnar section P1 and the remaining portion of the third columnar section P3 located below the electrostatic breakdown protection element 110 are formed. More specifically, first, resist (not shown) is coated on the contact layer 24, and then the coated resist is patterned by a lithography method. As a result, a resist layer having a specified pattern is formed. Then, by using the resist layer as a mask, the contact layer 24, the second mirror 23 and the active layer 22 are etched by, for example, a dry etching method. It is noted that the active layer 22 between the first columnar section P1 and the third columnar section P3 is left remained without being etched. In the manner described above, the first columnar section P1 and the third columnar section P3 are formed, as shown in FIG. 35B.

By the steps described above, a vertical resonator (the surface-emitting type semiconductor laser 20) including the first columnar section P1 is formed on the semiconductor substrate 11. By this, a laminated body of the surface-emitting type semiconductor laser 20, the isolation layer 27 and the photodetecting element 30 is formed, and the electrostatic breakdown protection element 110 is formed above the third columnar section P3. Then, the resist layer is removed. It is noted that, in the exemplary embodiment, after forming the photodetecting element 30, the electrostatic breakdown protection element 110 and the isolation layer 27, the first columnar section P1 and the third columnar section P3 are formed. However, the first columnar section P1 and the third columnar section P3 may be formed first, and then the photodetecting element 30, the electrostatic breakdown protection element 110 and the isolation layer 27 may be formed.

Then, as shown in FIG. 36A, a current constricting layer 25 is formed. To form the current constricting layer 25, first, the semiconductor substrate 11 on which the first columnar section P1 and the third columnar section P3 are formed is placed in a water vapor atmosphere at, for example, about 400° C. As a result, a layer having a high Al composition in the second mirror 23 described above is oxidized from its side surface, whereby the current constricting layer 25 is formed.

The oxidation rate depends on the temperature of the furnace, the amount of water vapor supply, and the Al composition and the film thickness of the layer to be oxidized. When driving a surface-emitting type laser equipped with the current constricting layer 25 that is formed by oxidation, current flows only in a portion where the current constricting layer 25 is not formed (a portion that is not oxidized). Accordingly, in the process of forming the current constricting layer 25, the range of the current constricting layer 25 to be formed may be controlled, whereby the current density can be controlled. Also, the diameter of the current constricting layer 25 may preferably be adjusted such that a major portion of laser light that is emitted from the surface-emitting type semiconductor laser 20 enters the first contact layer 31.

Next, as shown in FIG. 36B, an insulation layer 50 is formed on the active layer 22 and the first mirror 21, around the first columnar section P1 and the third columnar section P3, and around the second columnar section P2. The insulation layer 50 may preferably be composed of a material that is easier to make a thick film. The film thickness of the insulation layer 50 may be, for example, about 2-4 μm, but it is not particularly limited, and may be appropriately decided according to the height of the first columnar section P1 and the third columnar section P3.

For example, the insulation layer 50 can be formed from material that is obtained by hardening liquid material settable by energy, such as, heat, light or the like (for example, a precursor of ultraviolet setting type resin or thermosetting type resin). As the ultraviolet setting type resin, for example, an acrylic resin, an epoxy resin or the like that is an ultraviolet setting type can be enumerated. Also, as the thermosetting type resin, a thermosetting type polyimide resin or the like can be enumerated. Furthermore, for example, the insulation layer 50 may be composed of a laminated layered film using a plurality of the materials described above.

In this exemplary embodiment, the case where a precursor of polyimide resin is used as the material for forming the insulation layer 50 is described. First, for example, by using a spin coat method, the precursor (precursor of polyimide resin) is coated on the semiconductor substrate 11, thereby forming a precursor layer. In this instance, the precursor layer is formed in a manner to cover the upper surface of the first columnar section P1. It is noted that, as the method for forming the precursor layer, besides the aforementioned spin coat method, other known technique, such as, a dipping method, a spray coat method, an ink jet method or the like can be used. Then, the semiconductor substrate 11 is heated by using, for example, a hot plate or the like, thereby removing the solvent, and then is placed in a furnace at about 350° C. to thereby imidize the precursor layer, whereby a polyimide resin layer that is almost completely set is formed. Then, as shown in FIG. 36B, the polyimide resin layer is patterned by using a known lithography technique, thereby forming the insulation layer 50.

As the etching method used for patterning, a dry etching method or the like can be used. Dry etching can be conducted with, for example, oxygen or argon plasma. In the method for forming the insulation layer 50 described above, an example in which a precursor layer of polyimide resin is hardened and then patterning is conducted is described. However, before hardening the precursor layer of polyimide resin, patterning may be conducted. As the etching method used for this patterning, a wet etching method or the like may be used. The wet etching may be conducted with, for example, an alkaline solution or an organic solution.

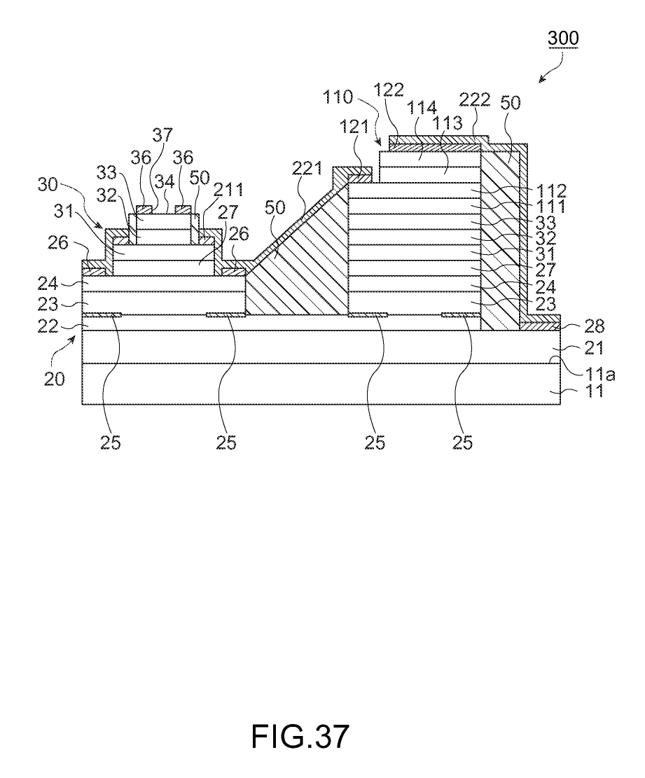

When the steps described above are completed, as shown in FIG. 37, an electrode 28 on the first mirror 21, an electrode 211 on the upper surface of the first contact layer 31 and an electrode 121 on the first contact layer 112 are formed. Also, an electrode 26 on the contact layer 24, an electrode 36 on the second contact layer 33 and an electrode 122 on the second contact layer 114 are formed. In this exemplary embodiment, the electrode 36 has a connecting section 36a having a ring-shaped plane configuration, a lead-out section 36b having a linear plane configuration, and a pad section 36c having a circular plane configuration. It is noted that the connecting section 36a is formed on the upper surface of the second contact layer 33, and the lead-out section 36b and the pad section 36c are formed on the insulation layer 50.

A concrete method for forming the electrodes 28, 121 and 211 is conducted in the following manner. First, before forming the electrodes 28, 121 and 211, the upper surface of the first mirror 21, the upper surface of the first contact layer 31 and the upper surface of the first contact layer 112 are washed by a plasma processing method or the like, if necessary. As a result, an element with more stable characteristics can be formed. Next, a laminated layered film of, for example, an alloy of chrome (Cr), gold (Au) and germanium (Ge), nickel (Ni) and gold (Au) is formed by, for example, a vacuum deposition method. Then, the electrodes 28, 121 and 211 are formed by removing portions of the laminated layered film other than specified positions by a lift-off method.

Further, a concrete method for forming the electrodes 26, 36 and 122 is conducted in the following manner. First, before forming the electrodes 26, 36 and 122, the upper surface of the contact layer 24, the upper surface of the second contact layer 33 and the upper surface of the second contact layer 144 are washed by a plasma processing method or the like, if necessary. As a result, an element with more stable characteristics can be formed. Next, a laminated layered film of, for example, an alloy of chrome (Cr), gold (Au) and zinc (Zn), and gold (Au) is formed by, for example, a vacuum deposition method. Then, the electrodes 26, 36 and 122 are formed by removing portions of the laminated layered film other than specified positions by a lift-off method.

It is noted that in the process of forming the electrodes 28, 121 and 211 and the electrodes 26, 36 and 122 described above, a dry etching method or a wet etching method may be used instead of a lift-off method. Also, in the above-described process, a sputtering method may be used instead of a vacuum deposition method. Moreover, although the electrodes 28, 121 and 211 are concurrently patterned, and the electrodes 26, 36 and 122 are concurrently patterned in the process described above, these electrodes may be formed individually from one another.

When the process described above is completed, electrode wirings 221 and 222 are formed, as shown in FIG. 37. It is noted that the electrode wiring 221 is formed in a manner to electrically connect the electrode 26 of the surface-emitting type semiconductor laser 20, the electrode 211 of the photodetecting element 30, and the electrode 121 of the electrostatic breakdown protection element 110. Further, the electrode wiring 222 is formed in a manner to electrically connect the electrode 28 of the surface-emitting type semiconductor laser 20 with the electrode 122 of the electrostatic breakdown protection element 110. Concretely, like the aforementioned case of forming the electrodes, surfaces above the semiconductor substrate 11 are washed by using a plasma processing method or the like if necessary. Next, a metal film composed of, for example, gold (Au) is formed by, for example, a vacuum deposition method. Then, portions of the metal film other than the specified positions are removed, thereby forming the electrode wirings 221 and 222.

Finally, an annealing treatment is conducted. The temperature of the annealing treatment depends on the electrode material. For example, the annealing treatment may be conducted at about 400° C. for the electrode material used in the present embodiment. It is noted that the annealing treatment may be conducted before the electrode wirings 221 and 222 are formed, if necessary. By the process described above, the optical semiconductor element 300 in accordance with the present embodiment shown in FIG. 37 is manufactured. In the present exemplary embodiment, the photodetecting element 30 and the electrostatic breakdown protection element 110 are formed by individual process steps. For this reason, the optical semiconductor element 300 whose electrostatic breakdown voltage is improved can be manufactured without complicating the manufacturing process.

### Eleventh Embodiment

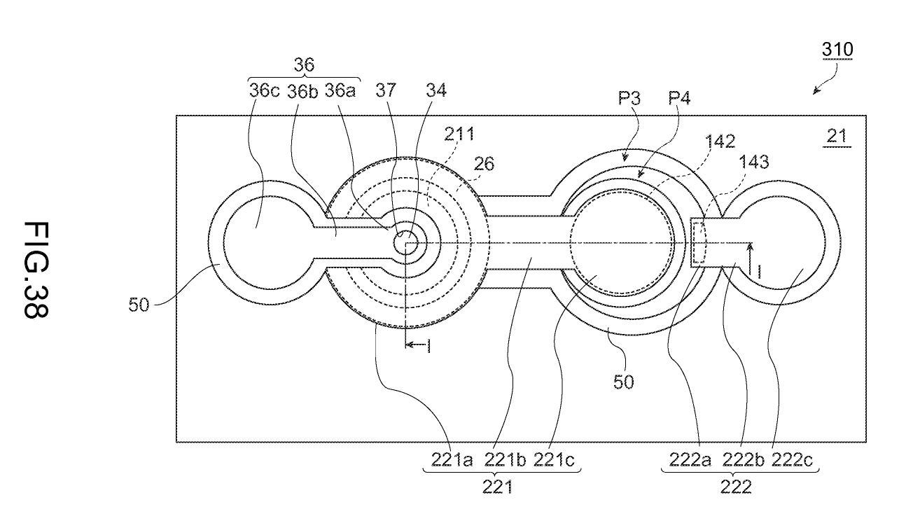

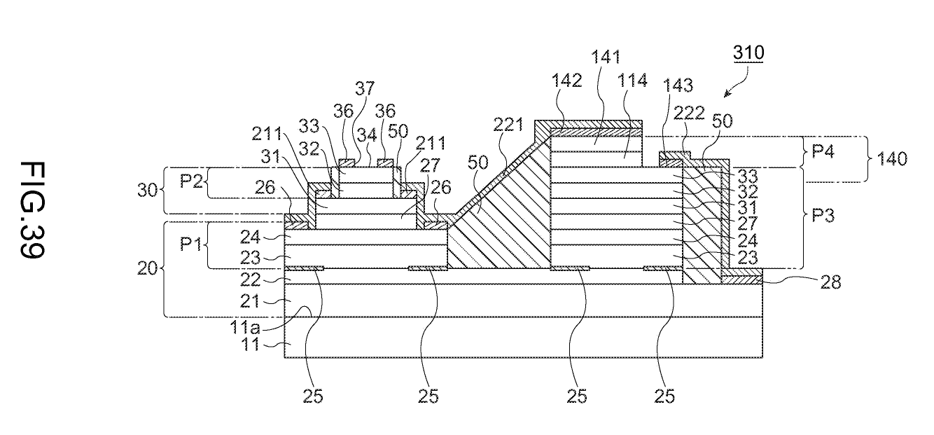

FIG. 38 is a plan view schematically showing an optical semiconductor element in accordance with an eleventh embodiment of the invention, and FIG. 39 is a cross-sectional view taken along a line I-I of FIG. 38. In FIG. 38 and FIG. 39, components corresponding to the components shown in FIG. 31 and FIG. 32 are appended with the same reference numerals. As shown in FIG. 38 and FIG. 39, an optical semiconductor element 310 in accordance with the present embodiment includes a surface-emitting type semiconductor laser 20, a photodetecting element 30, and an electrostatic breakdown protection element 140. The surface-emitting type semiconductor laser 20 and the photodetecting element 30 of the optical semiconductor element 310 of the present embodiment have the same structure as those of the optical semiconductor element 300 of the tenth embodiment shown in FIG. 31 and FIG. 32, but the electrostatic breakdown protection element 140 has a structure different from the electrostatic breakdown protection element 110 of the optical semiconductor element 300.

According to the tenth embodiment described above, the isolation layer 111, the first contact layer 112, the dielectric breakdown protection layer 113 and the second contact layer 114 are successively laminated on the second contact layer 33 that composes the photodetecting element 30, and the electrostatic breakdown protection element 110 is formed from the first contact layer 112, the dielectric breakdown protection layer 113 and the second contact layer 114 above the isolation layer 111. In contrast, in accordance with the present embodiment, the isolation layer 111 and the first contact layer 112 above the second contact layer 33 are omitted, and a dielectric breakdown protection layer 113 and a contact layer 141 are sequentially laminated on the second contact layer 33. Furthermore, the electrostatic breakdown protection element 140 is formed from the second contact layer 33, the dielectric breakdown protection layer 113 and the contact layer 141. In other words, the electrostatic breakdown protection element 140 includes the same layer as the second contact layer 33 that composes the photodetecting element 30.

The contact layer 141 laminated on the dielectric breakdown protection layer 113 is composed of n-type GaAs similar to the first contact layer 112 of the tenth embodiment. Concretely, the contact layer 141 is made to be n-type by doping, for example, silicon (Si). Accordingly, the p-type second contact layer 33, the dielectric breakdown protection layer 113 in which no impurity is doped, and the n-type contact layer 141 form a pin diode.

In accordance with the present embodiment, the second contact layer 33 is formed in a third columnar section P3, and the dielectric breakdown protection layer 113 and the contact layer 141 are formed in a fourth columnar section P4. The third columnar section P3 is etched in a circular shape as viewed from above the upper surface of the second contact layer 33, and the fourth columnar section P4 is etched in a circular shape as viewed from above the upper surface of the contact layer 141. Also, as shown in FIG. 38 and FIG. 39, the fourth columnar section P4 is formed to have a diameter smaller than the diameter of the third columnar section P3, and is formed in a state in which the fourth columnar section P4 is eccentric in a direction shifted toward the first columnar section P1 and the second columnar section P2 so as not to be concentric with the third columnar section P3. It is noted that, although an example in which the fourth columnar section P4 is eccentric with respect to the third columnar section P3 is described in this embodiment, they can be made concentric with each other.

An electrode 142 is formed on an upper surface of the fourth columnar section P4 (on the contact layer 141), and an electrode 143 is formed on an upper surface of the third columnar section P3 (on the second contact layer 33). The electrode 142 may be formed from a multilayer film of, for example, an alloy of chrome (Cr), gold (Au) and germanium (Ge), nickel (Ni) and gold (Au). The electrode 143 may be formed from a multilayer film of, for example, an alloy of chrome (Cr), gold (Au) and zinc (Zn), and gold (Au), or a multilayer film of platinum (Pt), titanium (Ti) and gold (Au).

Further, as shown in FIG. 39, an electrode wiring 221 is formed on the electrode 142. By this, the electrode 142 is electrically connected with the electrode 26 of the surface-emitting type semiconductor laser 20 and the electrode 211 of the photodetecting element 30. Also, an electrode wiring 222 is formed on the electrode 143. By this, the electrode 143 is electrically connected with the electrode 28 of the surface-emitting type semiconductor laser 20. Accordingly, in the optical semiconductor element 310 in accordance with the present embodiment, the electrostatic breakdown protection element 140 is connected in parallel with the surface-emitting type semiconductor laser 20 by the electrode wirings 221 and 222 so as to have a reverse polarity (a rectification action in a reverse direction) with respect to the surface-emitting type semiconductor laser 20. For this reason, even when a voltage in a reverse direction is applied across the electrode 26 and the electrode 28 of the surface-emitting type semiconductor laser 20, the current flows through the electrostatic breakdown protection element 140, and therefore the surface-emitting type semiconductor laser 20 can be protected from electrostatic destruction.

Also, in accordance with the present embodiment, the isolation layer 111 and the first contact layer 112, which are required in the tenth embodiment, are omitted, and the second contact layer 33 is shared by the photodetecting element 30 and the electrostatic breakdown protection element 140. Accordingly, in accordance with the present embodiment, the epitaxial layers are reduced by two layers compared with the tenth embodiment, such that the number of manufacturing steps can be reduced and the material cost can also be reduced. Further, the dielectric breakdown protection layer 113 of the electrostatic breakdown protection element 140 is not used in the photodetecting element 30, and therefore the film thickness of the dielectric breakdown protection layer 113 can be appropriately set in a manner that the electrical characteristics of the electrostatic breakdown protection element 140 become optimized.

Furthermore, in accordance with the present embodiment, the electrostatic breakdown protection element 140 is formed by manufacturing steps generally independent from those for forming the photodetecting element 30, although a part thereof is shared by the photodetecting element 30. However, the electrostatic breakdown protection element 140 can be readily formed by devising the etching steps, such that the optical semiconductor element 310 whose electrostatic breakdown voltage is improved can be manufactured without complicating the manufacturing process.

Exemplary embodiments of the invention are described above. However, the invention is not limited to the embodiments described above, and changes can be freely made within the scope of the invention. For example, in the embodiments described above, optical elements in which the photodetecting element 30 is provided above the surface-emitting type semiconductor laser 20 are described as examples. However, the invention is also applicable to optical elements having a structure described in, for example, Japanese Examined Patent Application Publication JP-B-7-56552 or Japanese Laid-open Patent Application JP-A-6-37299, in which a surface-emitting type semiconductor laser is provided above a photodetecting element.

Also, in the embodiments described above, the photodetecting element 30 is provided to detect the light intensity of laser light emitted from the surface-emitting type semiconductor laser 20. However, the photodetecting element 30 can also be used to detect external light. More specifically, for example, the optical element may be used for optical communications, wherein laser light emitted from the surface-emitting type semiconductor laser 20 may be used for optical signals to be transmitted, and optical signals transmitted can be detected by the photodetecting element 30. Optical signals received by the photodetecting element 30 are extracted as electrical signals through the electrodes 36 and 211. Moreover, interchanging the p-type and n-type characteristics of each of the semiconductor layers in the above described embodiments does not deviate from the subject matter of the present invention. Moreover, in the embodiments described above, examples in which the electrostatic breakdown protection element 140 is a pin diode (an element that forms a PIN junction) are described. However, an electrostatic breakdown protection element 140 can be formed with an element that forms a PN junction, a heterojunction, or a Schottky junction.

What is claimed is:

1. An optical semiconductor element comprising:
a surface-emitting type semiconductor laser with a multilayered structure that emits laser light in a direction vertical to a substrate surface;
a photodetecting element with a multilayered structure formed above or below the surface-emitting type semiconductor laser; and
an electrostatic breakdown protection element that protects the surface-emitting type semiconductor laser from electrostatic destruction, which are provided on the substrate,
wherein a pair of input terminals for driving the surface-emitting type semiconductor laser and a pair of output terminals of the photodetecting element are provided independently of one another.

2. An optical semiconductor element according to claim 1, wherein the electrostatic breakdown protection element is connected between the pair of input terminals in parallel with the surface-emitting type semiconductor laser and has a rectification action in a reverse direction with respect to the surface-emitting type semiconductor laser.

3. An optical semiconductor element according to claim 2, wherein the electrostatic breakdown protection element has one of a PN junction, a PIN junction, a heterojunction and a Schottky junction formed therein.

4. An optical semiconductor element according to claim 1, wherein the electrostatic breakdown protection element has a layer structure identical with at least a portion of the multilayered structure of at least one of the surface-emitting type semiconductor laser and the photodetecting element.

5. An optical semiconductor element according to claim 4, wherein the photodetecting element has a first semiconductor layer of a first conductivity type, a second semiconductor layer that functions as a absorption layer, and a third semiconductor layer of a second conductivity type, and the electrostatic breakdown protection element has a PIN junction formed with a layer structure identical with the layer structure of the first through third semiconductor layers.

6. An optical semiconductor element according to claim 4, comprising an isolation layer provided between the surface-emitting type semiconductor laser and the photodetecting element for isolating the surface-emitting type semiconductor laser from the photodetecting element.

7. An optical semiconductor element according to claim 6, wherein the electrostatic breakdown protection element has a heterojunction formed therein with a layer structure identical with a portion of the multilayered structure of the photodetecting element, the isolation layer and a layer structure identical with a portion of the multilayered structure of the surface-emitting type semiconductor laser.

8. An optical semiconductor element according to claim 1, wherein the electrostatic breakdown protection element has have a layer structure different from the multilayered structure of the surface-emitting type semiconductor laser and the photodetecting element.

9. An optical semiconductor element according to claim 8, wherein the photodetecting element is equipped with a first semiconductor layer of a first conductivity type, a second semiconductor layer that functions as a absorption layer, and a third semiconductor layer of a second conductivity type, wherein the electrostatic breakdown protection element has a layer structure identical with a layer structure of one of the first semiconductor layer and the third semiconductor layer.

10. An optical semiconductor element according to claim 8, comprising an isolation layer that isolates the surface-emitting type semiconductor laser from the photodetecting element provided between the surface-emitting type semiconductor laser and the photodetecting element.

11. A method for manufacturing an optical semiconductor element, the method comprising the steps of:
forming, above a substrate, a surface-emitting type semiconductor laser with a multilayered structure that emits laser light in a direction vertical to a substrate surface, a photodetecting element with a multilayered structure above or below the surface-emitting type semiconductor laser, and an electrostatic breakdown protection element that protects the surface-emitting type semiconductor laser from electrostatic destruction; and
forming a pair of input terminals for driving the surface-emitting type semiconductor laser and a pair of output terminals of the photodetecting element independently of one another.

12. A method for manufacturing an optical semiconductor element according to claim 11, wherein the electrostatic breakdown protection element is connected between the pair of input electrodes in parallel with the surface-emitting type semiconductor laser to as to have a rectification action in a reverse direction with respect to the surface-emitting type semiconductor laser.

13. A method for manufacturing an optical semiconductor element according to claim 11, wherein the electrostatic breakdown protection element is formed to have a layer structure identical with at least a portion of the multilayered structure of at least one of the surface-emitting type semiconductor laser and the photodetecting element.

14. A method for manufacturing an optical semiconductor element according to claim 13, wherein the electrostatic breakdown protection element is formed concurrently with at least one of the surface-emitting type semiconductor laser and the photodetecting element.

15. A method for manufacturing an optical semiconductor element according to claim 11, wherein the electrostatic breakdown protection element is formed to have a layer structure different from the multilayered structure of the surface-emitting type semiconductor laser and the photodetecting element.

16. A method for manufacturing an optical semiconductor element according to claim 15, wherein the electrostatic breakdown protection element is formed by a process different from the process of forming the surface-emitting type semiconductor laser and the photodetecting element.
